(19) United States
(12) Patent Application Publication
(10) Pub. No.: US 2024/0429170 A1
(43) Pub. Date: Dec. 26, 2024

(54) SEMICONDUCTOR DEVICE AND METHOD FOR MANUFACTURING SEMICONDUCTOR DEVICE

(71) Applicant: SEMICONDUCTOR ENERGY LABORATORY CO., LTD., Atsugi-shi (JP)

(72) Inventors: Junichi KOEZUKA, Tochigi (JP); Masami JINTYOU, Shimotsuga (JP)

(21) Appl. No.: 18/669,136

(22) Filed: May 20, 2024

(30) Foreign Application Priority Data
Jun. 23, 2023 (JP) 2023-103055

(51) Int. Cl. H01L 23/532; H01L 23/528; H01L 29/66; H01L 29/786

(52) U.S. Cl. CPC H01L 23/5329; H01L 23/5283; H01L 29/66742; H01L 29/7869

(57) ABSTRACT

A semiconductor device includes first to fourth conductive layers, first and second insulating layers, and a semiconductor layer. The first insulating layer is over the first conductive layer. The second conductive layer is over the first insulating layer. The second conductive layer and the first insulating layer include an opening reaching the first conductive layer. The semiconductor layer is in the opening. The second insulating layer is over the semiconductor layer. The third conductive layer is over the second insulating layer to fill the opening. The first insulating layer includes a depressed portion surrounding the opening in a plan view. The fourth conductive layer fills the depressed portion. Inside the opening, one side of the semiconductor layer faces the third conductive layer with the second insulating layer therebetween, and the other side of the semiconductor layer faces the fourth conductive layer with the first insulating layer therebetween.

### BACKGROUND OF THE INVENTION

### 1. Field of the Invention

One embodiment of the present invention relates to a semiconductor device, a memory device, and an electronic device. Another embodiment of the present invention relates to a method of manufacturing the semiconductor device.

Note that one embodiment of the present invention is not limited to the above technical field. Examples of the technical field of one embodiment of the present invention include a semiconductor device, a display device, a light-emitting device, a power storage device, a memory device, a lighting device, an input device (e.g., a touch sensor), an input/output device (e.g., a touch panel), an electronic device including any of these devices, a method for driving any of these devices, and a method for manufacturing any of these devices.

In this specification and the like, a semiconductor device generally means a device that can function by utilizing semiconductor characteristics. A semiconductor element such as a transistor, an integrated circuit, an arithmetic device, and a memory device are each an embodiment of a semiconductor device. A display device (e.g., a liquid crystal display device and a light-emitting display device), a projection device, a lighting device, an electro-optical device, a power storage device, a memory device, an integrated circuit, an imaging device, an electronic device, and the like may include a semiconductor device.

### 2. Description of the Related Art

In recent years, semiconductor devices have been developed to be used mainly for an LSI, a CPU, a memory, and the like. A CPU is an aggregation of semiconductor elements; the CPU includes an integrated circuit (a circuit including at least a transistor) formed into a chip by processing a semiconductor wafer, and is provided with an electrode that is a connection terminal.

An integrated circuit (IC) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit and an image display device (also simply referred to as a display device). A silicon-based semiconductor material is widely known as a material of a semiconductor thin film that can be used in a transistor. As another material, an oxide semiconductor has been attracting attention.

It is known that a transistor including an oxide semiconductor has an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film. Furthermore, for example, Patent Document 4 discloses a technique for achieving an integrated circuit with higher density by forming a channel of a transistor including an oxide semiconductor film in the vertical direction.

### REFERENCES

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537
[Non-Patent Document 1] M. Oota et al., “3D-Stacked CAAC-In—Ga—Zn Oxide FETs with Gate Length of 72 nm”, IEDM Tech. Dig., 2019, pp. 50-53

### SUMMARY OF THE INVENTION

When a channel of a transistor is formed in the vertical direction as described above, the area occupied by the transistor can be reduced, and a transistor with an extremely short channel length, which is difficult to achieve with a planar transistor, can be obtained. Accordingly, a transistor which occupies a small area and has a high on-state current can be obtained.

Meanwhile, when the channel length of a transistor is decreased, the transistor tends to have normally-on characteristics by the influence of a so-called short-channel effect (also referred to as SCE). A transistor with normally-on characteristics has a higher off-state current than a transistor with normally-off characteristics. Thus, for example, the use of a transistor with normally-on characteristics in a memory device causes a shorter data retention time and requires a higher refresh frequency, leading to an increase in power consumption.

Thus, in the case where a transistor with an extremely short channel length is formed on the assumption of use in a memory device or the like, the transistor needs to be formed to have normally-off characteristics.

One method for achieving normally-off characteristics of a transistor is to provide a back gate electrode (a second gate electrode) so as to face a gate electrode (a first gate electrode) with a semiconductor layer of the transistor therebetween and to apply a reverse bias from the back gate electrode to the semiconductor layer. For example, in the case of an n-channel transistor, when drain current (I_{d})-gate voltage (V_{g}) characteristics are obtained by sweeping the voltage of a gate electrode (a first gate electrode) while applying a constant negative bias to a back gate electrode, a threshold voltage can be positively shifted as compared with the case of not applying a negative bias to the back gate electrode. That is, a transistor with normally-off characteristics can be obtained.

However, unlike a planar transistor, a miniaturized transistor whose channel is placed in the vertical direction has problems such as difficulty in accurately forming a back gate electrode and a significant increase in the area occupied by the transistor due to provision of the back gate electrode.

In view of the above, an object of one embodiment of the present invention is to provide a miniaturized transistor in which a back gate electrode can be formed accurately and a method for manufacturing the transistor. Another object is to provide a transistor which includes a back gate electrode but can inhibit a significant increase in the area occupied by the transistor and a method for manufacturing the transistor.

Another object of one embodiment of the present invention is to provide a semiconductor device that can be miniaturized or highly integrated and a method for manufacturing the semiconductor device. Another object of one embodiment of the present invention is to provide a semiconductor device including a transistor with a high on-state current and a method for manufacturing the semiconductor device. Another object of one embodiment of the present invention is to provide a semiconductor device including a transistor with a low off-state current and a method for manufacturing the semiconductor device. Another object of one embodiment of the present invention is to provide a semiconductor device including a normally-off transistor and a method for manufacturing the semiconductor device. Another object of one embodiment of the present invention is to provide a semiconductor device with a high operation speed and a method for manufacturing the semiconductor device. Another object of one embodiment of the present invention is to provide a semiconductor device with high reliability and a method for manufacturing the semiconductor device. Another object of one embodiment of the present invention is to provide a semiconductor device with a small variation in electrical characteristics of transistors and a method for manufacturing the semiconductor device. Another object of one embodiment of the present invention is to provide a semiconductor device with low power consumption and a method for manufacturing the semiconductor device. Another object of one embodiment of the present invention is to provide a novel semiconductor device and a method for manufacturing the semiconductor device. Another object of one embodiment of the present invention is to provide a method for manufacturing a semiconductor device with high productivity.

Note that the description of these objects does not preclude the existence of other objects. One embodiment of the present invention does not necessarily achieve all of these objects. Other objects can be derived from the description of the specification, the drawings, the claims, and the like.

One embodiment of the present invention is a semiconductor device including a first conductive layer, a second conductive layer, a third conductive layer, a fourth conductive layer, a first insulating layer, a second insulating layer, and a semiconductor layer. The first insulating layer is provided over the first conductive layer. The second conductive layer is provided over the first insulating layer. The second conductive layer and the first insulating layer include an opening reaching the first conductive layer. The semiconductor layer is provided in contact with a top surface of the first conductive layer inside the opening, a side surface of the first insulating layer inside the opening, a side surface of the second conductive layer inside the opening, and a top surface of the second conductive layer. The second insulating layer is provided in contact with a top surface of the semiconductor layer inside the opening, a side surface of the semiconductor layer inside the opening, and a top surface of the semiconductor layer outside the opening. The third conductive layer is provided over the second insulating layer to fill the opening. The first insulating layer includes a depressed portion surrounding the opening in a plan view. The fourth conductive layer is provided to fill the depressed portion. Inside the opening, one side of the semiconductor layer faces the third conductive layer with the second insulating layer therebetween, and the other side of the semiconductor layer faces the fourth conductive layer with the first insulating layer therebetween.

In the above embodiment, the semiconductor layer preferably contains a metal oxide.

In the above embodiment, it is preferable that the first insulating layer include a third insulating layer and a fourth insulating layer over the third insulating layer, a fifth insulating layer be provided in contact with a top surface of the fourth insulating layer and a top surface of the fourth conductive layer, the third insulating layer and the fifth insulating layer contain one or a plurality of silicon nitride, silicon nitride oxide, hafnium oxide, and aluminum oxide, and the fourth insulating layer contain one or a plurality of silicon oxide and silicon oxynitride.

Another embodiment of the present invention is a semiconductor device including a first conductive layer, a second conductive layer, a third conductive layer, a fourth conductive layer, a first insulating layer, a second insulating layer, a third insulating layer, and a semiconductor layer. The first insulating layer is provided over the first conductive layer. The second conductive layer is provided over the first insulating layer. The first insulating layer includes a depressed portion. The third conductive layer is provided to fill the depressed portion. The second conductive layer, the third conductive layer, and the first insulating layer include an opening reaching the first conductive layer in a region overlapping with the depressed portion. The second insulating layer is provided in contact with a side surface of the first insulating layer inside the opening, a side surface of the third conductive layer inside the opening, and a side surface of the second conductive layer inside the opening. The semiconductor layer is provided in contact with a top surface of the first conductive layer inside the opening, a side surface of the second insulating layer inside the opening, and a top surface of the second conductive layer. The third insulating layer is provided in contact with a top surface of the semiconductor layer inside the opening, a side surface of the semiconductor layer inside the opening, and a top surface of the semiconductor layer outside the opening. The fourth conductive layer is provided over the third insulating layer to fill the opening. The semiconductor layer includes a region facing the fourth conductive layer with the third insulating layer therebetween and a region facing the third conductive layer with the second insulating layer therebetween inside the opening.

In the above embodiment, the semiconductor layer preferably contains a metal oxide.

In the above embodiment, it is preferable that the first insulating layer include a fourth insulating layer and a fifth insulating layer over the fourth insulating layer, a sixth insulating layer be provided in contact with a top surface of the fifth insulating layer and a top surface of the third conductive layer, the fourth insulating layer and the sixth insulating layer contain one or a plurality of silicon nitride, silicon nitride oxide, hafnium oxide, and aluminum oxide, and the fifth insulating layer contain one or a plurality of silicon oxide and silicon oxynitride.

In the above embodiment, it is preferable that the second insulating layer contain one or a plurality of silicon oxide and silicon oxynitride.

In the above embodiment, it is preferable that the second insulating layer include a seventh insulating layer and an eighth insulating layer, the seventh insulating layer be provided in contact with the side surface of the first insulating layer inside the opening, the side surface of the third conductive layer inside the opening, and the side surface of the second conductive layer inside the opening and contain one or a plurality of silicon nitride, silicon nitride oxide, hafnium oxide, and aluminum oxide, the eighth insulating layer be provided over the seventh insulating layer to face the side surface of the first insulating layer inside the opening, the side surface of the third conductive layer inside the opening, and the side surface of the second conductive layer inside the opening with the seventh insulating layer therebetween and contain one or a plurality of silicon oxide and silicon oxynitride.

Another embodiment of present invention is a method for manufacturing a semiconductor device, including the steps of: forming a first conductive layer and a first insulating film over the first conductive layer; processing the first insulating film to form a first insulating layer including a depressed portion; forming a first conductive film over the first insulating layer; planarizing the first conductive film until a top surface of the first insulating layer is exposed to form a second conductive layer filling the depressed portion; forming a second insulating film over the second conductive layer and the first insulating layer and a second conductive film over the second insulating film; processing the second conductive film, the second insulating film, and the first insulating layer to form a third conductive layer, a second insulating layer, and a third insulating layer including an opening reaching the first conductive layer in a region surrounded by the depressed portion in a plan view; forming a metal oxide film in contact with a top surface of the first conductive layer inside the opening, a side surface of the third insulating layer inside the opening, a side surface of the second insulating layer inside the opening, a side surface of the third conductive layer inside the opening, and a top surface of the third conductive layer; and processing the metal oxide film to form a semiconductor layer including a region overlapping with the opening in a plan view.

Another embodiment of present invention is a method for manufacturing a semiconductor device, including the steps of: forming a first conductive layer, a first insulating film over the first conductive layer, and a second insulating film over the first insulating film; processing the second insulating film to form a first insulating layer including a depressed portion; forming a first conductive film over the first insulating layer; planarizing the first conductive film until a top surface of the first insulating layer is exposed to form a second conductive layer filling the depressed portion; forming a third insulating film over the second conductive layer and the first insulating layer and a second conductive film over the third insulating film; processing the second conductive film, the third insulating film, the second conductive layer, and the first insulating layer to form a third conductive layer, a second insulating layer, a fourth conductive layer, and a third insulating layer including an opening reaching the first insulating film in a region overlapping with the depressed portion in a plan view; forming a fourth insulating film in contact with a top surface of the first insulating film inside the opening, a side surface of the third insulating layer inside the opening, a side surface of the fourth conductive layer inside the opening, a side surface of the second insulating layer inside the opening, a side surface of the third conductive layer inside the opening, and a top surface of the third conductive layer; removing a region of the fourth insulating film in contact with the top surface of the third conductive layer, part of a region of the fourth insulating film in contact with the first insulating film, and part of a region of the first insulating film overlapping with the opening to form a fourth insulating layer in contact with the side surface of the third insulating layer inside the opening, the side surface of the fourth conductive layer inside the opening, the side surface of the second insulating layer inside the opening, and the side surface of the third conductive layer inside the opening and to expose the first conductive layer in a region overlapping with the opening; forming a metal oxide film in contact with a top surface of the first conductive layer in the region overlapping with the opening, a side surface of the fourth insulating layer inside the opening, and the top surface of the third conductive layer; and processing the metal oxide film to form a semiconductor layer including a region overlapping with the opening in a plan view.

According to one embodiment of the present invention, a miniaturized transistor in which a back gate electrode can be formed accurately and a method for manufacturing the transistor can be provided. According to one embodiment of the present invention, a transistor which includes a back gate electrode but can inhibit a significant increase in the area occupied by the transistor and a method for manufacturing the transistor can be provided.

According to one embodiment of the present invention, a semiconductor device that can be miniaturized or highly integrated and a method for manufacturing the semiconductor device can be provided. According to one embodiment of the present invention, a semiconductor device including a transistor with a high on-state current and a method for manufacturing the semiconductor device can be provided. According to one embodiment of the present invention, a semiconductor device including a transistor with a low off-state current and a method for manufacturing the semiconductor device can be provided. According to one embodiment of the present invention, a semiconductor device including a normally-off transistor and a method for manufacturing the semiconductor device can be provided. According to one embodiment of the present invention, a semiconductor device with a high operation speed and a method for manufacturing the semiconductor device can be provided. According to one embodiment of the present invention, a semiconductor device with high reliability and a method for manufacturing the semiconductor device can be provided. According to one embodiment of the present invention, a semiconductor device with a small variation in electrical characteristics of transistors and a method for manufacturing the semiconductor device can be provided. According to one embodiment of the present invention, a semiconductor device with low power consumption and a method for manufacturing the semiconductor device can be provided. According to one embodiment of the present invention, a novel semiconductor device and a method for manufacturing the semiconductor device can be provided. According to one embodiment of the present invention, a method for manufacturing a semiconductor device with high productivity can be provided.

Note that the description of these effects does not preclude the existence of other effects. One embodiment of the present invention does not necessarily have all of these effects. Other effects can be derived from the description of the specification, the drawings, the claims, and the like.

### BRIEF DESCRIPTION OF THE DRAWINGS

FIG. 1A is a plan view illustrating an example of a semiconductor device, and

FIG. 1B is a cross-sectional view illustrating the example of the semiconductor device.

FIGS. 2A and 2B are cross-sectional views illustrating the example of the semiconductor device.

FIG. 3A is a plan view illustrating an example of a semiconductor device, and FIG. 3B is a cross-sectional view illustrating the example of the semiconductor device.

FIGS. 4A and 4B are cross-sectional views illustrating the example of the semiconductor device.

FIG. 5A is a plan view illustrating an example of a semiconductor device, and FIG. 5B is a cross-sectional view illustrating the example of the semiconductor device.

FIGS. 6A and 6B are cross-sectional views illustrating the example of the semiconductor device.

FIGS. 7A and 7B are cross-sectional views each illustrating an example of a semiconductor device.

FIGS. 8A and 8B are cross-sectional views each illustrating an example of a semiconductor device.

FIGS. 9A and 9B are cross-sectional views each illustrating an example of a semiconductor device.

FIGS. 10A and 10B are cross-sectional views each illustrating an example of a semiconductor device.

FIGS. 11A to 11C are cross-sectional views illustrating an example of a method for manufacturing a semiconductor device.

FIGS. 12A to 12C are cross-sectional views illustrating the example of the method for manufacturing the semiconductor device.

FIGS. 13A to 13C are cross-sectional views illustrating the example of the method for manufacturing the semiconductor device.

FIGS. 14A to 14C are cross-sectional views illustrating an example of a method for manufacturing a semiconductor device.

FIGS. 15A to 15C are cross-sectional views illustrating the example of the method for manufacturing the semiconductor device.

FIGS. 16A to 16C are cross-sectional views illustrating the example of the method for manufacturing the semiconductor device.

FIGS. 17A and 17B are cross-sectional views illustrating the example of the method for manufacturing the semiconductor device.

FIG. 18 is a block diagram illustrating a structure example of a semiconductor device.

FIGS. 19A to 19D each illustrate a circuit structure example of a memory cell.

FIGS. 20A to 20D each illustrate a circuit structure example of a memory cell.

FIGS. 21A and 21B are perspective views each illustrating a structure example of a semiconductor device.

FIG. 22 is a block diagram illustrating a CPU.

FIGS. 23A and 23B are perspective views illustrating a semiconductor device.

FIGS. 24A and 24B are perspective views each illustrating a semiconductor device.

FIGS. 25A and 25B each illustrate a hierarchy of various memory devices.

FIGS. 26A and 26B each illustrate an example of an electronic device, and FIGS. 26C to 26E illustrate an example of a large computer.

FIG. 27 illustrates an example of a device for space.

FIG. 28 illustrates an example of a storage system that can be used in a data center.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Moreover, some components may be omitted particularly in a plan view, a perspective view, or the like for easy understanding of the invention. In addition, some hidden lines might not be shown.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

Note that the terms “film” and “layer” can be interchanged with each other. For example, the term “conductive layer” can be replaced with the term “conductive film”. As another example, the term “insulating film” can be replaced with the term “insulating layer”. The term “conductor” can be replaced with the term “conductive layer” or “conductive film”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 850 and less than or equal to 950 is also included. In addition, the term “substantially perpendicular” indicates that the angle formed between two straight lines is greater than or equal to 600 and less than or equal to 120°.

The term “opening” includes a groove, a slit, a depressed portion, and the like. A region where an opening is formed may be referred to as an opening portion.

In the drawings used in embodiments, a sidewall of an insulator in an opening portion is perpendicular or substantially perpendicular to a substrate surface or a formation surface, but the sidewall may have a tapered shape.

Note that in this specification and the like, a tapered shape refers to a shape such that at least part of a side surface of a component is inclined with respect to a substrate surface or a formation surface of the component. For example, a tapered shape refers to a shape including a region where the angle formed between the inclined side surface and the substrate surface or the formation surface of the component (hereinafter, such an angle is referred to as a taper angle in some cases) is less than 90°. Note that the side surface of the component, the substrate surface, and the formation surface are not necessarily completely flat and may be substantially flat with a slight curvature or with slight unevenness.

Note that in this specification and the like, the expression “level with” indicates a structure having the same level from a reference surface (e.g., a flat surface such as a substrate surface). For example, in a manufacturing process of a memory device, planarization treatment (typically, chemical mechanical polishing (CMP) treatment) is performed, whereby the surface(s) of a single layer or a plurality of layers are exposed in some cases. In this case, the surfaces on which the CMP treatment is performed are at the same level from a reference surface. Note that a plurality of layers may be at different levels depending on a treatment apparatus, a treatment method, or a material of the treated surfaces, used for the CMP treatment. This case is also regarded as being “level with” in this specification and the like.

In this specification and the like, the expression “top surface shapes (also referred to as shapes in a plan view or outline shapes) are the same” means that at least outlines of stacked layers partly overlap with each other. For example, the expression includes the case of patterning or partly patterning an upper layer and a lower layer with the use of the same mask pattern. The expression “top surface shapes are the same” also includes the case where the outlines do not exactly overlap with each other and the outline of the upper layer is positioned inward or outward from the outline of the lower layer.

Note that in this specification and the like, a top surface shape of a component means an outline shape of the component in a plan view. A plan view means that the component is observed from a direction normal to a surface where the component is formed or from a direction normal to a surface of a support (e.g., a substrate) where the component is formed.

In general, it is difficult to clearly differentiate “completely the same” from “substantially the same”. Thus, in this specification and the like, the expression “the same” includes both “completely the same” and “substantially the same”.

Note that in this specification and the like, the term “island shape” refers to a state where two or more layers are physically separated from each other.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values, and a potential supplied to a wiring, a potential applied to a circuit and the like, and a potential output from a circuit and the like, for example, are changed with a change of the reference potential.

### Embodiment 1

In this embodiment, a transistor of one embodiment of the present invention and a method for manufacturing the transistor are described.

One embodiment of the present invention is a semiconductor device including a transistor whose channel is placed in the vertical direction. That is, the transistor has a structure in which a source electrode and a drain electrode overlap with each other at different heights from a substrate surface and a drain current flows in a height direction (the vertical direction). Thus, the transistor can be miniaturized as compared with a transistor having a structure in which a source electrode and a drain electrode are provided on the same plane. The above-described structure of the transistor enables miniaturization and high integration of the semiconductor device.

The transistor of one embodiment of the present invention includes a first insulating layer between the source electrode and the drain electrode. That is, the first insulating layer is provided over one of the source and drain electrodes, and the other of the source and drain electrodes is provided over the first insulating layer.

The other of the source and drain electrodes of the transistor and the first insulating layer are provided with a first opening reaching one of the source and drain electrodes of the transistor. A semiconductor layer of the transistor is provided to cover a sidewall and a bottom surface of the first opening, and a gate insulating layer (a first gate insulating layer) of the transistor is provided over the semiconductor layer. A gate electrode (a first gate electrode) of the transistor is provided over the gate insulating layer to fill the first opening. Inside the first opening, the semiconductor layer includes a region that faces the gate electrode with the gate insulating layer therebetween.

The first insulating layer is provided with a depressed portion or a second opening that surrounds the first opening in a plan view. A second gate electrode (also referred to as a back gate electrode) of the transistor is provided to fill the depressed portion or the second opening.

A second gate insulating layer of the transistor is provided between the semiconductor layer covering the sidewall of the first opening and the second gate electrode provided in the depressed portion or the second opening. The semiconductor layer covering the sidewall of the first opening includes a region that faces the second gate electrode with the second gate insulating layer therebetween.

That is, in the transistor of one embodiment of the present invention, the semiconductor layer includes a region sandwiched between the two gate electrodes. The region can function as a channel formation region of the transistor. Accordingly, the influence of a gate electric field on carriers in the channel formation region can be increased as compared with a transistor including only one gate electrode. This enables a threshold voltage to be shifted to easily achieve normally-off characteristics of the transistor, for example.

The second gate electrode is provided to surround the semiconductor layer with the second gate insulating layer therebetween in a plan view. Thus, the region that can function as the channel formation region in the semiconductor layer can be surrounded by an electric field from the second gate electrode, so that the transistor can have what is called a gate-all-around (GAA) structure. Thus, an on-state current can be increased as compared with a transistor including only the first gate electrode.

The second gate insulating layer positioned between the semiconductor layer and the second gate electrode may be formed using part of the first insulating layer or may be formed using a second insulating layer provided separately from the first insulating layer. In the transistor of one embodiment of the present invention, the second gate insulating layer contains oxygen. In addition, the second gate insulating layer releases oxygen. Thus, in the case where the first insulating layer is formed using a material containing oxygen, for example, the oxygen can be supplied to the semiconductor layer through the second gate insulating layer. In addition, oxygen contained in the second gate insulating layer itself can be supplied to the semiconductor layer. Accordingly, in the case of using a metal oxide (also referred to as an oxide semiconductor) as a material of the semiconductor layer, for example, oxygen vacancies in the metal oxide can be repaired, and the electrical characteristics and reliability of the transistor can be improved. As a specific example, the transistor can have a high on-state current. As another example, the transistor can have a low off-state current. As another example, the transistor can have normally-off characteristics.

As described above, in the transistor of one embodiment of the present invention, the second gate electrode is provided to fill the depressed portion or the second opening formed in the first insulating layer. Thus, the second gate electrode can be formed using what is called a damascene process. With the use of the damascene process, the second gate electrode can be formed in the first insulating layer in a self-aligned manner; thus, the second gate electrode can be accurately formed even in a miniaturized transistor. Thus, a method for manufacturing a semiconductor device with a small variation in electrical characteristics of transistors and with high productivity can be provided.

The transistor whose channel is placed in the vertical direction normally occupies a larger area because of its structure where the second gate electrode is provided. However, since the second gate electrode is provided to fill the depressed portion or the opening that is formed in the first insulating layer to surround the semiconductor layer, the area occupied by the transistor can be adjusted by narrowing the width of the depressed portion or the opening in a plan view. This can inhibit a significant increase in the area occupied by the transistor.

Specific structure examples of the transistor of one embodiment of the present invention are hereinafter described.

### Structure Example 1

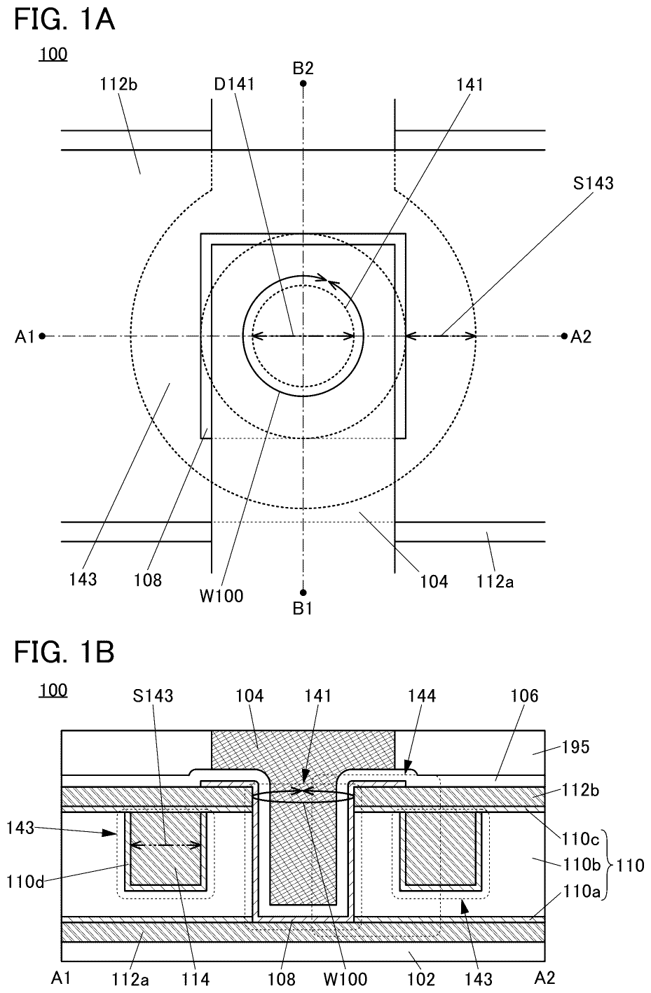

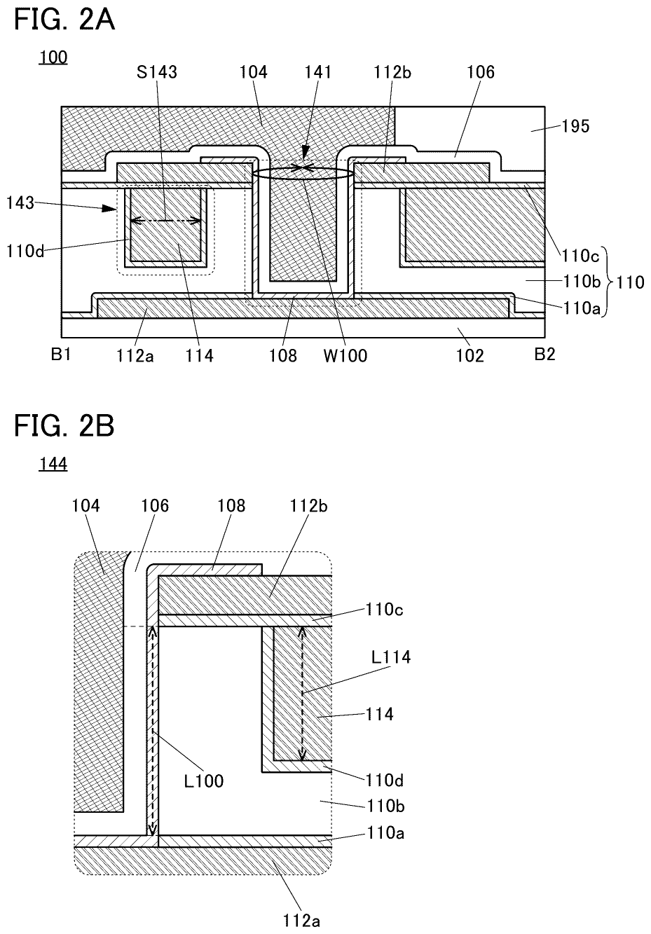

FIG. 1A is a plan view (also referred to as a top view) of a transistor 100. FIG. 1B is a cross-sectional view taken along dashed-dotted line A1-A2 in FIG. 1A, and FIG. 2A is a cross-sectional view taken along dashed-dotted line B1-B2 in FIG. 1A. FIG. 2B is an enlarged view of a region 144 illustrated in FIG. 1B. Note that some components of the transistor 100 (e.g., an insulating layer) are not illustrated in FIG. 1A. Some components are not illustrated in plan views of transistors and the like in the following drawings, as in FIG. 1A.

FIG. 1B or the like illustrates an example in which the transistor 100 is provided over a substrate 102. The transistor 100 includes a conductive layer 104, an insulating layer 106, a semiconductor layer 108, a conductive layer 112a, a conductive layer 112b, an insulating layer 110 (an insulating layer 110a, an insulating layer 110b, and an insulating layer 110c), an insulating layer 110d, and a conductive layer 114. The conductive layer 104 functions as a first gate electrode. Part of the insulating layer 106 functions as a first gate insulating layer. The conductive layer 112a functions as one of source and drain electrodes, and the conductive layer 112b functions as the other of the source and drain electrodes. The conductive layer 114 functions as a second gate electrode. Part of the insulating layer 110 and part of the insulating layer 110d function as a second gate insulating layer. In the semiconductor layer 108, the whole region that is between the source electrode and the drain electrode and faces the first gate electrode with the first gate insulating layer therebetween can function as a channel formation region. In the semiconductor layer 108, the whole region that is between the source electrode and the drain electrode and faces the second gate electrode with the second gate insulating layer therebetween can function as a channel formation region. In the semiconductor layer 108, a region in contact with the source electrode functions as a source region, and a region in contact with the drain electrode functions as a drain region.

As illustrated in FIGS. 1B and 2A, the conductive layer 112a is provided over the substrate 102. The insulating layer 110 (the insulating layer 110a, the insulating layer 110b, and the insulating layer 110c) is provided over the conductive layer 112a. The conductive layer 114 is provided so as to be embedded in the insulating layer 110b. The side surface and the bottom surface of the conductive layer 114 are covered with the insulating layer 110d. The top surface of the conductive layer 114 and the top surface of the insulating layer 110b are level with each other. The conductive layer 112b is provided over the insulating layer 110, the insulating layer 110d, and the conductive layer 114.

An opening 141 reaching the conductive layer 112a is provided in the insulating layer 110 and the conductive layer 112b. The opening 141 has a circular shape in a plan view (see FIG. 1A). In FIG. 1A, the opening 141 is illustrated as a circular shape having a center at the intersection of the dashed-dotted line A1-A2 and the dashed-dotted line B1-B2 and having a diameter of a width D141.

The semiconductor layer 108 is provided in contact with the top surface of the conductive layer 112a inside the opening 141, the side surface of the insulating layer 110 inside the opening 141, the side surface of the conductive layer 112b inside the opening 141, and the top surface of the conductive layer 112b. The insulating layer 106 is provided in contact with the top surface of the semiconductor layer 108 inside the opening 141, the side surface of the semiconductor layer 108 inside the opening 141, the top surface of the semiconductor layer 108 outside the opening 141, the side surface of the semiconductor layer 108 outside the opening 141, and the top surface of the conductive layer 112b. The semiconductor layer 108 and the insulating layer 106 each have a shape reflecting the shape of the opening 141 (a shape along the sidewall and the bottom surface of the opening 141) inside the opening 141. The conductive layer 104 is provided over the insulating layer 106 to fill the opening 141. The conductive layer 104 includes a region overlapping with the top surface of the semiconductor layer 108 in a plan view. Inside the opening 141, the conductive layer 104 faces the semiconductor layer 108 with the insulating layer 106 therebetween.

A depressed portion 143 is provided in the insulating layer 110b. The depressed portion 143 includes a region having a ring-like shape including an inner perimeter and an outer perimeter of a circular shape with a width S143 and enclosing the opening 141 in a plan view (see FIG. 1A). In other words, the depressed portion 143 is provided to surround the opening 141.

The insulating layer 110d is provided in contact with the top surface and the side surface of the insulating layer 110b inside the depressed portion 143. The insulating layer 110d has a shape reflecting the shape of the depressed portion 143 (a shape along the sidewall and the bottom surface of the depressed portion 143) inside the depressed portion 143. The conductive layer 114 is provided over the insulating layer 110d to fill the depressed portion 143. The conductive layer 114 faces the semiconductor layer 108 with the insulating layer 110d, which is in contact with the side surface of the insulating layer 110b inside the depressed portion 143, and the insulating layer 110b, which is positioned between the opening 141 and the depressed portion 143, therebetween.

The insulating layer 110a is provided under the insulating layer 110b in contact with the top surface of the conductive layer 112a. Over the insulating layer 110b, the insulating layer 110c is provided in contact with the bottom surface of the conductive layer 112b. That is, the insulating layer 110a, the insulating layer 110b, and the insulating layer 110c are stacked in this order between the conductive layer 112a and the conductive layer 112b. The insulating layer 110c is provided in contact with the top surface of the insulating layer 110b and the top surface of the conductive layer 114.

As described above, the conductive layer 104 in the transistor 100 functions as the first gate electrode. In the insulating layer 106, a region sandwiched between the conductive layer 104 and the semiconductor layer 108 in contact with the side surface of the insulating layer 110 inside the opening 141 can function as the first gate insulating layer. In the semiconductor layer 108, a region facing the conductive layer 104 with the first gate insulating layer therebetween can function as the channel formation region.

As described above, the conductive layer 114 in the transistor 100 functions as the second gate electrode. In the insulating layer 110b and the insulating layer 110d, a region sandwiched between the opening 141 and the depressed portion 143 in a plan view can function as the second gate insulating layer. In the semiconductor layer 108, a region facing the conductive layer 114 with the second gate insulating layer therebetween can function as the channel formation region. In FIG. 2B, a length L114 of the conductive layer 114 functioning as the second gate electrode is indicated by a dashed double-headed arrow.

As illustrated in FIGS. 1B and 2A, the conductive layer 104 and the conductive layer 114 face each other in a cross-sectional view perpendicular to a substrate surface. Part of the insulating layer 110d, part of the insulating layer 110b, part of the semiconductor layer 108, and part of the insulating layer 106 are sandwiched between the conductive layer 104 and the conductive layer 114 in the cross-sectional view perpendicular to the substrate surface. Inside the opening 141, one side of the semiconductor layer 108 faces the conductive layer 104 with the insulating layer 106 therebetween, and the other side of the semiconductor layer 108 faces the conductive layer 114 with the insulating layer 110b and the insulating layer 110d therebetween.

As described above, the transistor 100 includes the two gate electrodes (the conductive layer 104 and the conductive layer 114) between which the semiconductor layer 108 is sandwiched. Since the transistor 100 includes the conductive layer 114 functioning as the second gate electrode, a potential of a region of the semiconductor layer 108 on the side facing the conductive layer 114 (also referred to as a back channel formation region) can be fixed. Thus, a threshold voltage of the transistor 100 can be shifted to achieve normally-off characteristics of the transistor more easily than in the case of not including the second gate electrode. In addition, the saturation of the drain current (I_{d})-drain voltage (V_{d}) characteristics of the transistor 100 can be improved. Note that in this specification and the like, the state where the change in a current is small (i.e., the slope of the curve of the current is gentle) in the saturation region of the I_{d}—V_{d} characteristics of a transistor is sometimes described using the expression “favorable saturation”.

The conductive layer 114 functioning as the second gate electrode of the transistor 100 is shaped to surround the semiconductor layer 108 in a plan view. Accordingly, the region that can function as the channel formation region in the semiconductor layer 108 can be surrounded by an electric field from the second gate electrode. Thus, the transistor can have a GAA structure and can have a higher on-state current than a transistor including only the first gate electrode (the conductive layer 104).

The conductive layer 114 is provided to fill the depressed portion 143 formed in the insulating layer 110b. Thus, the conductive layer 114 can be formed using a damascene process. With the use of the damascene process, the conductive layer 114 can be formed in the insulating layer 110b in a self-aligned manner; thus, the second gate electrode can be accurately formed even in a miniaturized transistor. Thus, a semiconductor device including miniaturized transistors with a small variation in electrical characteristics can be obtained. In particular, in a transistor whose channel is placed in the vertical direction as in the transistor 100, the conductive layer 114 needs to be formed in the insulating layer 110b having a significantly small thickness. Thus, the conductive layer 114 is preferably formed using the damascene process, in which case the second gate electrode can be accurately formed even in a transistor whose channel is placed in the vertical direction and has a short channel length as in the transistor 100.

When a potential at which the transistor is turned on is applied to the second gate electrode, the field-effect mobility of the transistor can be increased. By changing the level of the potential applied to the second gate electrode, the threshold voltage of the transistor can be changed. The potential applied to the second gate electrode can be equal to a potential applied to the first gate electrode. Alternatively, the potential applied to the second gate electrode may be a ground potential or a given potential. Alternatively, the potential applied to the second gate electrode may be equal to a potential applied to the source electrode or the drain electrode.

In the case where the same potential is applied to the second gate electrode and the first gate electrode, the second gate electrode and the first gate electrode are connected to each other to establish electrical continuity. In the case where the same potential is applied to the second gate electrode and the source or drain electrode, the second gate electrode and the source or drain electrode are connected to each other to establish electrical continuity. When the first gate electrode or the second gate electrode is connected to the source electrode, the reliability of the transistor can be increased, for example. When the first gate electrode or the second gate electrode is connected to the drain electrode, the transistor can function as a diode, for example.

The second gate electrode and the first gate electrode are not necessarily connected to each other, and a potential may be individually applied to each gate electrode.

The transistor whose channel is placed in the vertical direction normally occupies a larger area because of its structure where the second gate electrode is provided. However, when the conductive layer 114 is formed to fill the depressed portion 143 provided in the insulating layer 110 and is used as the second gate electrode as in the transistor 100, the second gate electrode can be accurately formed, and the area occupied by the transistor can be inhibited from increasing significantly. For example, the area occupied by the transistor 100 can be adjusted by narrowing the width S143 of the depressed portion 143 and providing the second gate electrode therein. This can inhibit the area occupied by the transistor from being significantly increased by providing the second gate electrode.

An insulating layer 195 is provided over the insulating layer 106. The insulating layer 195 functions as a protective layer for the transistor 100. The conductive layer 104 is provided so as to be embedded in the insulating layer 195. The top surface of the insulating layer 195 and the top surface of the conductive layer 104 are level with each other.

In the transistor of one embodiment of the present invention, the source electrode and the drain electrode are positioned at different heights from the substrate surface as illustrated in FIG. 1B or the like, so that a drain current flows in the height direction (the vertical direction). Accordingly, the transistor of one embodiment of the present invention can also be referred to as a vertical transistor, a vertical-channel transistor, a vertical field-effect transistor (VFET), or the like.

In the transistor 100, the top surface of the conductive layer 112a functioning as one of the source and drain electrodes and the top surface of the conductive layer 112b functioning as the other of the source and drain electrodes are both in contact with the bottom surface of the semiconductor layer 108 (a surface on the substrate 102 side). Thus, the transistor 100 can also be referred to as a bottom-contact transistor.

Next, the channel length and the channel width of the transistor 100 are described.

The channel length of the transistor 100 is a distance between the source region and the drain region. In FIG. 2B, a channel length L100 of the transistor 100 is indicated by a dashed double-headed arrow. The channel length L100 can also be regarded as a length along the side surface of the insulating layer 110 in contact with the semiconductor layer 108 between the source electrode and the drain electrode.

The insulating layer 110 illustrated in FIG. 1B or the like has a stacked-layer structure of the insulating layer 110a, the insulating layer 110b over the insulating layer 110a, and the insulating layer 110c over the insulating layer 110b, for example. Accordingly, the channel length L100 of the transistor 100 can be regarded as the sum of the length of the side surface of the insulating layer 110a in contact with the semiconductor layer 108, the length of the side surface of the insulating layer 110b in contact with the semiconductor layer 108, and the length of the side surface of the insulating layer 110c in contact with the semiconductor layer 108. The channel length L100 of the transistor 100 may be regarded as the length of the side surface of the insulating layer 110b in contact with the semiconductor layer 108.

In the case where the insulating layer 110 has the stacked-layer structure of the insulating layer 110a, the insulating layer 110b over the insulating layer 110a, and the insulating layer 110c over the insulating layer 110b as illustrated in FIG. 1B or the like, a region of the semiconductor layer 108 in contact with the insulating layer 110a and a region of the semiconductor layer 108 in contact with the insulating layer 110c may have a lower resistance than a region of the semiconductor layer 108 in contact with the insulating layer 110b, depending on the material of the semiconductor layer 108 and the materials of the insulating layer 110a and the insulating layer 110c.

In one embodiment of the present invention, an insulating layer that contains oxygen and releases oxygen is used as the insulating layer 110b. Meanwhile, insulating layers that inhibit diffusion of oxygen are used as the insulating layer 110a and the insulating layer 110c. Thus, in the case where a metal oxide is used as the material of the semiconductor layer 108, for example, the region of the semiconductor layer 108 in contact with the insulating layer 110b can be a highly purified intrinsic or substantially highly purified intrinsic region because oxygen vacancies are repaired with oxygen supplied from the insulating layer 110b. In contrast, unlike the region of the semiconductor layer 108 in contact with the insulating layer 110b, the region of the semiconductor layer 108 in contact with the insulating layer 110a and the region of the semiconductor layer 108 in contact with the insulating layer 110c are not supplied with oxygen; thus, oxygen vacancies are not repaired in those regions. Accordingly, the region of the semiconductor layer 108 in contact with the insulating layer 110a and the region of the semiconductor layer 108 in contact with the insulating layer 110c have a lower resistance than the region of the semiconductor layer 108 in contact with the insulating layer 110b. Thus, the region of the semiconductor layer 108 in contact with the insulating layer 110a can also be regarded as part of one of the source and drain regions. In addition, the region of the semiconductor layer 108 in contact with the insulating layer 110c can also be regarded as part of the other of the source and drain regions.

Therefore, the region of the semiconductor layer 108 in contact with the insulating layer 110b is defined as the channel formation region of the transistor 100, and the channel length L100 is illustrated as the length of the semiconductor layer 108 along the side surface of the insulating layer 110b.

Here, the channel length L100 of the transistor 100 is determined by, for example, the thickness of the insulating layer 110 (the insulating layer 110a, the insulating layer 110b, and the insulating layer 110c) on its formation surface and the angle formed between the side surface of the insulating layer 110 and the surface on which the insulating layer 110a is formed (the top surface of the conductive layer 112a), and is not affected by the performance of a light-exposure apparatus used for manufacturing the transistor. Thus, the channel length L100 can be a value smaller than that of the resolution limit of a light-exposure apparatus, which enables the transistor to have a minute size.

Note that FIG. 2B or the like illustrates an example in which the side surface of the insulating layer 110 is perpendicular to the formation surface of the insulating layer 110 (the top surface of the conductive layer 112a). In this case, the area occupied by the transistor in a plan view can be decreased, which is preferable. Meanwhile, in the case where the side surface of the insulating layer 110 has a tapered shape with respect to the formation surface of the insulating layer 110, the coverage of a layer (e.g., the semiconductor layer 108) provided in contact with the side surface of the insulating layer 110 inside the opening 141 can be improved, which is preferable. In the transistor of one embodiment of the present invention, the side surface of the insulating layer 110 can be perpendicular to the formation surface of the insulating layer 110. Alternatively, the side surface of the insulating layer 110 can be inclined with respect to the formation surface of the insulating layer 110.

An electric field generated from the conductive layer 114 functioning as the second gate electrode of the transistor 100 toward the semiconductor layer 108 side is preferably applied to at least half or more of the back channel formation region. In that case, in the back channel formation region, the area of a region to which the electric field from the conductive layer 114 is applied can be made larger than the area of a region to which the electric field from the conductive layer 114 is not applied. This enables the threshold voltage of the transistor to be shifted to easily achieve normally-off characteristics. For example, the length L114 of the conductive layer 114 illustrated in FIG. 2B is preferably at least half or more of the channel length L100 of the transistor 100. That is, the length L114 is preferably greater than or equal to 0.5 times as large as the channel length L100, further preferably 0.5 to 1.0 times as large as the channel length L100. Accordingly, the effect of the conductive layer 114 functioning as the second gate electrode can be further enhanced.

The channel length L100 is preferably greater than or equal to 1 nm and less than or equal to 2 μm, greater than or equal to 2 nm and less than or equal to 2 μm, greater than or equal to 3 nm and less than or equal to 1 μm, greater than or equal to 5 nm and less than or equal to 750 nm, greater than or equal to 10 nm and less than or equal to 500 nm, greater than or equal to 10 nm and less than or equal to 400 nm, greater than or equal to 10 nm and less than or equal to 300 nm, greater than or equal to 10 nm and less than or equal to 200 nm, or greater than or equal to 10 nm and less than or equal to 100 nm, for example.

When the channel length L100 is small, the transistor 100 can have a high on-state current. With the use of the transistor 100 with a high on-state current, a circuit capable of high-speed operation can be manufactured. Furthermore, the area occupied by a circuit can be reduced. Accordingly, when the transistor of one embodiment of the present invention is used in a semiconductor device, the semiconductor device can be downsized.

For example, when the transistor of one embodiment of the present invention is used in a memory device, the memory device can be highly integrated and downsized. In addition, the memory device can achieve high-speed data writing and reading.

In general, a transistor with a short channel length tends to have poor saturation of I_{d}—V_{d} characteristics. However, the transistor of one embodiment of the present invention can have favorable saturation because of including the second gate electrode. Accordingly, the transistor of one embodiment of the present invention can achieve both high on-state current and favorable saturation.

The channel width of the transistor 100 is the length of the source region or the length of the drain region in a plan view. It can also be said that the channel width of the transistor 100 is the perimeter of the outline of the channel formation region. In other words, the channel width is the length of a region where the semiconductor layer 108 is in contact with the conductive layer 112a or the length of a region where the semiconductor layer 108 is in contact with the conductive layer 112b in a plan view.

In the transistor 100, the semiconductor layer 108 is provided along the top surface of the conductive layer 112a inside the opening 141, the side surface of the insulating layer 110 inside the opening 141, and the side surface of the conductive layer 112b inside the opening 141. Thus, the perimeter of the opening 141 in a plan view is sometimes used as the channel width of the transistor 100.

Here, the channel width of the transistor 100 is described as the length of the region where the semiconductor layer 108 is in contact with the conductive layer 112b in a plan view. In FIGS. 1A, 1, and 2A, a channel width W100 of the transistor 100 is indicated by a solid double-headed arrow. The channel width W100 corresponds to the perimeter of the opening 141 in a plan view.

The channel width W100 is determined by the top surface shape of the opening 141. In FIG. 1A, the width D141 corresponding to the diameter of the opening 141 of a circular shape is indicated by a dashed double-dotted double-headed arrow. In the case where the top surface shape of the opening 141 is circular as in the transistor 100, the channel width W100 can be roughly calculated to be “D141×π”.

Although FIG. 1A illustrates an example in which the top surface shape of the opening 141 is circular, one embodiment of the present invention is not limited thereto. The top surface shape of the opening 141 can be a circle (not limited to a perfect circle), an ellipse, a polygon such as a triangle, a quadrangle (including a rectangle, a rhombus, and a square), or a pentagon, or any of these polygons whose corners are rounded, for example. When the opening 141 has any of the above top surface shapes, flexibility in manufacturing the semiconductor device can be increased.

Although FIG. 1A illustrates an example in which the depressed portion 143 includes a region having a ring-like top surface shape including an inner perimeter and an outer perimeter of a circular shape, one embodiment of the present invention is not limited thereto. The depressed portion 143 can include a region having a ring-like top surface shape including an inner perimeter and an outer perimeter of the shape of a circle (not limited to a perfect circle), an ellipse, a polygon such as a triangle, a quadrangle (including a rectangle, a rhombus, and a square), or a pentagon, or any of these polygons whose corners are rounded. When the depressed portion 143 has any of the above top surface shapes, flexibility in manufacturing the semiconductor device can be increased.

Note that the top surface shape of the opening 141 and the top surface shapes of the inner perimeter and the outer perimeter of the depressed portion 143 are preferably the same shape. For example, in the case where the top surface shape of the opening 141 is circular, the top surface shapes of the inner perimeter and the outer perimeter of the depressed portion 143 are also preferably circular, and in the case where the top surface shape of the opening 141 is quadrangular, the top surface shapes of the inner perimeter and the outer perimeter of the depressed portion 143 are also preferably quadrangular. In a plan view, the center of the opening 141 and the centers of the inner perimeter and the outer perimeter of the depressed portion 143 preferably coincide with each other to the extent possible. This enables the second gate insulating layer in the transistor of one embodiment of the present invention to have a uniform thickness. Thus, the electric field from the conductive layer 114 functioning as the second gate electrode can be uniformly applied to the back channel formation region of the semiconductor layer 108 that faces the conductive layer 114. As a result, the transistor can have stable electrical characteristics and reliability.

As described above, the channel length of the transistor of one embodiment of the present invention can be set to a significantly small value by controlling the thickness of the insulating layer 110, for example. In addition, the channel width of the transistor can be set to a significantly large value by controlling the perimeter of the opening 141 in a plan view, without considerably increasing the area occupied by the transistor within a substrate plane. Therefore, the transistor 100 can have a higher on-state current.

As described above, part of the insulating layer 110 (the insulating layer 110a, the insulating layer 110b, and the insulating layer 110c) and part of the insulating layer 110d function as the second gate insulating layer in the transistor 100. Among these insulating layers, the insulating layer 110b has a large contact area with the semiconductor layer 108 as illustrated in FIG. 2B or the like. In one embodiment of the present invention, the insulating layer 110b preferably contains oxygen. The insulating layer 110b also preferably releases oxygen. In that case, oxygen contained in the insulating layer 110b can be efficiently supplied into the semiconductor layer 108 by heat treatment or the like in the manufacturing process of the transistor 100. Accordingly, in the case where a metal oxide is used as the material of the semiconductor layer 108, for example, oxygen vacancies in the metal oxide can be repaired. Thus, the insulating layer 110b of the transistor 100 preferably has a function of the second gate insulating layer and a function of supplying oxygen to the semiconductor layer 108. As a result, the transistor 100 can have excellent electrical characteristics and high reliability.

Materials that can be used for the transistor of one embodiment of the present invention and the semiconductor device including the transistor of one embodiment of the present invention are described below.

### [Semiconductor Layer 108]

A semiconductor material that can be used for the semiconductor layer 108 is not particularly limited. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics can be used. These semiconductor materials may contain an impurity as a dopant.

There is no particular limitation on the crystallinity of the semiconductor material used for the semiconductor layer 108, and an amorphous semiconductor or a semiconductor having crystallinity (a single-crystal semiconductor, a polycrystalline semiconductor, a microcrystalline semiconductor, or a semiconductor partly including crystal regions) may be used. A semiconductor having crystallinity is preferably used, in which case deterioration of transistor characteristics can be inhibited.

For the semiconductor layer 108, silicon can be used. Examples of silicon include single crystal silicon, polycrystalline silicon, microcrystalline silicon, and amorphous silicon. An example of polycrystalline silicon is low-temperature polysilicon (LTPS).

The transistor including amorphous silicon in the semiconductor layer 108 can be formed over a large-sized glass substrate, thereby reducing the manufacturing cost. The transistor including polycrystalline silicon in the semiconductor layer 108 has a high field-effect mobility and a high operation speed. The transistor including microcrystalline silicon in the semiconductor layer 108 has a higher field-effect mobility and a higher operation speed than the transistor including amorphous silicon.

The semiconductor layer 108 preferably contains a metal oxide. Examples of the metal oxide that can be used for the semiconductor layer 108 include indium oxide, gallium oxide, and zinc oxide. The metal oxide preferably contains at least indium or zinc. The metal oxide preferably contains two or three selected from indium, an element M, and zinc. The element M is a metal element or a metalloid element that has a high bonding energy with oxygen, such as a metal element or a metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, the semiconductor layer 108 can be formed using indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide), indium aluminum zinc oxide (In—Al—Zn oxide, also referred to as IAZO), indium tin zinc oxide (In—Sn—Zn oxide, also referred to as ITZO (registered trademark)), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO, IGZAO, or IAGZO). Alternatively, indium tin oxide containing silicon, gallium tin oxide (Ga—Sn oxide), aluminum tin oxide (Al—Sn oxide), or the like can be used.

A sputtering method or an atomic layer deposition (ALD) method can be suitably used for forming a film of the metal oxide. Note that in the case where the metal oxide film is formed by a sputtering method, the atomic ratio in a target may be different from the atomic ratio in the metal oxide. In particular, the atomic ratio of zinc in the metal oxide is lower than that in the target in some cases. Specifically, the atomic ratio of zinc in the metal oxide may be approximately higher than or equal to 40% and lower than or equal to 90% of the atomic ratio of zinc in the target.

Specific examples of ALD methods used to form the semiconductor layer 108 include film formation methods such as a thermal ALD method and a plasma enhanced ALD (PEALD) method. The thermal ALD method is preferable because of its capability of forming a film with extremely high step coverage. The PEALD method is preferable because of its capability of forming a film at low temperatures, in addition to its capability of forming a film with high step coverage.

The composition of the metal oxide contained in the semiconductor layer 108 significantly affects the electrical characteristics and reliability of the transistor 100.

For example, a metal oxide with a higher indium content enables the transistor to have a higher on-state current.

In the case where In—Zn oxide is used for the semiconductor layer 108, it is preferable to use a metal oxide in which the atomic ratio of indium is higher than or equal to that of zinc. For example, a metal oxide with metal elements in an atomic ratio of In:Zn=1:1, In:Zn=2:1, In:Zn=3:1, In:Zn=4:1, In:Zn=5:1, In:Zn=7:1, In:Zn=10:1, or the neighborhood thereof can be used.

In the case where In—Sn oxide is used for the semiconductor layer 108, it is preferable to use a metal oxide in which the atomic ratio of indium is higher than or equal to that of tin. For example, a metal oxide with metal elements in an atomic ratio of In:Sn=1:1, In:Sn=2:1, In:Sn=3:1, In:Sn=4:1, In:Sn=5:1, In:Sn=7:1, In:Sn=10:1, or the neighborhood thereof can be used.

In the case where In-M-Zn oxide is used for the semiconductor layer 108, it is possible to use a metal oxide in which the atomic ratio of indium is higher than that of the element M. Furthermore, it is preferable to use a metal oxide in which the atomic ratio of zinc is higher than that of the element M. For example, a metal oxide with metal elements in an atomic ratio of In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the neighborhood thereof can be used for the semiconductor layer 108.

In the case where a plurality of metal elements are contained as the element M, the sum of the atomic ratios of the metal elements can be the atomic ratio of the element M. In In—Ga—Al—Zn oxide where gallium and aluminum are contained as the element M, for example, the sum of the atomic ratios of gallium and aluminum can be the atomic ratio of the element M. The atomic ratio of indium to the element M and zinc is preferably within the range given above. In In—Ga—Sn—Zn oxide where gallium and tin are contained as the element M, for example, the sum of the atomic ratios of gallium and tin can be the atomic ratio of the element M. The atomic ratio of indium to the element M and zinc is preferably within the range given above.

The proportion of the number of indium atoms to the number of atoms of the metal elements contained in the metal oxide can be, for example, higher than or equal to 30 atomic % and lower than or equal to 100 atomic %, higher than or equal to 30 atomic % and lower than or equal to 95 atomic %, higher than or equal to 35 atomic % and lower than or equal to 95 atomic %, higher than or equal to 35 atomic % and lower than or equal to 90 atomic %, higher than or equal to 40 atomic % and lower than or equal to 90 atomic %, higher than or equal to 45 atomic % and lower than or equal to 90 atomic %, higher than or equal to 50 atomic % and lower than or equal to 80 atomic %, higher than or equal to 60 atomic % and lower than or equal to 80 atomic %, or higher than or equal to 70 atomic % and lower than or equal to 80 atomic %. For example, when In—Ga—Zn oxide is used for the semiconductor layer 108, the proportion of the number of indium atoms to the sum of the numbers of indium atoms, atoms of the element M, and zinc atoms is preferably within the ranges given above.

In this specification and the like, the proportion of the number of indium atoms to the number of atoms of the metal elements contained is sometimes referred to as indium content. The same applies to other metal elements.

A metal oxide with a higher indium content enables the transistor to have a higher on-state current. By using such a transistor as a transistor required to have a high on-state current, a semiconductor device having excellent electrical characteristics can be provided.

The composition of the metal oxide can be analyzed by energy dispersive X-ray spectroscopy (EDX), X-ray photoelectron spectroscopy (XPS), inductively coupled plasma-mass spectrometry (ICP-MS), inductively coupled plasma-atomic emission spectrometry (ICP-AES), or the like, for example. Alternatively, any of these methods may be combined with each other for the analysis. As for an element whose content is low, the actual content may be different from the content obtained by analysis because of the influence of the analysis accuracy. In the case where the content of the element Mis low, for example, the content of the element M obtained by analysis may be lower than the actual content.

In this specification and the like, a composition in the neighborhood includes the range of ±30% of an intended atomic ratio. For example, in the case of describing an atomic ratio of In:M:Zn=4:2:3 or a composition in the neighborhood thereof, the case is included in which with the atomic ratio of indium being 4, the atomic ratio of M is higher than or equal to 1 and lower than or equal to 3 and the atomic ratio of zinc is higher than or equal to 2 and lower than or equal to 4. In the case of describing an atomic ratio of In:M:Zn=5:1:6 or a composition in the neighborhood thereof, the case is included in which with the atomic ratio of indium being 5, the atomic ratio of M is higher than 0.1 and lower than or equal to 2 and the atomic ratio of zinc is higher than or equal to 5 and lower than or equal to 7. In the case of describing an atomic ratio of In:M:Zn=1:1:1 or a composition in the neighborhood thereof, the case is included in which with the atomic ratio of indium being 1, the atomic ratio of M is higher than 0.1 and lower than or equal to 2 and the atomic ratio of zinc is higher than 0.1 and lower than or equal to 2.

Here, the reliability of a transistor is described. One of indexes for evaluating the reliability of a transistor is a gate bias temperature (GBT) stress test in which the transistor is kept at a high temperature with an electric field applied to its gate. The GBT stress test includes a positive bias temperature stress (PBTS) test in which a transistor is kept at a high temperature with a positive potential (positive bias) with respect to a source potential and a drain potential supplied to its gate and a negative bias temperature stress (NBTS) test in which a transistor is kept at a high temperature with a negative potential (negative bias) supplied to its gate. The PBTS test and the NBTS test conducted in a state where irradiation with light is performed are respectively referred to as a positive bias temperature illumination stress (PBTIS) test and a negative bias temperature illumination stress (NBTIS) test.

In an n-channel transistor, a positive potential is supplied to a gate when the transistor becomes an on state (a state in which a current flows); thus, the amount of change in the threshold voltage in a PBTS test is one of important indexes to be focused on as a reliability indicator of the transistor.

With the use of a metal oxide that does not contain gallium or has a low gallium content for the semiconductor layer 108, the transistor can be highly reliable against positive bias application. In other words, the amount of change in the threshold voltage of the transistor in the PBTS test can be small. In the case of using a metal oxide containing gallium, the gallium content is preferably lower than the indium content. As a result, the transistor can have high reliability.

One of the factors changing the threshold voltage in the PBTS test is carrier (here, electron) trapping by defect states at the interface between a semiconductor layer and a gate insulating layer or in the vicinity of the interface. As the density of defect states increases, the number of carriers that are trapped at the above-described interface increases; thus, degradation in the PBTS test becomes more significant. Generation of the defect states can be inhibited and thus change in the threshold voltage in the PBTS test can be inhibited by reducing the gallium content in a region of the semiconductor layer that is in contact with the gate insulating layer.

The following can be given as the reason why the amount of change in the threshold voltage in the PBTS test can be reduced when a metal oxide that does not contain gallium or has a low gallium content is used for the semiconductor layer. Gallium contained in the metal oxide more easily attracts oxygen than another metal element (e.g., indium or zinc). Therefore, when, at the interface between the metal oxide containing a large amount of gallium and the gate insulating layer, gallium is bonded to excess oxygen in the gate insulating layer, carrier (here, electron) trap sites are likely to be generated easily. This might cause the change in the threshold voltage when a positive potential is supplied to a gate and carriers are trapped at the interface between the semiconductor layer and the gate insulating layer.

Specifically, in the case where In—Ga—Zn oxide is used for the semiconductor layer 108, a metal oxide in which the atomic ratio of indium is higher than that of gallium can be used for the semiconductor layer 108. It is preferable to use a metal oxide in which the atomic ratio of zinc is higher than that of gallium. In other words, a metal oxide with metal elements in an atomic ratio satisfying both relationships In>Ga and Zn>Ga is preferably used for the semiconductor layer 108.

In the case where a metal oxide is used for the semiconductor layer 108, the proportion of the number of gallium atoms to the number of atoms of the metal elements contained in the metal oxide is preferably higher than 0 atomic % and lower than or equal to 50 atomic %, further preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content in the semiconductor layer enables the transistor to be highly resistant to the PBTS test. Note that oxygen vacancies (V_{O}) are less likely to be generated in the metal oxide when the metal oxide contains gallium.

A metal oxide that does not contain gallium may be used for the semiconductor layer 108. For example, In—Zn oxide can be used for the semiconductor layer 108. In this case, when the atomic ratio of indium to the metal elements contained in the metal oxide is increased, the field-effect mobility of the transistor can be increased. By contrast, when the atomic ratio of zinc to the metal elements contained in the metal oxide is increased, the metal oxide has high crystallinity; thus, a change in the electrical characteristics of the transistor can be suppressed and the reliability can be increased. A metal oxide that contains neither gallium nor zinc, such as indium oxide, can be used for the semiconductor layer 108. The use of a metal oxide that does not contain gallium can make a change in the threshold voltage particularly in the PBTS test extremely small.

For example, an oxide containing indium and zinc can be used for the semiconductor layer 108. At that time, for example, a metal oxide with metal elements in an atomic ratio of In:Zn=2:3 or the neighborhood thereof can be used.

Although the case of using gallium is described as an example, the same applies in the case where the element M is used instead of gallium. A metal oxide in which the atomic ratio of indium is higher than that of the element M is preferably used for the semiconductor layer 108. Furthermore, a metal oxide in which the atomic ratio of zinc is higher than that of the element Mis preferably used.

With the use of a metal oxide with a low content of the element M for the semiconductor layer 108, the transistor can be highly reliable against positive bias application. With the use of the transistor as a transistor that is required to have high reliability against positive bias application, a highly reliable semiconductor device can be provided.

Next, the reliability of a transistor against light is described.

Light incidence on a transistor may change its electrical characteristics. In particular, a transistor provided in a region on which light can be incident preferably exhibits a small change in electrical characteristics under light irradiation and has high reliability against light. The reliability against light can be evaluated by the amount of change in threshold voltage in a NBTIS test, for example.

The high content of the element M in a metal oxide enables the transistor to be highly reliable against light. That is, the transistor can show a small amount of change in the threshold voltage of the transistor in the NBTIS test. Specifically, in a metal oxide in which the atomic ratio of the element Mis higher than or equal to that of indium, the band gap is increased and accordingly the amount of change in the threshold voltage of the transistor in the NBTIS test can be reduced. The band gap of the metal oxide in the semiconductor layer 108 is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, a metal oxide with metal elements in an atomic ratio of In:M:Zn=1:1:1, In:M:Zn=1:1:1.2, In:M:Zn=1:3:2, In:M:Zn=1:3:3, In:M:Zn=1:3:4, or the neighborhood thereof can be used for the semiconductor layer 108.

In particular, a metal oxide in which the proportion of the number of atoms of the element M to the number of atoms of the metal elements contained in the metal oxide is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic % can be suitably used for the semiconductor layer 108.

In the case where In—Ga—Zn oxide is used for the semiconductor layer 108, a metal oxide in which the atomic ratio of indium is lower than or equal to that of gallium can be used. For example, a metal oxide with metal elements in an atomic ratio of In:Ga:Zn=1:1:1, In:Ga:Zn=1:1:1.2, In:Ga:Zn=1:3:2, In:Ga:Zn=1:3:3, In:Ga:Zn=1:3:4, or the neighborhood thereof can be used.

In particular, a metal oxide in which the proportion of the number of gallium atoms to the number of atoms of the metal elements contained in the metal oxide is higher than or equal to 20 atomic % and lower than or equal to 60 atomic %, preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic % can be suitably used for the semiconductor layer 108.

With the use of a metal oxide with a high content of the element M for the semiconductor layer 108, the transistor can be highly reliable against light. With the use of the transistor as a transistor that is required to have high reliability against light, a highly reliable semiconductor device can be provided.

As described above, electrical characteristics and reliability of a transistor depend on the composition of the metal oxide used for the semiconductor layer 108. Therefore, by changing the composition of the metal oxide in accordance with the electrical characteristics and reliability required for the transistor, the semiconductor device can have both excellent electrical characteristics and high reliability.

The semiconductor layer 108 may have a stacked-layer structure of two or more metal oxide layers. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 108 may have different compositions. For example, a stacked-layer structure of a first metal oxide layer having an atomic ratio of In:M:Zn=1:3:4 or a composition in the neighborhood thereof and a second metal oxide layer having an atomic ratio of In:M:Zn=1:1:1 or a composition in the neighborhood thereof and being formed over the first metal oxide layer can be suitably employed. In particular, gallium or aluminum is preferably used as the element M. A stacked-layer structure of one selected from indium oxide, indium gallium oxide, and IGZO and one selected from IAZO, IAGZO, and ITZO (registered trademark) may be employed, for example.

A metal oxide layer having crystallinity is preferably used as the semiconductor layer 108. For example, a metal oxide layer having a c-axis aligned crystal (CAAC) structure, a polycrystalline structure, a nano-crystal (nc) structure, or the like can be used. By using a metal oxide layer having crystallinity as the semiconductor layer 108, the density of defect states in the semiconductor layer 108 can be reduced, which enables the transistor to have high reliability.

The higher the crystallinity of the metal oxide layer used as the semiconductor layer 108 is, the lower the density of defect states in the semiconductor layer 108 can be. In contrast, with the use of a metal oxide layer having low crystallinity, a large amount of current can flow through the transistor.

The semiconductor layer 108 may have a stacked-layer structure of two or more metal oxide layers having different crystallinities. For example, a stacked-layer structure of a first metal oxide layer and a second metal oxide layer over the first metal oxide layer can be employed; the second metal oxide layer can include a region with higher crystallinity than the first metal oxide layer. Alternatively, the second metal oxide layer can include a region having lower crystallinity than the first metal oxide layer. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target. For example, a stacked-layer structure of two or more metal oxide layers with different crystallinities can be formed with the use of the same sputtering target and different oxygen flow rate ratios. The two or more metal oxide layers included in the semiconductor layer 108 may have different compositions.

The thickness of the semiconductor layer 108 is preferably greater than or equal to 1 nm and less than or equal to 100 nm, greater than or equal to 1 nm and less than or equal to 70 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 25 nm, greater than or equal to 1 nm and less than or equal to 20 nm, greater than or equal to 1 nm and less than or equal to 15 nm, greater than or equal to 3 nm and less than or equal to 15 nm, greater than or equal to 5 nm and less than or equal to 15 nm, greater than or equal to 5 nm and less than or equal to 12 nm, or greater than or equal to 5 nm and less than or equal to 10 nm, for example.

Here, oxygen vacancies that might be formed in the semiconductor layer 108 are described.

In the case where the semiconductor layer 108 is formed using an oxide semiconductor, hydrogen contained in the oxide semiconductor reacts with oxygen bonded to a metal atom to be water, and thus sometimes forms an oxygen vacancy (V_{O}) in the oxide semiconductor. In some cases, a defect that is an oxygen vacancy into which hydrogen enters (hereinafter referred to as V_{O}H) functions as a donor and generates an electron serving as a carrier. In other cases, bonding of part of hydrogen to oxygen bonded to a metal atom generates an electron serving as a carrier. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen in an oxide semiconductor might reduce the reliability of a transistor.

V_{O}H can serve as a donor of the oxide semiconductor. However, it is difficult to evaluate the defects quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as a parameter of the oxide semiconductor. That is, “carrier concentration” in this specification and the like can be replaced with “donor concentration” in some cases.

Therefore, when an oxide semiconductor is used for the semiconductor layer 108, the V_{O}H in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydration or dehydrogenation treatment) and supply oxygen to the oxide semiconductor to repair oxygen vacancies (V_{O}). When an oxide semiconductor with sufficiently reduced defects such as V_{O}H is used for a channel formation region of a transistor, the transistor can have stable electrical characteristics. Supplying oxygen to the oxide semiconductor to repair oxygen vacancies (V_{O}) is sometimes referred to as oxygen adding treatment.

When an oxide semiconductor is used for the semiconductor layer 108, the carrier concentration of the oxide semiconductor in the region functioning as the channel formation region is preferably lower than or equal to 1×10¹⁸ cm⁻³, further preferably lower than 1×10¹⁷ cm⁻³, further preferably lower than 1×10¹⁶ cm⁻³, further preferably lower than 1×10¹³ cm⁻³, further preferably lower than 1×10¹² cm⁻³. The minimum carrier concentration of the oxide semiconductor in the region functioning as the channel formation region is not particularly limited and can be 1×10⁻⁹ cm⁻³, for example.

A transistor including an oxide semiconductor (hereinafter referred to as an OS transistor) has a much higher field-effect mobility than a transistor including amorphous silicon. An OS transistor has an extremely low leakage current between a source and a drain in an off state (hereinafter also referred to as an off-state current). Therefore, the OS transistor is preferably used for a memory device. For example, in the case where an OS transistor and a capacitor connected in series with the OS transistor are included in a memory device, data can be written to the memory device at high speed. In addition, data retained in the memory device can be read at high speed. In addition, data written to the memory device can be retained for a long time. As a result, the memory device can have a low refresh frequency and consumes less power.

The transistor of one embodiment of the present invention includes the second gate electrode and can therefore have a shift in the threshold voltage to achieve normally-off characteristics more easily than a transistor not including the second gate electrode. Since the second gate insulating layer has a function of releasing oxygen, in the case where an oxide semiconductor is used for the semiconductor layer, the channel formation region can be a highly purified intrinsic or substantially highly purified intrinsic region because oxygen vacancies in the oxide semiconductor layer are repaired with oxygen supplied to the oxide semiconductor from the second gate insulating layer. As a result, the transistor can have a low off-state current. Accordingly, when an OS transistor is used as the transistor of one embodiment of the present invention, the off-state current can be further reduced as compared with the case of using a transistor including silicon (hereinafter referred to as a Si transistor), for example. In addition, power consumption of a memory device including the OS transistor can be further reduced as compared with that of a memory device including the Si transistor.

An OS transistor can also be used in a display device. To increase the luminance of a light-emitting element included in a pixel circuit of a display device, it is necessary to increase the amount of current flowing through the light-emitting element. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Thus, with the use of an OS transistor as the driving transistor in the pixel circuit, the amount of current flowing through the light-emitting element can be increased, resulting in an increase in luminance of the light-emitting element.

When transistors operate in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be set minutely by a change in gate-source voltage; hence, the amount of current flowing through the light-emitting element can be controlled minutely. Consequently, the number of gray levels expressed by the pixel circuit can be increased.

Regarding saturation characteristics of a current flowing when transistors operate in a saturation region, even in the case where the source-drain voltage of an OS transistor increases gradually, a more stable current (saturation current) can flow through the OS transistor than through a Si transistor. Thus, by using an OS transistor as the driving transistor, a stable current can flow through light-emitting elements even when the current-voltage characteristics of the light-emitting elements vary, for example. In other words, when the OS transistor operates in the saturation region, the source-drain current hardly changes with an increase in the source-drain voltage; hence, the luminance of the light-emitting element can be stable.

As described above, by using an OS transistor as the driving transistor included in the pixel circuit, it is possible to inhibit black-level degradation, increase the luminance, increase the number of gray levels, and suppress variations in luminance, for example.

A change in electrical characteristics of an OS transistor due to exposure to radiation is small, i.e., an OS transistor has a high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a neutron beam, and a proton beam).

### [Insulating Layers 110, 110d, and 106]

In the transistor of one embodiment of the present invention and the semiconductor device including the transistor of one embodiment of the present invention, an inorganic insulating material or an organic insulating material can be used for insulating layers (the insulating layer 110, the insulating layer 110d, and the insulating layer 106). The insulating layers (the insulating layer 110, the insulating layer 110d, and the insulating layer 106) may each have a stacked-layer structure of an inorganic insulating material and an organic insulating material.

As the inorganic insulating material, one or more of an oxide, an oxynitride, a nitride oxide, and a nitride can be used.

Note that in this specification and the like, an oxynitride refers to a material in which an oxygen content is higher than a nitrogen content. A nitride oxide refers to a material in which a nitrogen content is higher than an oxygen content. For example, a silicon oxynitride refers to a material in which an oxygen content is higher than a nitrogen content, and a silicon nitride oxide refers to a material in which a nitrogen content is higher than an oxygen content.

The oxygen content and the nitrogen content can be analyzed by secondary ion mass spectrometry (SIMS) or X-ray photoelectron spectroscopy (XPS). XPS is suitable when the content of a target element is high (e.g., 0.5 atomic % or more, or 1 atomic % or more). In contrast, SIMS is suitable when the content of a target element is low (e.g., 0.5 atomic % or less, or 1 atomic % or less). To compare the contents of elements, analysis with a combination of SIMS and XPS is preferably used.

The film density of an insulating layer or the like can be evaluated by Rutherford backscattering spectrometry (RBS) or X-ray reflection (XRR), for example. A difference in film density can be evaluated using a transmission electron microscopy (TEM) image of a cross section in some cases. In TEM observation, the transmission electron (TE) image is dark-colored (dark) when the film density is high, and the transmission electron (TE) image is pale (bright) when the film density is low. Note that when insulating layers formed using the same material have different film densities, it is sometimes possible to identify the boundary between the insulating layers by a difference in contrast in a TEM image of a cross section.

The nitrogen content of an insulating layer can be analyzed by EDX, for example. In the case where a silicon nitride, a silicon oxynitride, or the like, for example, is used for the insulating layer, the nitrogen content can be evaluated with the ratio of the peak height of nitrogen to the peak height of silicon. Note that in EDX, the peak of a certain element refers to a point at which the number of counts of the element reaches a local maximum value in a spectrum of a graph where the horizontal axis represents the energy of characteristic X-rays and the vertical axis represents the number of counts (the detected value) of characteristic X-rays. Alternatively, the number of counts at an energy of a characteristic X-ray unique to the element may be used to evaluate a difference in the nitrogen content with the ratio of the number of counts of nitrogen to the number of counts of silicon. For example, the number of counts at 1.739 keV (Si-Kα) can be used for silicon, and the number of counts at 0.392 keV (N-Kα) can be used for nitrogen.

The hydrogen concentration of an insulating layer can be evaluated by SIMS, for example.

When an insulating layer that releases oxygen is used as an insulating layer in contact with the semiconductor layer 108 or an insulating layer around the semiconductor layer 108, oxygen can be supplied from the insulating layer to the semiconductor layer 108. Supplying oxygen to the channel formation region of the semiconductor layer 108 can allow the amount of oxygen vacancies (V_{O}) and V_{O}H to be reduced in the semiconductor layer 108, so that the transistor can have favorable electrical characteristics and high reliability. For example, the transistor can have a high on-state current. As another example, the transistor can have a low off-state current. As another example, the transistor can have normally-off characteristics. Examples of treatment for supplying oxygen to the semiconductor layer 108 include heat treatment in an oxygen-containing atmosphere and plasma treatment in an oxygen-containing atmosphere.

Hydrogen diffused in the semiconductor layer 108 reacts with an oxygen atom contained in an oxide semiconductor to be water, and thus sometimes forms an oxygen vacancy (V_{O}). Furthermore, V_{O}H is formed and the carrier concentration is increased in some cases. When a blocking film that inhibits hydrogen diffusion is used as the insulating layer in contact with the semiconductor layer 108 or the insulating layer around the semiconductor layer 108, oxygen vacancies (V_{O}) and V_{O}H can be reduced in the semiconductor layer 108, so that the transistor can have favorable electrical characteristics and high reliability.

Oxygen vacancies (V_{O}) and V_{O}H are preferably reduced in the channel formation region of the transistor 100. Particularly in the case where the channel length L100 is short, oxygen vacancies (V_{O}) and V_{O}H in the channel formation region greatly affect the electrical characteristics and reliability of the transistor 100. For example, diffusion of V_{O}H from the source region or the drain region into the channel formation region increases the carrier concentration in the channel formation region, which might cause a change in the threshold voltage or a reduction in the reliability of the transistor 100. As the channel length L100 of the transistor 100 becomes shorter, the influence of such diffusion of V_{O}H on electrical characteristics and reliability becomes greater. Reducing oxygen vacancies (V_{O}) and V_{O}H in the semiconductor layer 108, particularly in the channel formation region in the semiconductor layer 108, enables the transistor with a short channel length to have favorable electrical characteristics and high reliability.

The amount of impurities (e.g., water and hydrogen) released from the insulating layer in contact with the semiconductor layer 108 or the insulating layer around the semiconductor layer 108 is preferably small. When the amount of impurities released from the insulating layer is small, diffusion of impurities into the semiconductor layer 108 can be inhibited, so that the transistor can have favorable electrical characteristics and high reliability.

In some cases, oxygen is released from the semiconductor layer 108 by heat applied in a step after the formation of the semiconductor layer 108. However, when oxygen is supplied to the semiconductor layer 108 from the insulating layer in contact with the semiconductor layer 108 or the insulating layer around the semiconductor layer 108, the amount of oxygen vacancies (V_{O}) and V_{O}H can be inhibited from increasing in the semiconductor layer 108. In addition, the temperature of treatment in a step after the formation of the semiconductor layer 108 can be set more flexibly. Specifically, the temperature of treatment can be set high even in a step after the formation of the semiconductor layer 108. Accordingly, the transistor 100 can be formed to have favorable electrical characteristics and high reliability.

For the insulating layer 110 and the insulating layer 110d, an inorganic insulating material or an organic insulating material can be used. The insulating layer 110 and the insulating layer 110d may each have a stacked-layer structure of an inorganic insulating material and an organic insulating material.

An inorganic insulating material can be suitably used for the insulating layer 110 and the insulating layer 110d. As the inorganic insulating material, one or more of an oxide, an oxynitride, a nitride oxide, and a nitride can be used. For example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used for the insulating layer 110 and the insulating layer 110d.

The insulating layer 110 and the insulating layer 110d may each have a stacked-layer structure of two or more layers. The insulating layer 110 illustrated in FIG. 1B or the like has a three-layer structure of the insulating layer 110a, the insulating layer 110b over the insulating layer 110a, and the insulating layer 110c over the insulating layer 110b. For each of the insulating layers 110a, 110b, and 110c, any of the above-described materials can be used. Note that the insulating layers 110a, 110b, and 110c may be formed using the same material or different materials.

The amount of impurities (e.g., water and hydrogen) released from the insulating layers 110a, 110b, and 110c is preferably small.

The thickness of the insulating layer 110b can be larger than that of the insulating layer 110a. The thickness of the insulating layer 110b can be larger than that of the insulating layer 110c. The film formation rate of the insulating layer 110b is preferably higher than those of the insulating layers 110a and 110c. By increasing the film formation rate of a film with a large thickness, the productivity can be increased.

The insulating layers 110a and 110c each function as a blocking film that inhibits release of gas from the insulating layer 110b. Each of the insulating layers 110a and 110c is preferably formed using a material that does not easily allow diffusion of gas. The insulating layer 110a preferably includes a region having a higher film density than the insulating layer 110b. The insulating layer 110c preferably includes a region having a higher film density than the insulating layer 110b. An insulating layer having a high film density can have a high blocking property against impurities (e.g., water and hydrogen). An insulating layer formed at a low film formation rate can have a high film density and a high blocking property against impurities.

The insulating layer 110b is preferably formed using an oxide or an oxynitride. A film from which oxygen is released by heating is preferably used for the insulating layer 110b. For example, silicon oxide or silicon oxynitride can be suitably used for the insulating layer 110b.

When the insulating layer 110b releases oxygen, oxygen can be supplied from the insulating layer 110b to the semiconductor layer 108. The insulating layer 110b preferably has a high oxygen diffusion coefficient. Oxygen is easily diffused in the insulating layer 110b having a high oxygen diffusion coefficient, so that oxygen can be efficiently supplied to the semiconductor layer 108.

The insulating layer 110a, the insulating layer 110b, and the insulating layer 110c are preferably formed by a film formation method such as a sputtering method, an ALD method, or a plasma CVD method.

It is particularly preferable to employ a film formation method in which a hydrogen gas is not used as a film formation gas, such as a sputtering method, to form a film having an extremely low hydrogen content. In that case, supply of hydrogen to the semiconductor layer 108 is inhibited and the electrical characteristics of the transistor 100 can be stabilized. In the case where a silicon oxide film is formed by a sputtering method, the film can be formed using a silicon target in an atmosphere containing an oxygen gas, for example. In the case where a silicon nitride film is formed by a sputtering method, the film can be formed using a silicon target in an atmosphere containing a nitrogen gas, for example. In the case where an aluminum oxide film is formed by a sputtering method, the film can be formed using an aluminum target in an atmosphere containing an oxygen gas, for example.

Silicon oxide and silicon nitride films can be formed by a PEALD method, for example. Aluminum oxide and hafnium oxide films can be formed by a thermal ALD method, for example. An insulating layer formed by a PEALD method or a thermal ALD method can be dense and can thus have a high blocking property against oxygen and hydrogen.

A material containing more nitrogen than the insulating layer 110b can be used for the insulating layer 110a. A material containing more nitrogen than the insulating layer 110b can also be used for the insulating layer 110c. An insulating layer in which the nitrogen content is high can have a high blocking property against impurities (e.g., water and hydrogen).

It is preferably that oxygen be less likely to pass through the insulating layers 110a and 110c. Each of the insulating layers 110a and 110c functions as a blocking film that inhibits release of oxygen from the insulating layer 110b. It is further preferable that hydrogen be less likely to pass through the insulating layers 110a and 110c. The insulating layers 110a and 110c function as blocking films that inhibit diffusion of hydrogen into the semiconductor layer 108 from the outside of the transistor through the insulating layers 110a and 110c. The insulating layers 110a and 110c preferably have a high film density. The insulating layers 110a and 110c having a high film density can have a high blocking property against oxygen and hydrogen. In the case where silicon oxide or silicon oxynitride is used for the insulating layer 110b, silicon nitride or silicon nitride oxide can be used for each of the insulating layers 110a and 110c. In addition, hafnium oxide or aluminum oxide can be suitably used for each of the insulating layers 110a and 110c.

Each of the insulating layers 110a and 110c can have a stacked structure of two or more layers selected from silicon nitride, silicon nitride oxide, hafnium oxide, and aluminum oxide layers.

When oxygen contained in the insulating layer 110b is diffused upward from a region of the insulating layer 110b that is not in contact with the semiconductor layer 108 (e.g., the top surface of the insulating layer 110b), the amount of oxygen supplied from the insulating layer 110b to the semiconductor layer 108 might be reduced. Providing the insulating layer 110c over the insulating layer 110b can inhibit upward diffusion of oxygen contained in the insulating layer 110b from the region of the insulating layer 110b that is not in contact with the semiconductor layer 108. Similarly, providing the insulating layer 110a under the insulating layer 110b can inhibit downward diffusion of oxygen contained in the insulating layer 110b from the region of the insulating layer 110b that is not in contact with the semiconductor layer 108. Accordingly, the amount of oxygen supplied from the insulating layer 110b to the semiconductor layer 108 is increased, whereby the amount of oxygen vacancies (V_{O}) and V_{O}H in the semiconductor layer 108 can be reduced.

The conductive layers 112a and 112b are oxidized by oxygen contained in the insulating layer 110b and have a high resistance in some cases. When the conductive layers 112a and 112b are oxidized, the amount of oxygen supplied from the insulating layer 110b to the semiconductor layer 108 might be reduced. Providing the insulating layer 110a between the insulating layer 110b and the conductive layer 112a can inhibit the conductive layer 112a from being oxidized and having a high resistance. Similarly, providing the insulating layer 110c between the insulating layer 110b and the conductive layer 112b can inhibit the conductive layer 112b from being oxidized and having a high resistance. In addition, the amount of oxygen supplied from the insulating layer 110b to the semiconductor layer 108 is increased, whereby the amount of oxygen vacancies (V_{O}) and V_{O}H in the semiconductor layer 108 can be reduced.

Providing the insulating layers 110a and 110c can inhibit diffusion of hydrogen into the semiconductor layer 108 and reduce the amount of oxygen vacancies (V_{O}) and V_{O}H in the semiconductor layer 108.

Each of the insulating layers 110a and 110c preferably has a thickness with which the insulating layer can function as a blocking film against oxygen and hydrogen. When the thickness is small, the function of a blocking film might deteriorate. Meanwhile, when the thickness is large, a region where the semiconductor layer 108 is in contact with the insulating layer 110b is narrowed and the amount of oxygen supplied to the semiconductor layer 108 might be reduced. The thickness of each of the insulating layers 110a and 110c is preferably greater than or equal to 1 nm and less than or equal to 200 nm, greater than or equal to 1 nm and less than or equal to 100 nm, greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, greater than or equal to 1 nm and less than or equal to 10 nm, greater than or equal to 1 nm and less than or equal to 5 nm, or greater than or equal to 2 nm and less than or equal to 5 nm.

The above description of the insulating layer 110a and the insulating layer 110c can be applied to the insulating layer 110d. The insulating layer 110d covers the side surface and the bottom surface of the conductive layer 114 functioning as the second gate electrode of the transistor. When the insulating layer 110d has a function similar to those of the insulating layers 110a and 110c, the conductive layer 114 can be inhibited from being oxidized by oxygen from the insulating layer 110b and having a high resistance. In addition, the amount of oxygen supplied from the insulating layer 110b to the semiconductor layer 108 can be prevented from being reduced by diffusion of oxygen from the insulating layer 110b to the conductive layer 114.

The insulating layer 106 functioning as the gate insulating layer preferably has low defect density. With the insulating layer 106 having low defect density, the transistor can have favorable electrical characteristics. In addition, the insulating layer 106 preferably has high withstand voltage. With the insulating layer 106 having high withstand voltage, the transistor can have high reliability.

For the insulating layer 106, one or more of an insulating oxide, an insulating oxynitride, an insulating nitride oxide, and an insulating nitride can be used, for example. One or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used for the insulating layer 106. The insulating layer 106 may be either a single layer or a stacked layer. The insulating layer 106 may have a stacked-layer structure of an oxide and a nitride, for example.

A miniaturized transistor including a thin gate insulating layer may have a large leakage current. When a high dielectric constant material (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 106 itself is preferably small. When the amount of impurities released from the insulating layer 106 is small, diffusion of impurities into the semiconductor layer 108 can be inhibited, so that the transistor can have favorable electrical characteristics and high reliability.

The insulating layer 106 is formed over the semiconductor layer 108, and thus is preferably a film that can be formed under conditions where damage to the semiconductor layer 108 is small. For example, the insulating layer 106 is preferably formed under conditions where the film formation rate is sufficiently low. For example, when the insulating layer 106 is formed by a plasma CVD method under a low-power condition, damage to the semiconductor layer 108 can be small.

Here, the insulating layer 106 will be described in detail with use of a structure in which a metal oxide is used for the semiconductor layer 108 as an example.

To improve the properties of the interface with the semiconductor layer 108, an oxide is preferably used for at least the side of the insulating layer 106 that is in contact with the semiconductor layer 108. For example, one or more of silicon oxide and silicon oxynitride can be suitably used for the insulating layer 106. A film from which oxygen is released by heating is further preferably used for the insulating layer 106.

Note that the insulating layer 106 may have a stacked-layer structure. The insulating layer 106 can have a stacked-layer structure of an oxide film on the side in contact with the semiconductor layer 108 and a nitride film on the side in contact with the conductive layer 104. For example, one or more of silicon oxide and silicon oxynitride can be suitably used for the oxide film. For example, silicon nitride can be suitably used for the nitride film.

The thickness of the insulating layer 106 is preferably greater than or equal to 0.5 nm and less than or equal to 20 nm, further preferably greater than or equal to 0.5 nm and less than or equal to 15 nm, further preferably greater than or equal to 0.5 nm and less than or equal to 10 nm. The insulating layer 106 at least partly includes a region with the above thickness.

In addition, the insulating layer 106 preferably has a function of supplying oxygen to the semiconductor layer 108.

[Conductive layers 112a, 112b, 104, and 114]

The conductive layer 112a functioning as one of the source and drain electrodes and the conductive layer 112b functioning as the other of the source and drain electrodes can each be formed using one or more of chromium, copper, aluminum, gold, silver, zinc, tantalum, titanium, tungsten, manganese, nickel, iron, cobalt, molybdenum, niobium, and ruthenium or an alloy including one or more of these metals as its components. A conductive material with a low resistance that contains one or more of copper, silver, gold, and aluminum can be suitably used for the conductive layers 112a and 112b. Copper or aluminum is particularly preferable because of its high mass-productivity.

For each of the conductive layers 112a and 112b, a conductive metal oxide (also referred to as an oxide conductor) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, the oxide conductor (OC) is described. For example, when an oxygen vacancy (V_{O}) is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layers 112a and 112b may each have a stacked-layer structure of a conductive film containing the above-described oxide conductor (metal oxide) and a conductive film containing a metal or an alloy. The use of the conductive film containing a metal or an alloy can reduce the resistance.

A Cu—X alloy film (X is Mn, Ni, Cr, Fe, Co, Mo, Ta, or Ti) may be used for the conductive layers 112a and 112b. The use of a Cu—X alloy film enables the manufacturing cost to be reduced because the film can be processed by wet etching.

Note that the conductive layers 112a and 112b may be formed using the same material or different materials.

Here, the conductive layers 112a and 112b will be described in detail with use of a structure in which a metal oxide is used for the semiconductor layer 108 as an example.

When an oxide semiconductor is used for the semiconductor layer 108, the conductive layers 112a and 112b are oxidized by oxygen contained in the semiconductor layer 108 and have a high resistance in some cases. Moreover, when the conductive layers 112a and 112b are oxidized by oxygen contained in the semiconductor layer 108, the amount of oxygen vacancies (V_{O}) in the semiconductor layer 108 is increased in some cases.

Each of the conductive layers 112a and 112b is preferably formed using a conductive material that is less likely to be oxidized, a conductive material that maintains a low electric resistance even when oxidized, or an oxide conductor. For example, titanium, In—Sn oxide (ITO), or In—Sn—Si oxide (ITSO) can be suitably used. A nitride conductor may be used for each of the conductive layers 112a and 112b. Examples of the nitride conductor include tantalum nitride and titanium nitride. Each of the conductive layers 112a and 112b may have a stacked-layer structure of the above-described materials.

The conductive layers 112a and 112b formed using a material that is less likely to be oxidized can be inhibited from being oxidized by oxygen contained in the semiconductor layer 108 and having a high resistance. In addition, the amount of oxygen vacancies (V_{O}) can be inhibited from increasing in the semiconductor layer 108.

As described above, a material that is less likely to be oxidized is preferably used for the conductive layers 112a and 112b in contact with the semiconductor layer 108. However, the use of a material that is less likely to be oxidized might increase the resistance of the conductive layers 112a and 112b. For example, in the case where the conductive layers 112a and 112b are extended to function as wirings, the conductive layers 112a and 112b preferably have a low resistance. In view of this, the total resistance of the conductive layers 112a and 112b can be reduced when the conductive layers 112a and 112b each have a stacked-layer structure in which a material that is less likely to be oxidized is used for a conductive layer including a region in contact with the semiconductor layer 108 and a material with a low resistance is used for a conductive layer not including a region in contact with the semiconductor layer 108. In addition, the amount of oxygen vacancies (V_{O}) and V_{O}H can be reduced in the semiconductor layer 108.

Particularly in the case where the channel length L100 is short, oxygen vacancies (V_{O}) and V_{O}H in the channel formation region greatly affect the electrical characteristics and reliability of the transistor, as described above. When a material that is less likely to be oxidized is used for each of the conductive layers 112a and 112b, the amount of oxygen vacancies (V_{O}) and V_{O}H can be inhibited from increasing in the semiconductor layer 108. Thus, the transistor with a short channel length can have favorable electrical characteristics and high reliability.

In the case where the conductive layers 112a and 112b each have a stacked-layer structure, one or more of an oxide conductor and a nitride conductor can be suitably used for a conductive layer including a region in contact with the semiconductor layer 108. Meanwhile, a material having a lower resistance than the above-described material is preferably used for a conductive layer not including a region in contact with the semiconductor layer 108. For example, one or more of copper, aluminum, titanium, tungsten, and molybdenum or an alloy containing one or more of these metals as its components can be suitably used. For example, In—Sn—Si oxide (ITSO) can be suitably used for the conductive layer including a region in contact with the semiconductor layer 108, and tungsten can be suitably used for the conductive layer not including a region in contact with the semiconductor layer 108.

The conductive layer 104 functioning as the first gate electrode and the conductive layer 114 functioning as the second gate electrode can each be formed using one or more of chromium, copper, aluminum, gold, silver, zinc, molybdenum, tantalum, titanium, tungsten, manganese, nickel, iron, cobalt, and niobium or an alloy including one or more of these metals as its components. A nitride and an oxide that can be used for the conductive layers 112a and 112b may be used for the conductive layer 104 and the conductive layer 114.

Note that the conductive layers 104 and 114 may each have a stacked-layer structure of two layers. For example, a nitride or an oxide can be used for the lower conductive layer, and one or more of chromium, copper, aluminum, gold, silver, zinc, molybdenum, tantalum, titanium, tungsten, manganese, nickel, iron, cobalt, and niobium or an alloy containing one or more of these metals as its components can be used for the upper conductive layer.

### [Insulating Layer 195]

The insulating layer 195 functioning as a protective layer for the transistor 100 is preferably formed using a material that does not easily allow diffusion of impurities. Providing the insulating layer 195 can effectively inhibit diffusion of impurities into the transistor from the outside and increase the reliability of the transistor. Examples of the impurities include water and hydrogen. The insulating layer 195 can be an insulating layer containing an inorganic material or an insulating layer containing an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As an organic material, for example, one or more of an acrylic resin and a polyimide resin can be used. As an organic material, a photosensitive material may be used. A stack including two or more of the above insulating films may also be used. The insulating layer 195 may have a stacked-layer structure of an insulating layer containing an inorganic material and an insulating layer containing an organic material.

### [Substrate 102]

There is no particular limitation on the properties of the material of the substrate 102 as long as the material has heat resistance high enough to withstand at least heat treatment to be performed later. For example, a single crystal semiconductor substrate or a polycrystalline semiconductor substrate of silicon or silicon carbide, a compound semiconductor substrate of silicon germanium or the like, a silicon-on-insulator (SOI) substrate, a glass substrate, a quartz substrate, a sapphire substrate, a ceramic substrate, or an organic resin substrate may be used as the substrate 102. Alternatively, any of these substrates provided with a semiconductor element may be used as the substrate 102. Note that the shape of the semiconductor substrate and an insulating substrate may be circular or square.

A flexible substrate may be used as the substrate 102, and the transistor 100 and the like may be formed directly on the flexible substrate. Alternatively, a separation layer may be provided between the substrate 102 and the transistor 100 and the like. The separation layer can be used when part or the whole of a semiconductor device completed thereover is separated from the substrate 102 and transferred onto another substrate. In that case, the transistor 100 and the like can be transferred onto a substrate having low heat resistance or a flexible substrate as well.

Structure examples of transistors different from the above-described transistor 100 are described below. Note that in some cases, the above description is referred to for the portions already described and the description thereof is omitted.

### Structure Example 2

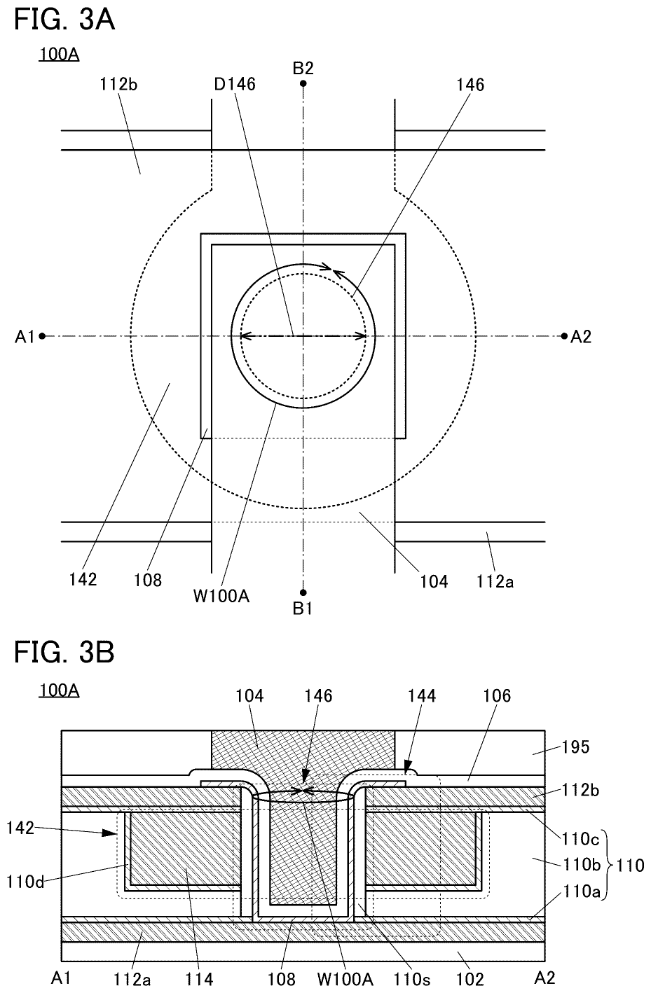

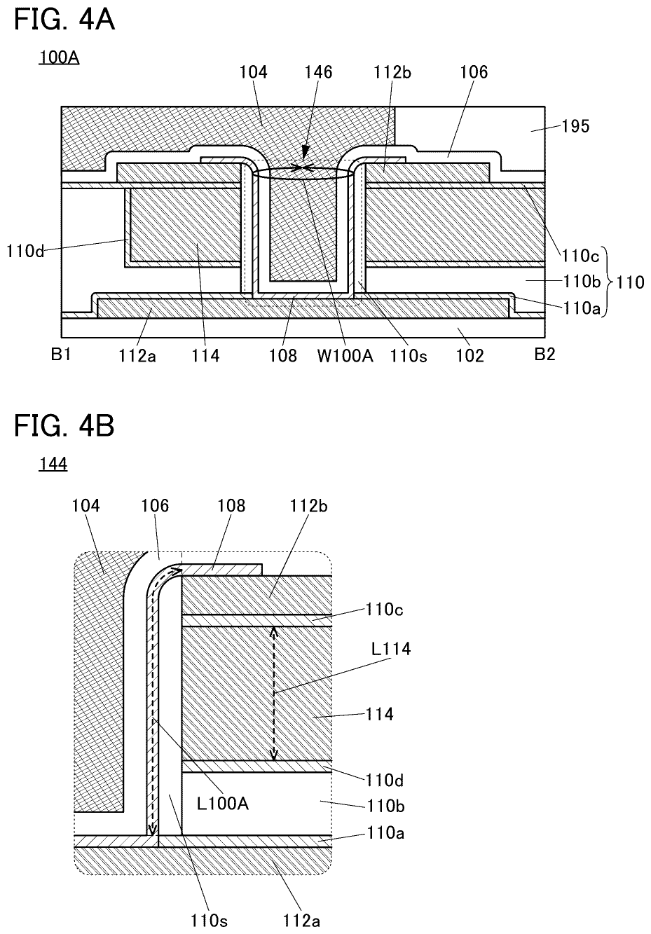

FIG. 3A is a plan view of a transistor 100A. FIG. 3B is a cross-sectional view taken along dashed-dotted line A1-A2 in FIG. 3A, and FIG. 4A is a cross-sectional view taken along dashed-dotted line B1-B2 in FIG. 3A. FIG. 4B is an enlarged view of the region 144 illustrated in FIG. 3B. Note that some components of the transistor 100A (e.g., an insulating layer) are not illustrated in FIG. 3A.

The transistor 100A is different from the transistor 100 mainly in the structure of the second gate insulating layer, for example.

In the transistor 100A, a depressed portion 142 is provided in the insulating layer 110b. The insulating layer 110d is provided in contact with the top surface and the side surface of the insulating layer 110b inside the depressed portion 142. The conductive layer 114 is provided over the insulating layer 110d to fill the depressed portion 142.

In a region overlapping with the depressed portion 142, an opening 146 is provided in the insulating layer 110b, the insulating layer 110d, the conductive layer 114, the insulating layer 110c, and the conductive layer 112b. It can also be said that the insulating layer 110d is provided in contact with the side surface and the top surface of the insulating layer 110b in a region inside the depressed portion 142 excluding the opening 146, and the conductive layer 114 is provided over the insulating layer 110d so as to fill the region.

In a region overlapping with the opening 146, an opening is provided also in the insulating layer 110a. Inside the opening, the conductive layer 112a is exposed. Here, the diameter of the opening in the insulating layer 110a is smaller than the diameter of the opening 146. That is, the insulating layer 110a includes a region positioned inside the opening 146 in a plan view.

Although FIG. 3A illustrates an example in which the top surface shapes of the opening 146 and the depressed portion 142 are each circular, one embodiment of the present invention is not limited thereto. The top surface shapes of the opening 146 and the depressed portion 142 can each be a circle (not limited to a perfect circle), an ellipse, a polygon such as a triangle, a quadrangle (including a rectangle, a rhombus, and a square), or a pentagon, or any of these polygons whose corners are rounded, for example. When the opening 146 and the depressed portion 142 have any of the above top surface shapes, flexibility in manufacturing the semiconductor device can be increased.

An insulating layer 110s is provided in contact with the top surface of the insulating layer 110a in the region overlapping with the opening 146, the side surface of the insulating layer 110b inside the opening 146, the side surface of the insulating layer 110d inside the opening 146, the side surface of the conductive layer 114 inside the opening 146, the side surface of the insulating layer 110c inside the opening 146, and the side surface of the conductive layer 112b inside the opening 146. As illustrated in FIGS. 3B and 4A, the upper end portion of the insulating layer 110s has a curved shape.

The semiconductor layer 108 is provided in contact with the top surface of the conductive layer 112a in the region overlapping with the opening 146, the side surface of the insulating layer 110a in the region overlapping with the opening 146, the side surface of the insulating layer 110s inside the opening 146, the curved portion of the insulating layer 110s, and the top surface of the conductive layer 112b.

The semiconductor layer 108 includes a region facing the conductive layer 104 with the insulating layer 106 therebetween inside the opening 146.

In addition, the semiconductor layer 108 includes a region facing the conductive layer 114 with the insulating layer 110s therebetween inside the opening 146. Thus, the insulating layer 110s functions as the second gate insulating layer in the transistor 100A.

As described above, the transistor 100 has a structure in which part of the insulating layer 110b is in contact with the back channel formation region of the semiconductor layer 108. Accordingly, the part of the insulating layer 110b can have a function of supplying oxygen to the semiconductor layer 108 in addition to the function of the second gate insulating layer. Meanwhile, the transistor 100A has a structure in which the insulating layer 110b does not include a region that is in contact with the semiconductor layer 108 and the insulating layer 110s is in contact with the back channel formation region of the semiconductor layer 108. Thus, the insulating layer 110s preferably contains oxygen. The insulating layer 110s also preferably releases oxygen. In that case, oxygen in the insulating layer 110b can be supplied to the semiconductor layer 108 through the insulating layer 110s. In addition, oxygen contained in the insulating layer 110s itself can be supplied to the semiconductor layer 108. Examples of materials that can be used for the insulating layer 110s include the above-described materials that can be used for the insulating layer 110b.

In the transistor 100A, the thickness of the second gate insulating layer can be adjusted simply by controlling the thickness of the insulating layer 110s on its formation surface (the sidewall of the opening 146). Accordingly, the second gate insulating layer can be formed more accurately and thinly than in the transistor 100. Furthermore, variation in thickness of the second gate insulating layer among the transistors included in the semiconductor device can be reduced. Thus, a semiconductor device including miniaturized transistors with a small variation in electrical characteristics can be obtained.

Although FIG. 3B and the like illustrate an example in which the upper end portion of the insulating layer 110s is level with the top surface of the conductive layer 112b, one embodiment of the present invention is not limited thereto. The insulating layer 110s is provided at least in a region facing the side surface of the conductive layer 114 so as to have the function of the second gate insulating layer of the transistor 100A as described above. Thus, the upper end portion of the insulating layer 110s may be in contact with the side surface of the conductive layer 112b at a lower position than the top surface of the conductive layer 112b. The upper end portion of the insulating layer 110s may be in contact with the side surface of the insulating layer 110c.

Meanwhile, the insulating layer 110s has the function of supplying oxygen to the back channel formation region of the semiconductor layer 108. Therefore, a contact area between the insulating layer 110s and the semiconductor layer 108 is preferably large, in which case a large amount of oxygen can be supplied from the insulating layer 110s to the semiconductor layer 108. Thus, the upper end portion of the insulating layer 110s is preferably level with the top surface of the conductive layer 112b as illustrated in FIG. 3B and the like.

In FIG. 4B, a channel length L100A of the transistor 100A is indicated by a dashed double-headed arrow. Although the length of the semiconductor layer 108 along the insulating layer 110s between the source region and the drain region is illustrated as the channel length L100A in FIG. 4B, the height of the insulating layer 110s (the length along the side surfaces of the insulating layer 110b, the insulating layer 110d, the conductive layer 114, the insulating layer 110c, and the conductive layer 112b that are in contact with the insulating layer 110s) may be regarded as the channel length L100A, for example.

In FIGS. 3A, 3B, and 4A, a channel width W100A of the transistor 100A is indicated by a solid double-headed arrow. The channel width W100A corresponds to the perimeter of the opening 146 in a plan view.

In FIG. 3A, a width D146 corresponding to the diameter of the opening 146 of a circular shape is indicated by a dashed double-dotted double-headed arrow.

The above description of the transistor 100 can be referred to for details of the transistor 100A other than those described above.

### Structure Example 3

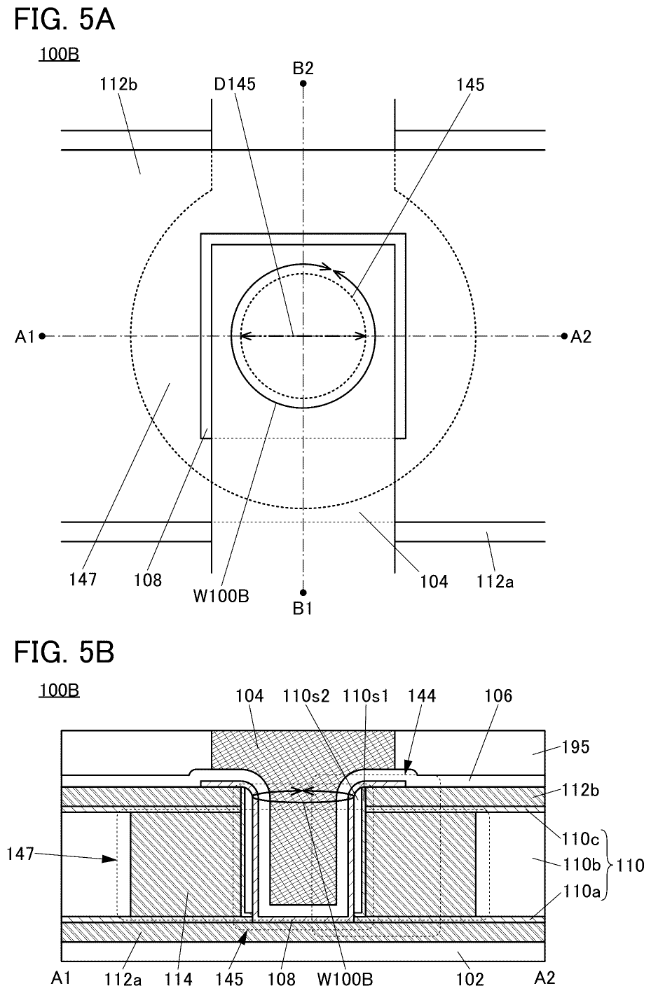

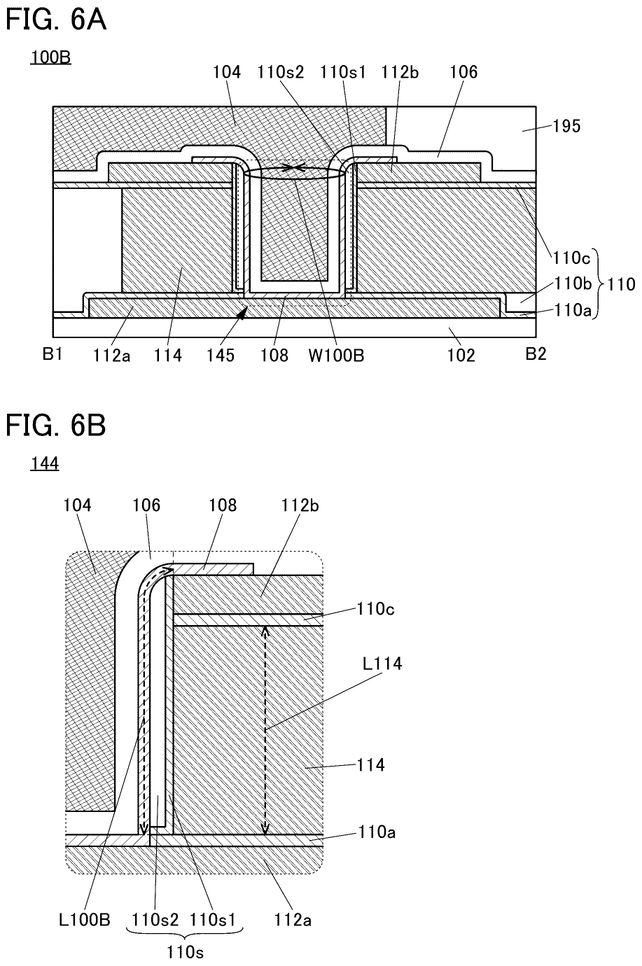

FIG. 5A is a plan view of a transistor 100B. FIG. 5B is a cross-sectional view taken along dashed-dotted line A1-A2 in FIG. 5A, and FIG. 6A is a cross-sectional view taken along dashed-dotted line B1-B2 in FIG. 5A. FIG. 6B is an enlarged view of the region 144 illustrated in FIG. 5B. Note that some components of the transistor 100B (e.g., an insulating layer) are not illustrated in FIG. 5A.

The transistor 100B is different from the transistor 100A described in <Structure example 2> mainly in the structure of the second gate electrode and the structure of the second gate insulating layer, for example.

In the transistor 100B, an opening 147 is provided in the insulating layer 110b. The insulating layer 110a is exposed inside the opening 147. The conductive layer 114 is provided over the insulating layer 110a to fill the opening 147.

In a region overlapping with the opening 147, an opening 145 is provided in the conductive layer 114, the insulating layer 110c, and the conductive layer 112b. It can also be said that the conductive layer 114 is provided over the insulating layer 110a so as to fill a region inside the opening 147 excluding the opening 145.

In a region overlapping with the opening 145, an opening is provided also in the insulating layer 110a. Inside the opening, the conductive layer 112a is exposed. Here, the diameter of the opening in the insulating layer 110a is smaller than the diameter of the opening 145. That is, the insulating layer 110a includes a region positioned inside the opening 145 in a plan view.

Although FIG. 5A illustrates an example in which the top surface shapes of the opening 145 and the opening 147 are each circular, one embodiment of the present invention is not limited thereto. The top surface shapes of the opening 145 and the opening 147 can each be a circle (not limited to a perfect circle), an ellipse, a polygon such as a triangle, a quadrangle (including a rectangle, a rhombus, and a square), or a pentagon, or any of these polygons whose corners are rounded, for example. When the opening 145 and the opening 147 have any of the above top surface shapes, flexibility in manufacturing the semiconductor device can be increased.

An insulating layer 110s1 is provided in contact with the top surface of the insulating layer 110a in the region overlapping with the opening 145, the side surface of the conductive layer 114 inside the opening 145, the side surface of the insulating layer 110c inside the opening 145, and the side surface of the conductive layer 112b inside the opening 145. Over the insulating layer 110s1, an insulating layer 110s2 is provided to face the side surface of the conductive layer 114, the side surface of the insulating layer 110c, and the side surface of the conductive layer 112b with the insulating layer 110s1 therebetween. That is, in the transistor 100B, the insulating layer 110s in the transistor 100A has a stacked-layer structure of the insulating layer 110s1 and the insulating layer 110s2 over the insulating layer 110s1. As illustrated in FIGS. 5B and 6A, the upper end portion of the insulating layer 110s2 has a curved shape.

The semiconductor layer 108 is provided in contact with the top surface of the conductive layer 112a in the region overlapping with the opening 145, the side surface of the insulating layer 110a in the region overlapping with the opening 145, the side surface of the insulating layer 110s1 inside the opening 145, the side surface of the insulating layer 110s2 inside the opening 145, the curved portion of the insulating layer 110s2, the upper end portion of the insulating layer 110s1, and the top surface of the conductive layer 112b.

The semiconductor layer 108 includes a region facing the conductive layer 104 with the insulating layer 106 therebetween inside the opening 145.

In addition, the semiconductor layer 108 includes a region facing the conductive layer 114 with the insulating layer 110s1 and the insulating layer 110s2 therebetween inside the opening 145. Thus, the insulating layer 110s1 and the insulating layer 110s2 function as the second gate insulating layer in the transistor 100B.

In the transistor 100B, the bottom surface of the conductive layer 114 functioning as the second gate electrode is over and in contact with the insulating layer 110a. That is, the length of the second gate electrode positioned between the source electrode and the drain electrode is larger than that in the transistor 100A. Accordingly, in the transistor 100B, an electric field from the second gate electrode can be applied to the entire back channel formation region of the semiconductor layer 108. Thus, the electric field from the second gate electrode has an increased influence on carriers in the back channel formation region, so that the threshold voltage can be shifted to easily achieve normally-off characteristics of the transistor. In addition, the entire back channel formation region is covered with the second gate electrode; thus, the on-state current can be increased.

Unlike the transistor 100 and the transistor 100A, the transistor 100B does not include a region where the second gate insulating layer is in contact with the insulating layer 110b. Thus, in the transistor 100B, the second gate insulating layer itself needs to have a function of supplying oxygen to the semiconductor layer 108. That is, the second gate insulating layer of the transistor 100B needs to contain oxygen and release oxygen.

Meanwhile, in the case where the second gate insulating layer has the above-described function, diffusion of oxygen contained in the second gate insulating layer into the adjacent conductive layers 114 and 112b might cause these layers to be oxidized and have a high resistance. In addition, diffusion of oxygen contained in the second gate insulating layer into the conductive layers 114 and 112b might reduce the amount of oxygen supplied to the semiconductor layer 108.

Thus, of the insulating layers 110s1 and 110s2 functioning as the second gate insulating layer of the transistor 100B, the insulating layer 110s1 in contact with the conductive layers 114 and 112b preferably inhibits oxygen diffusion. The insulating layer 110s2 in contact with the semiconductor layer 108 preferably contains oxygen and releases oxygen. In that case, oxygen contained in the insulating layer 110s2 can be efficiently supplied to the semiconductor layer 108. Examples of materials that can be used for the insulating layer 110s1 include the above-described materials that can be used for the insulating layer 110a and the insulating layer 110c. Examples of materials that can be used for the insulating layer 110s2 include the above-described materials that can be used for the insulating layer 110b.

Since the transistor 100B includes the second gate electrode (the conductive layer 114) and the second gate insulating layer (the insulating layer 110s1 and the insulating layer 110s2) as described above, the transistor can be miniaturized and have favorable electrical characteristics.

In FIG. 6B, a channel length L100B of the transistor 100B is indicated by a dashed double-headed arrow. Although the length along the semiconductor layer 108 between the source electrode and the drain electrode is illustrated as the channel length L100B in FIG. 6B, the height of the insulating layer 110s1 (the length along the side surfaces of the conductive layer 114, the insulating layer 110c, and the conductive layer 112b that are in contact with the insulating layer 110s1) may be regarded as the channel length L100B, for example.

In FIGS. 5A, 5B, and 6A, a channel width W100B of the transistor 100B is indicated by a solid double-headed arrow. The channel width W100B corresponds to the perimeter of the opening 145 in a plan view.

In FIG. 5A, a width D145 corresponding to the diameter of the opening 145 of a circular shape is indicated by a dashed double-dotted double-headed arrow.

The above description of the transistor 100 and the transistor 100A can be referred to for details of the transistor 100B other than those described above.

### Structure Example 4

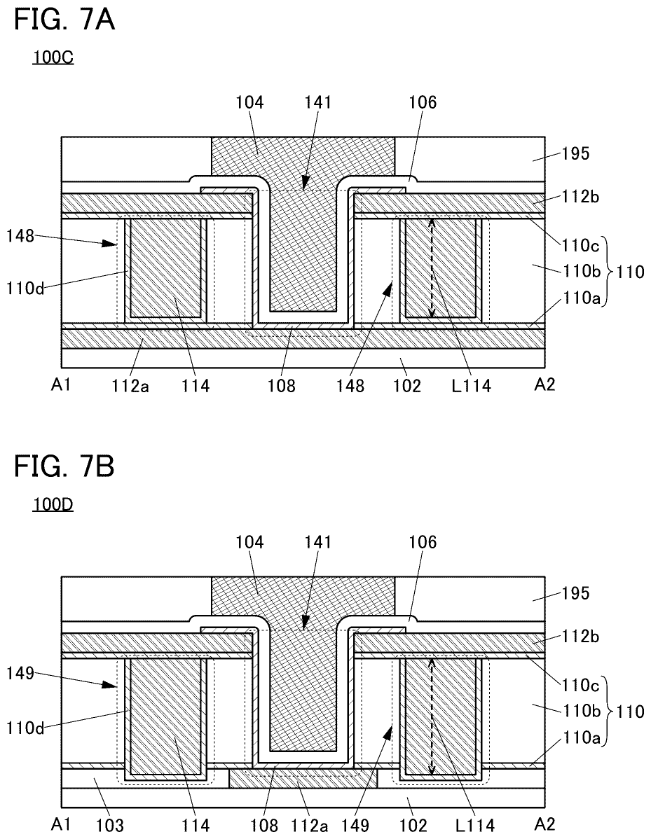

FIG. 7A is a cross-sectional view of a transistor 100C. Note that this cross-sectional view of the transistor 100C corresponds to the cross-sectional view of the transistor 100 taken along the dashed-dotted line A1-A2 illustrated in FIG. 1A.

The transistor 100C is different from the transistor 100 mainly in the size of the conductive layer 114 functioning as the second gate electrode.

Specifically, the conductive layer 114 in the transistor 100 is provided to fill the depressed portion 143 formed in the insulating layer 110b with the insulating layer 110d therebetween. Thus, the bottom surface of the conductive layer 114 is positioned in the insulating layer 110b. Meanwhile, the conductive layer 114 in the transistor 100C is provided to fill an opening 148 formed in the insulating layer 110b with the insulating layer 110d therebetween. Thus, the bottom surface of the conductive layer 114 faces the top surface of the insulating layer 110a with the insulating layer 110d therebetween. That is, it can be said that the length of the conductive layer 114 positioned between the source electrode and the drain electrode in the transistor 100C is larger than that in the transistor 100.

In the transistor 100C, the length L114 of the conductive layer 114 functioning as the second gate electrode is larger than the length L114 in the transistor 100. Accordingly, an electric field from the conductive layer 114 can be applied to substantially the entire back channel formation region of the semiconductor layer 108. As a result, the transistor can have stable electrical characteristics and reliability.

The above description of the transistor 100 can be referred to for details of the transistor 100C other than those described above.

### Structure Example 5

FIG. 7B is a cross-sectional view of a transistor 100D. Note that this cross-sectional view of the transistor 100D corresponds to the cross-sectional view of the transistor 100 taken along the dashed-dotted line A1-A2 illustrated in FIG. 1A.

The transistor 100D is different from the transistor 100 and the transistor 100C described in <Structure Example 4> mainly in the structure of the conductive layer 112a functioning as one of the source and drain electrodes and the size of the conductive layer 114 functioning as the second gate electrode, for example.

Specifically, the conductive layer 112a in the transistor 100 and the transistor 100C is provided over the entire substrate 102 in the cross-sectional view taken along the dashed-dotted line A1-A2, whereas the conductive layer 112a in the transistor 100D is provided over part of the substrate 102 and an insulating layer 103 is provided so that the conductive layer 112a is embedded in the insulating layer 103 in the cross-sectional view taken along the dashed-dotted line A1-A2.

In the transistor 100D, a depressed portion 149 is provided in the insulating layer 103, the insulating layer 110a, and the insulating layer 110b. The insulating layer 110d is provided in contact with the top surface of the insulating layer 103 inside the depressed portion 149, the side surface of the insulating layer 103 inside the depressed portion 149, the side surface of the insulating layer 110a inside the depressed portion 149, and the side surface of the insulating layer 110b inside the depressed portion 149. The conductive layer 114 is provided over the insulating layer 110d to fill the depressed portion 149. The depressed portion 149 can be regarded as including a depressed portion provided in the insulating layer 103, an opening provided in the insulating layer 110a to overlap with the depressed portion, and an opening provided in the insulating layer 110b (the opening 148 in the transistor 100C) to overlap with the opening provided in the insulating layer 110a. Thus, it can be said that the length of the conductive layer 114 positioned between the source electrode and the drain electrode in the transistor 100D is larger than that in the transistor 100C.

In the transistor 100D, the length L114 of the conductive layer 114 functioning as the second gate electrode is larger than the length L114 in the transistor 100C. The bottom surface of the conductive layer 114 is positioned below the top surface of the conductive layer 112a (i.e., positioned on the substrate 102 side). Accordingly, an electric field from the conductive layer 114 can be applied to the entire back channel formation region of the semiconductor layer 108. As a result, the transistor can have stable electrical characteristics and reliability.

Note that the insulating layer 103 in the transistor 100D can be formed using any of the above-described materials that can be used for the insulating layer 110, the insulating layer 110d, and the insulating layer 106.

The above description of the transistor 100 can be referred to for details of the transistor 100D other than those described above.

### Structure Example 6

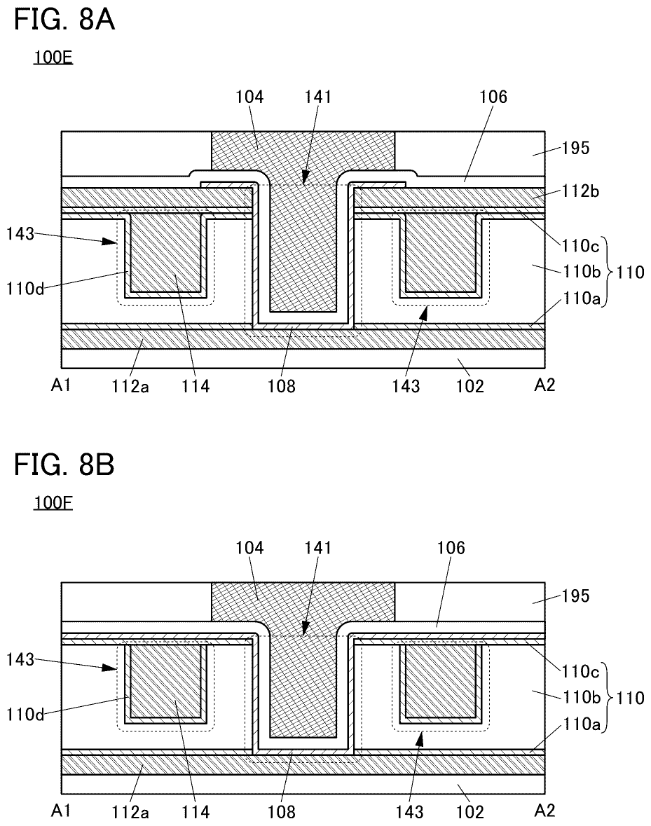

FIG. 8A is a cross-sectional view of a transistor 100E. Note that this cross-sectional view of the transistor 100E corresponds to the cross-sectional view of the transistor 100 taken along the dashed-dotted line A1-A2 illustrated in FIG. 1A.

The transistor 100E is different from the transistor 100 mainly in the structure of the insulating layer 110d.

Specifically, the insulating layer 110d in the transistor 100 is provided in contact with the top surface and the side surface of the insulating layer 110b inside the depressed portion 143. Meanwhile, the insulating layer 110d in the transistor 100E includes a region that extends to the outside of the depressed portion 143 and that is in contact with the top surface of the insulating layer 110b outside the depressed portion 143. The top surface of the conductive layer 114 is level with the top surface of the region of the insulating layer 110d that extends to the outside of the depressed portion 143. In the transistor 100E, the insulating layer 110c is provided in contact with these top surfaces.

The structure of the insulating layer 110d can differ depending on the conditions of CMP treatment that is performed to form the conductive layer 114 in the depressed portion 143 through a damascene process. For example, the conductive layer 114 and the insulating layer 110b whose top surfaces are flat and level with each other (the structure illustrated in the transistor 100) can be formed by forming a conductive film to be the conductive layer 114 over the insulating layer 110d to fill the depressed portion 143 and then performing CMP treatment on the conductive film until the top surface of the insulating layer 110b is exposed. Meanwhile, the conductive layer 114 and the insulating layer 110d whose top surfaces are flat and level with each other (the structure illustrated in the transistor 100E) can be formed by performing CMP treatment on the conductive film until the top surface of the insulating layer 110d is exposed.

In this manner, the transistor of one embodiment of the present invention can have either the structure of the transistor 100 or the structure of the transistor 100E. Accordingly, flexibility in manufacturing the transistor can be increased.

The above description of the transistor 100 can be referred to for details of the transistor 100E other than those described above.

### Structure Example 7

FIG. 8B is a cross-sectional view of a transistor 100F. Note that this cross-sectional view of the transistor 100F corresponds to the cross-sectional view of the transistor 100 taken along the dashed-dotted line A1-A2 illustrated in FIG. 1A.

The transistor 100F is different from the transistor 100 mainly in that the conductive layer 112b is not provided and the end portion of the semiconductor layer 108 extends to the outside of the depressed portion 143 in a plan view.

In the transistor 100F, the semiconductor layer 108 includes a region in contact with the top surface of the conductive layer 112a inside the opening 141, the side surface of the insulating layer 110 (the insulating layer 110a, the insulating layer 110b, and the insulating layer 110c) inside the opening 141, and the top surface of the insulating layer 110c. The semiconductor layer 108 in the transistor 100F can have both the function of the semiconductor layer including the channel formation region and the function of the other of the source and drain electrodes. For example, a region of the semiconductor layer 108 that is in contact with the side surface of the insulating layer 110 inside the opening 141 can function as the channel formation region. A region of the semiconductor layer 108 that extends to the outside of the opening 141 can function as the other of the source and drain electrodes.

For example, the resistance of the semiconductor layer 108 can be reduced by supplying an impurity such as boron to the semiconductor layer 108 from a direction perpendicular to the substrate surface by an ion implantation method, an ion doping method, a plasma immersion ion implantation method, plasma treatment, or the like. Alternatively, when an oxide semiconductor is used for the semiconductor layer 108, a low-resistance region can be formed in the semiconductor layer 108 by forming a silicon nitride film or the like over the region of the semiconductor layer 108 that extends to the outside of the opening 141 to change the region into an oxide conductor (OC). In this manner, the resistance of regions corresponding to the source and drain regions of the semiconductor layer 108 can be made lower than that of the channel formation region. Thus, the channel formation region and the source and drain regions having a lower resistance than the channel formation region can be separately formed in the semiconductor layer 108. Accordingly, regions corresponding to the source and drain electrodes can be formed in the semiconductor layer 108 in the transistor 100F, without providing the conductive layer 112b. Since the conductive layer 112b is not provided in the transistor 100F, the number of steps for manufacturing the transistor can be reduced.

The above description of the transistor 100 can be referred to for details of the transistor 100F other than those described above.

### Structure Example 8

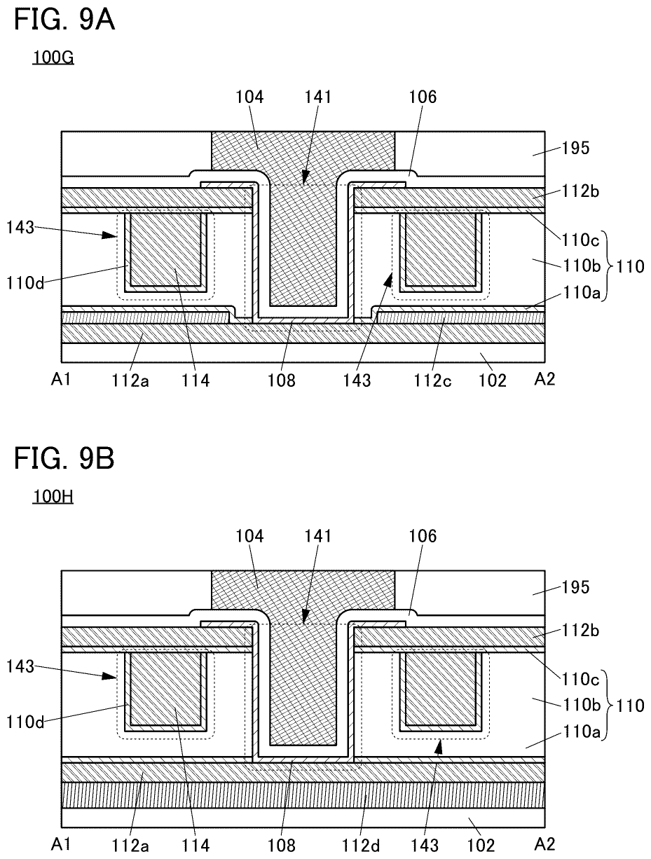

FIG. 9A is a cross-sectional view of a transistor 100G. Note that this cross-sectional view of the transistor 100G corresponds to the cross-sectional view of the transistor 100 taken along the dashed-dotted line A1-A2 illustrated in FIG. 1A.

The transistor 100G is different from the transistor 100 mainly in the structure of the conductive layer functioning as one of the source and drain electrodes.

Specifically, in the transistor 100, the conductive layer functioning as one of the source and drain electrodes has a single-layer structure of the conductive layer 112a alone. Meanwhile, in the transistor 100G, the conductive layer functioning as one of the source and drain electrodes has a stacked-layer structure of the conductive layer 112a and a conductive layer 112c over the conductive layer 112a.

The conductive layer 112c is provided over the conductive layer 112a so as to be present on both sides of the opening 141 in the cross-sectional view taken along the dashed-dotted line A1-A2. The insulating layer 110a is provided in contact with part of the side surface of the semiconductor layer 108 on the back channel formation region side, part of the top surface of the conductive layer 112a, the side surface of the conductive layer 112c, and the top surface of the conductive layer 112c.

In the transistor 100G, the stack of the conductive layers 112a and 112c functions as one of the source and drain electrodes.

The conductive layer 112a includes a region in contact with the semiconductor layer 108. Thus, the conductive layer 112a is preferably formed using a material that is less likely to be oxidized. Meanwhile, the conductive layer 112c that does not include a region in contact with the semiconductor layer 108 can be formed using a material that has a lower resistance than the conductive layer 112a. Note that the above description of the materials that can be used for the conductive layers 112a and 112b can be referred to for details of the material that is less likely to be oxidized and can be used for the conductive layer 112a and the material that has a low resistance and can be used for the conductive layer 112c. When a stack of a conductive layer that is less likely to be oxidized (the conductive layer 112a) and a conductive layer that has a low resistance (the conductive layer 112c) is used as one of source and drain electrodes as in the transistor 100G, the stack can be used also as a wiring.

The above description of the transistor 100 can be referred to for details of the transistor 100G other than those described above.

### Structure Example 9

FIG. 9B is a cross-sectional view of a transistor 100H. Note that this cross-sectional view of the transistor 100H corresponds to the cross-sectional view of the transistor 100 taken along the dashed-dotted line A1-A2 illustrated in FIG. 1A.

The transistor 100H is different from the transistor 100G described in <Structure Example 8> mainly in the structure of the conductive layer functioning as one of the source and drain electrodes.

Specifically, in the transistor 100H, the conductive layer functioning as one of the source and drain electrodes has a stacked-layer structure of a conductive layer 112d over the substrate 102 and the conductive layer 112a over the conductive layer 112d.

In the transistor 100H, the stack of the conductive layer 112d and the conductive layer 112a functions as one of the source and drain electrodes.

The conductive layer 112a includes a region in contact with the semiconductor layer 108. Thus, the conductive layer 112a is preferably formed using a material that is less likely to be oxidized. Meanwhile, the conductive layer 112d that does not include a region in contact with the semiconductor layer 108 can be formed using a material that has a lower resistance than the conductive layer 112a. Note that the above description of the materials that can be used for the conductive layers 112a and 112b can be referred to for details of the material that is less likely to be oxidized and can be used for the conductive layer 112a and the material that has a low resistance and can be used for the conductive layer 112d. When a stack of a conductive layer that has a low resistance (the conductive layer 112d) and a conductive layer that is less likely to be oxidized (the conductive layer 112a) is used as one of source and drain electrodes as in the transistor 100H, the stack can be used also as a wiring.

As the conductive layer functioning as one of the source and drain electrodes, the transistor 100G employs the stack of the conductive layer that is less likely to be oxidized (the conductive layer 112a) and the conductive layer thereover that has a lower resistance (the conductive layer 112c), whereas the transistor 100H employs the stack of the conductive layer that is less likely to be oxidized (the conductive layer 112a) and the conductive layer thereunder that has a lower resistance (the conductive layer 112d). In this manner, the conductive layer functioning as one of the source and drain electrodes in the transistor of one embodiment of the present invention can have either the structure in the transistor 100G or the structure in the transistor 100H. Accordingly, flexibility in manufacturing the transistor can be increased.

The above description of the transistor 100G can be referred to for details of the transistor 100H other than those described above.

### Structure Example 10

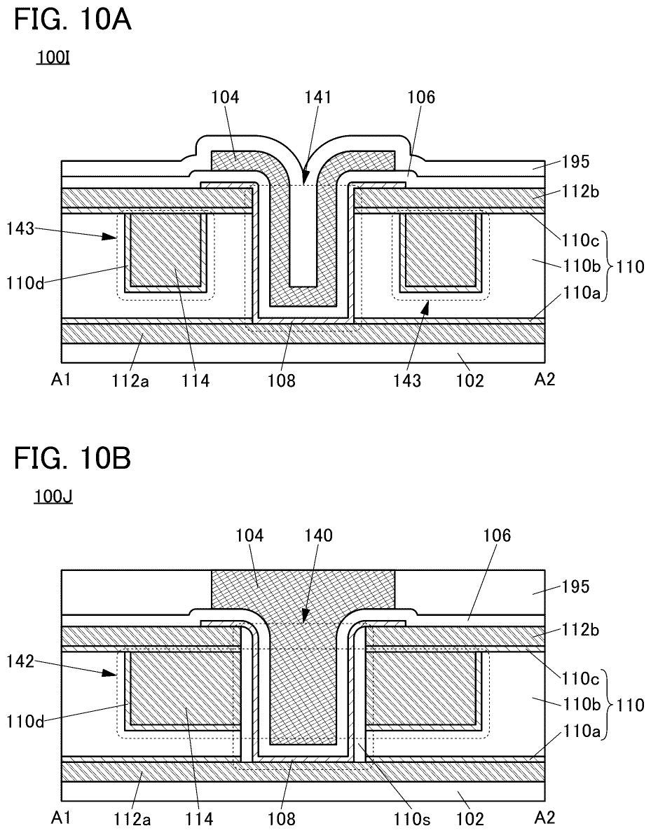

FIG. 10A is a cross-sectional view of a transistor 100I. Note that this cross-sectional view of the transistor 100I corresponds to the cross-sectional view of the transistor 100 taken along the dashed-dotted line A1-A2 illustrated in FIG. 1A.

The transistor 100I is different from the transistor 100 mainly in the structure of the conductive layer 104 functioning as the first gate electrode, for example.

Specifically, in the transistor 100, part of the conductive layer 104 is provided to fill the opening 141. The insulating layer 195 is provided over the insulating layer 106 so that the conductive layer 104 is embedded in the insulating layer 195. The top surface of the conductive layer 104 and the top surface of the insulating layer 195 are planarized and level with each other.

Meanwhile, in the transistor 100I, the conductive layer 104 has a shape reflecting the shapes of the semiconductor layer 108 and the insulating layer 106 inside the opening 141 (a shape along the sidewall and the bottom surface of the opening 141). That is, unlike in the transistor 100, the opening 141 in the transistor 100I is not filled with the conductive layer 104. The insulating layer 195 is provided to cover the conductive layer 104 and the insulating layer 106, and the top surface of the insulating layer 195 is not planarized.

The structure of the transistor 100 is preferable because it can increase coverage with a film formed over the conductive layer 104 and the insulating layer 195. Meanwhile, the structure of the transistor 100I is preferable because it does not require treatment for planarizing the top surfaces of the conductive layer 104 and the insulating layer 195 and can reduce the number of steps for manufacturing the transistor.

The above description of the transistor 100 can be referred to for details of the transistor 100I other than those described above.

### Structure Example 11

FIG. 10B is a cross-sectional view of a transistor 100J. Note that this cross-sectional view of the transistor 100J corresponds to the cross-sectional view of the transistor 100 taken along the dashed-dotted line A1-A2 illustrated in FIG. 1A.

The transistor 100J is different from the transistor 100A described in <Structure example 2> mainly in the structure of the insulating layer 110s functioning as the second gate insulating layer, for example.

In a region overlapping with the depressed portion 142 in the transistor 100J, an opening 140 is provided in the insulating layer 110a, the insulating layer 110b, the insulating layer 110d, the conductive layer 114, the insulating layer 110c, and the conductive layer 112b. The opening 140 can be regarded as a combination of the opening 146 in the transistor 100A and an opening provided in the insulating layer 110a to overlap with the opening 146. Inside the opening 140, the conductive layer 112a is exposed. It can also be said that the insulating layer 110d is provided in contact with the side surface and the top surface of the insulating layer 110b in a region inside the depressed portion 142 excluding the opening 140, and the conductive layer 114 is provided over the insulating layer 110d so as to fill the region.

The insulating layer 110s is provided in contact with the top surface of the conductive layer 112a inside the opening 140, the side surface of the insulating layer 110a inside the opening 140, the side surface of the insulating layer 110b inside the opening 140, the side surface of the insulating layer 110d inside the opening 140, the side surface of the conductive layer 114 inside the opening 140, the side surface of the insulating layer 110c inside the opening 140, and the side surface of the conductive layer 112b inside the opening 140.

That is, the lower end portion of the insulating layer 110s in the transistor 100A is in contact with the top surface of the insulating layer 110a and not in contact with the conductive layer 112a, whereas the lower end portion of the insulating layer 110s in the transistor 100J is in contact with the top surface of the conductive layer 112a. It can also be said that the transistor 100J has a larger contact area between the insulating layer 110s and the semiconductor layer 108 than the transistor 100A.

When the insulating layer 110s is provided as in the structure of the transistor 100A, oxygen released from the insulating layer 110s can be inhibited from diffusing into the conductive layer 112a functioning as one of the source and drain electrodes, so that the conductive layer 112a can be inhibited from being oxidized and having a high resistance. In addition, the amount of oxygen supplied to the semiconductor layer 108 can be prevented from being reduced by diffusion of oxygen from the insulating layer 110s to the conductive layer 112a.

Meanwhile, when the insulating layer 110s is provided as in the structure of the transistor 100J, oxygen can be efficiently supplied to the entire back channel formation region of the semiconductor layer 108.

The above description of the transistor 100A can be referred to for details of the transistor 100J other than those described above.

### Manufacturing Method Example 1

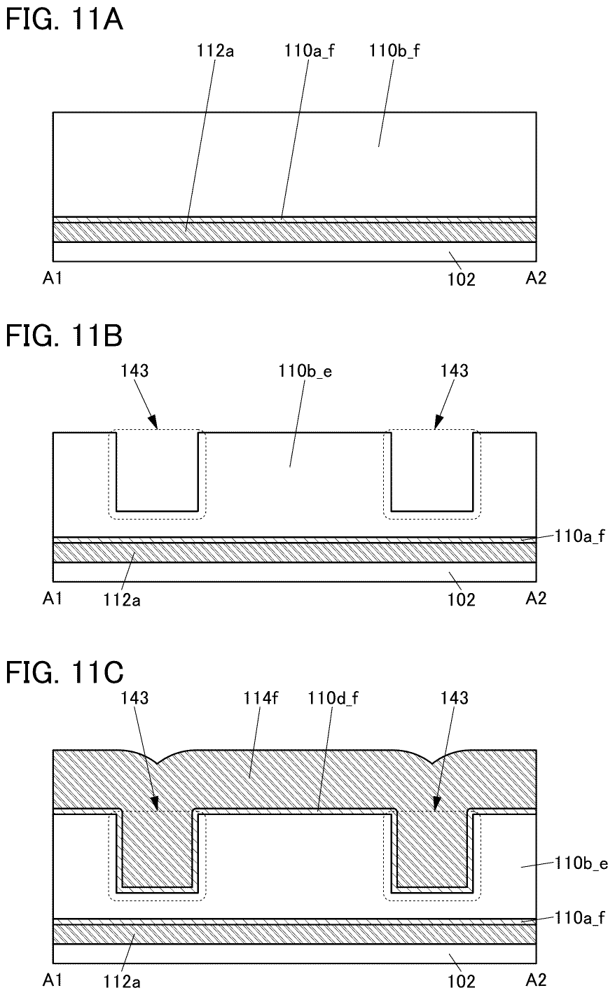

A method for manufacturing a transistor of one embodiment of the present invention is described below with reference to drawings (FIGS. 11A to 11C, FIGS. 12A to 12C, and FIGS. 13A to 13C). Note that an example of manufacturing the transistor 100 illustrated in FIG. 1B is described here.

Thin films included in the transistor 100 (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Examples of the sputtering method include an RF sputtering method in which a high-frequency power source is used for a sputtering power source, a DC sputtering method in which a DC power source is used, and a pulsed DC sputtering method in which a voltage is applied to an electrode while being changed in a pulsed manner. The RF sputtering method is mainly used in the case where an insulating film is formed, and the DC sputtering method is mainly used in the case where a metal conductive film is formed. The pulsed DC sputtering method is mainly used in the case where a film of a compound such as an oxide, a nitride, or a carbide is formed by a reactive sputtering method.

CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

The PECVD method enables a high-quality film to be obtained at a relatively low temperature. The thermal CVD method does not use plasma and thus causes less plasma damage to an object. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. The thermal CVD method, which does not use plasma, does not cause such plasma damage and thus can increase the yield of the semiconductor device. The thermal CVD method can yield a film with few defects because of no plasma damage during film formation.

As the ALD method, a thermal ALD method, in which a precursor and a reactant react with each other only by a thermal energy, a PEALD method, in which a reactant excited by plasma is used, or the like can be used.

CVD and ALD methods differ from the sputtering method by which particles ejected from a target or the like are deposited. Thus, CVD and ALD methods can provide good step coverage, almost regardless of the shape of an object. In particular, an ALD method can provide excellent step coverage and excellent thickness uniformity and thus can be suitably used for covering a surface of an opening portion with a high aspect ratio, for example. On the other hand, an ALD method has a relatively low film formation rate; thus, it is sometimes preferable to combine the ALD method with another film formation method with a high film formation rate, such as a CVD method.

By a CVD method, a film with a certain composition can be formed by adjusting the flow rate ratio of the source gases. For example, a CVD method enables formation of a film whose composition is gradually changed by changing the flow rate ratio of the source gases during film formation. In the case where the film is formed while changing the flow rate ratio of the source gases, as compared to the case where the film is formed using a plurality of film formation chambers, time taken for the film formation can be reduced because time taken for transfer or pressure adjustment is not required. Hence, the productivity of the semiconductor device can be improved in some cases.

An ALD method, in which a plurality of different kinds of precursors are introduced at a time, enables formation of a film with a desired composition. In the case where a plurality of different kinds of precursors are introduced, the number of cycles for each precursor is controlled, whereby a film with a desired composition can be formed.

Thin films included in the transistor 100 (e.g., insulating films, semiconductor films, and conductive films) can be formed by a method such as spin coating, dipping, spray coating, inkjet printing, dispensing, screen printing, or offset printing, or with a doctor knife, a slit coater, a roll coater, a curtain coater, or a knife coater.

Thin films included in the transistor 100 can be processed by a photolithography method or the like. Besides, a nanoimprinting method, a sandblasting method, a lift-off method, or the like may be employed to process thin films. Alternatively, island-shaped thin films may be directly formed by a film formation method using a shielding mask such as a metal mask.

There are two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light used for exposure in the photolithography method, for example, light with the i-line (wavelength: 365 nm), light with the g-line (wavelength: 436 nm), light with the h-line (wavelength: 405 nm), or light in which two or more of the i-line, the g-line, and the h-line are mixed can be used. Alternatively, ultraviolet rays, KrF laser light, ArF laser light, or the like can be used. Exposure may be performed by a liquid immersion exposure technique. As the light for exposure, extreme ultraviolet (EUV) light or X-rays may also be used. Furthermore, instead of the light used for exposure, an electron beam can be used. It is preferable to use EUV light, X-rays, or an electron beam to perform extremely minute processing. Note that a photomask is not needed when exposure is performed by scanning with a beam such as an electron beam.

For etching of thin films, for example, a dry etching method, a wet etching method, a sandblasting method, or the like can be used. These etching methods may be employed in combination.

An example of a method for manufacturing the transistor 100 is described below.

First, the conductive layer 112a is formed over the substrate 102, and an insulating film 110a_f and an insulating film 110b_f are formed in this order over the conductive layer 112a (FIG. 11A).

For the substrate 102, any of the above-described materials can be used, for example.

The conductive layer 112a can be formed with the above-described material by a sputtering method, for example.

The insulating film 110a_f and the insulating film 110b_f can be formed by a PECVD method using any of the above-described materials that can be used for the insulating layer 110a and the insulating layer 110b, for example. The insulating film 110a_f and the insulating film 110b_f are preferably formed successively in a vacuum without exposure to the air. Such formation can inhibit attachment of atmospherically derived impurities to the surface of the insulating film 110a_f. Examples of the impurities include water and organic substances.

The substrate temperature at the time of forming the insulating films 110a_f and 110b_f is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. When the substrate temperature at the time of forming the insulating films is in the above range, impurities (e.g., water and hydrogen) released from the insulating films can be reduced, which inhibits the diffusion of the impurities to the semiconductor layer 108 that is formed later. Consequently, a transistor with favorable electrical characteristics and high reliability can be obtained.

Note that since the insulating films 110a_f and 110b_f are formed earlier than the semiconductor layer 108, there is no need to consider the probability of oxygen release from the semiconductor layer 108 due to heat applied at the time of the formation of the insulating films.

Heat treatment may be performed after the insulating film 110b_f is formed. By the heat treatment, water and hydrogen can be released from the surface and inside of the insulating film 110b_f.

The heat treatment temperature is preferably higher than or equal to 150° C. and lower than the strain point of the substrate, further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating film 110b_f can be prevented as much as possible. An oven, a rapid thermal annealing (RTA) apparatus, or the like can be used for the heat treatment. With the RTA apparatus, the heat treatment time can be shortened.

After the insulating film 110b_f is formed, treatment for supplying oxygen to the insulating film 110b_f may be performed.

In one embodiment of the present invention, oxygen is supplied to the insulating film 110b_f by forming a metal oxide layer over the insulating film 110b_f after forming the insulating film 110b_f. Heat treatment may be performed after the formation of the metal oxide layer. By the heat treatment performed after the formation of the metal oxide layer, oxygen can be effectively supplied from the metal oxide layer to the insulating film 110b_f, and oxygen can be contained in the insulating film 110b_f. Oxygen supplied to the insulating film 110b_f is supplied to the semiconductor layer 108 in a later step, whereby oxygen vacancies (V_{O}) and V_{O}H in the semiconductor layer 108 can be reduced.

After the formation of the metal oxide layer or the above-described heat treatment, oxygen may be further supplied to the insulating film 110b_f through the metal oxide layer. Oxygen can be supplied by, for example, an ion implantation method, an ion doping method, a plasma immersion ion implantation method, or plasma treatment. For the plasma treatment, an apparatus in which an oxygen gas is made to be plasma by high-frequency power can be suitably used. Examples of an apparatus in which gas is made to be plasma by high-frequency power include a plasma etching apparatus and a plasma ashing apparatus.

The metal oxide layer may be an insulating layer or a conductive layer. For the metal oxide layer, aluminum oxide, hafnium oxide, hafnium aluminate, indium oxide, indium tin oxide (ITO), or indium tin oxide containing silicon (ITSO) can be used, for example.

An oxide material containing one or more of the same elements as those of the semiconductor layer 108 is preferably used for the metal oxide layer. It is particularly preferable to use an oxide semiconductor material that can be used for the semiconductor layer 108.

The metal oxide layer is preferably formed in, for example, an oxygen-containing atmosphere. In particular, the metal oxide layer is preferably formed by a sputtering method in an oxygen-containing atmosphere. Thus, oxygen can be favorably supplied to the insulating film 110b_f at the time of forming the metal oxide layer.

Next, the metal oxide layer is removed. For example, a wet etching method can be suitably used to remove the metal oxide layer.

The treatment for supplying oxygen to the insulating film 110b_f is not necessarily performed by the above-described method. For example, an ion doping method, an ion implantation method, or plasma treatment can be employed to supply an oxygen radical, an oxygen atom, an oxygen atomic ion, an oxygen molecular ion, or the like to the insulating film 110b_f. Furthermore, a film that suppresses oxygen release may be formed over the insulating film 110b_f and then, oxygen may be supplied to the insulating film 110b_f through the film. After the supply of oxygen, the film that suppresses oxygen release is preferably removed. The film that suppresses oxygen release can be formed using a conductive film or a semiconductor film containing one or more of indium, zinc, gallium, tin, aluminum, chromium, tantalum, titanium, molybdenum, nickel, iron, cobalt, and tungsten.

Next, a resist mask is formed over the insulating film 110b_f by a photolithography process (not illustrated), and then the insulating film 110b_f is processed, whereby an insulating layer 110b_e including the depressed portion 143 is formed (FIG. 11B). The insulating film 110b_f can be suitably processed by a dry etching method, for example. After the formation of the insulating layer 110b_e, the resist mask is removed.

Next, an insulating film 110d_f is formed over the insulating layer 110b_e so as to cover the depressed portion 143. The insulating film 110d_f is provided in contact with the top surface of the insulating layer 110b_e inside the depressed portion 143, the side surface of the insulating layer 110b_e inside the depressed portion 143, and the top surface of the insulating layer 110b_e outside the depressed portion 143. The insulating film 110d_f can be formed by a PECVD method using any of the above-described materials that can be used for the insulating layer 110d, for example.

Next, a conductive film 114f to be the conductive layer 114 later is formed over the insulating film 110d_f (FIG. 11C). The conductive film 114f is provided in contact with the top surface of the insulating film 110d_f inside the depressed portion 143, the side surface of the insulating film 110d_f inside the depressed portion 143, and the top surface of the insulating film 110d_f outside the depressed portion 143. The conductive film 114f is provided so that the level of the top surface of the conductive film 114f is higher than the level of the top surface of the insulating film 110d_f outside the depressed portion 143. The conductive film 114f can be formed by a sputtering method using any of the above-described materials that can be used for the conductive layer 114, for example.

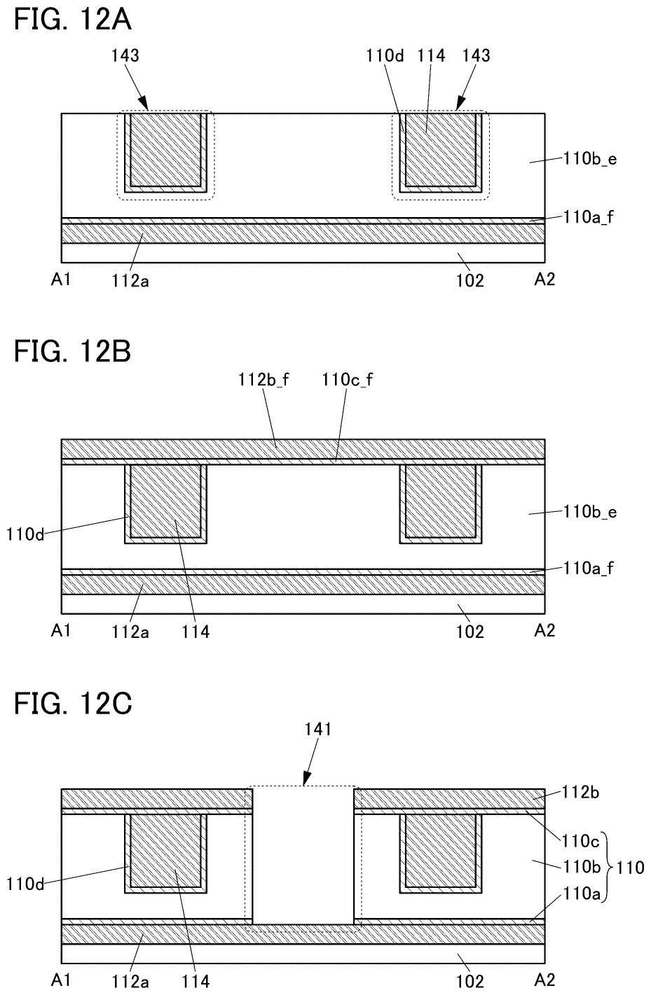

Next, planarization treatment is performed on the conductive film 114f and the insulating film 110d_f by a CMP method until the top surface of the insulating layer 110b_e is exposed, thereby forming the insulating layer 110d in contact with the top surface and the side surface of the insulating layer 110b_e inside the depressed portion 143 and the conductive layer 114 provided over the insulating layer 110d to fill the depressed portion 143 (FIG. 12A). By that treatment, the top surface of the conductive layer 114, the upper end portion of the insulating layer 110d in a region not overlapping with the conductive layer 114, and the top surface of the insulating layer 110b_e in a region not overlapping with the conductive layer 114 become level with each other.

In this manner, in one embodiment of the present invention, the conductive layer 114 is formed so as to selectively fill only the depressed portion 143 by forming the depressed portion 143 in advance in the insulating film to be the insulating layer 110b and then processing the conductive film 114f provided to cover the depressed portion 143. That is, the conductive layer 114 can be formed in a self-aligned manner; thus, the conductive layer 114 can be accurately formed even in a miniaturized transistor. Thus, a method for manufacturing a semiconductor device with a small variation in electrical characteristics of transistors and with high productivity can be provided.

Next, an insulating film 110c_f is formed in contact with the top surface of the conductive layer 114 and the top surface of the insulating layer 110b_e. The insulating film 110c_f can be formed by a PECVD method using any of the above-described materials that can be used for the insulating layer 110c, for example.

Next, a conductive film 112b_f to be the conductive layer 112b later is formed over the insulating film 110c_f (FIG. 12B). The conductive film 112b_f can be formed by a sputtering method using any of the above-described materials that can be used for the conductive layer 112b, for example.

Next, a resist mask is formed over the conductive film 112b_f by a photolithography process (not illustrated). The resist mask is formed in a position excluding a region surrounded by the depressed portion 143 (a position as close as possible to the center of the region) in a plan view. Then, the conductive film 112b_f, the insulating film 110c_f, the insulating layer 110b_e, and the insulating film 110a_f are processed to form the conductive layer 112b, the insulating layer 110c, the insulating layer 110b, and the insulating layer 110a including the opening 141 (FIG. 12C). By this processing, the conductive layer 112a is exposed in a region overlapping with the opening 141. After the processing, the resist mask is removed.

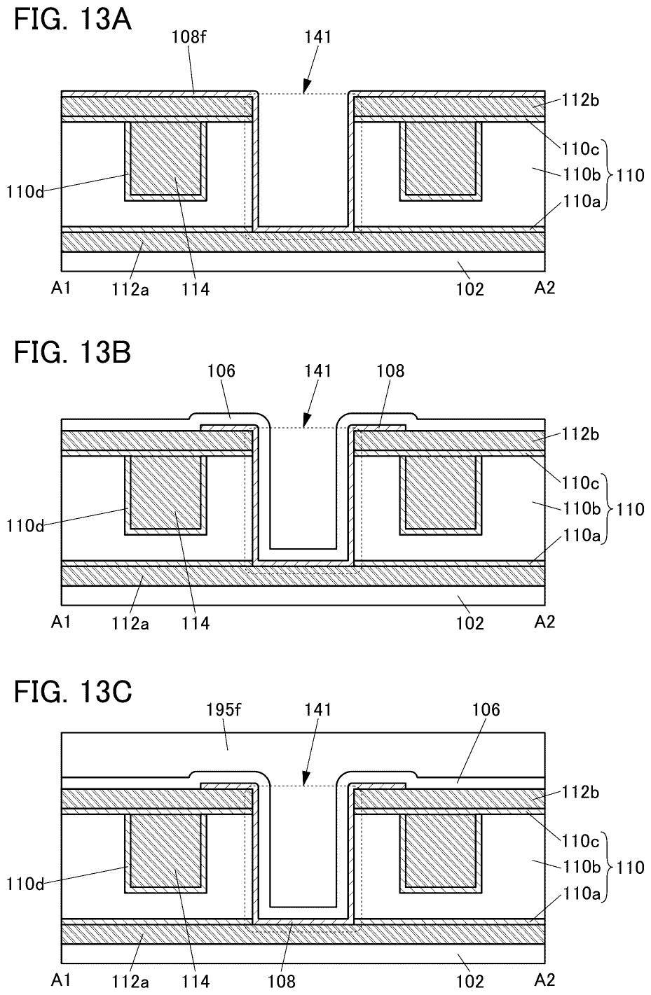

Next, a metal oxide film 108f to be the semiconductor layer 108 later is formed in contact with the top surface of the conductive layer 112a inside the opening 141, the side surface of the insulating layer 110 (the insulating layer 110a, the insulating layer 110b, and the insulating layer 110c) inside the opening 141, the side surface of the conductive layer 112b inside the opening 141, and the top surface of the conductive layer 112b (FIG. 13A). The metal oxide film 108f is preferably formed by a sputtering method using a metal oxide target.

The metal oxide film 108f is preferably a dense film with as few defects as possible. The metal oxide film 108f is preferably a highly purified film in which impurities containing the element hydrogen are reduced as much as possible. It is particularly preferable to use a metal oxide film having crystallinity as the metal oxide film 108f.

In forming the metal oxide film 108f, an oxygen gas and an inert gas (such as a helium gas, an argon gas, or a xenon gas) may be mixed. The higher the proportion of the oxygen gas in the whole film formation gas (oxygen flow rate ratio) is in forming the metal oxide film 108f, the higher the crystallinity of the metal oxide film 108f can be in some cases. Accordingly, the transistor 100 can have high reliability in some cases. On the other hand, the lower the oxygen flow rate ratio is, the lower the crystallinity of the metal oxide film 108f is in some cases. Accordingly, the transistor 100 can have a high on-state current in some cases.

A higher substrate temperature during the formation of the metal oxide film 108f leads to higher crystallinity and higher density of the metal oxide film in some cases. By contrast, a lower substrate temperature during the formation leads to lower crystallinity and higher electrical conductivity of the metal oxide film 108f in some cases.

The substrate temperature during the formation of the metal oxide film 108f is higher than or equal to room temperature and lower than or equal to 250° C., preferably higher than or equal to room temperature and lower than or equal to 200° C., further preferably higher than or equal to room temperature and lower than or equal to 140° C. For example, the substrate temperature is preferably set to be higher than or equal to room temperature and lower than or equal to 140° C. to increase the productivity.

In the case where the semiconductor layer 108 has a stacked-layer structure, an upper metal oxide film is preferably formed successively after the formation of a lower metal oxide film without exposure of the surface of the lower metal oxide film to the air.

For example, the semiconductor layer 108 containing a metal oxide can be formed by an ALD method using a precursor containing a constituent metal element and an oxidizer.

For example, a film of In—Ga—Zn oxide can be formed using a precursor containing indium, a precursor containing gallium, and a precursor containing zinc. Alternatively, a precursor containing indium and a precursor containing gallium and zinc may be used.

As the precursor containing indium, triethylindium, tris(2,2,6,6-tetramethyl-3,5-heptanedionato)indium, cyclopentadienylindium, indium(III) chloride, (3-(dimethylamino)propyl)dimethylindium, or the like can be used.

As the precursor containing gallium, trimethylgallium, triethylgallium, gallium trichloride, tris(dimethylamide)gallium, gallium(III) acetylacetonate, tris(2,2,6,6-tetramethyl-3,5-heptanedionato)gallium, dimethylchlorogallium, diethylchlorogallium, or gallium(III) chloride, or the like can be used.

As the precursor containing zinc, dimethylzinc, diethylzinc, bis(2,2,6,6-tetramethyl-3,5-heptanedionato)zinc, zinc chloride, or the like can be used.

Ozone, oxygen, water, or the like can be used as the oxidizer.

As an example of a method for controlling the composition of a film to be formed, adjusting the flow rate ratio, flowing time, flowing order, or the like of the source gases is given. By adjusting such conditions, a film whose composition is gradually changed can be formed. Furthermore, films having different compositions can be formed successively.

Heat treatment may be performed after the metal oxide film 108f is formed. By the heat treatment, water or hydrogen can be released from the surface and inside of the metal oxide film 108f. By the heat treatment, oxygen can also be supplied from the insulating layer 110b to the metal oxide film 108f. Furthermore, the film quality of the metal oxide film 108f is improved (e.g., the number of defects is reduced or crystallinity is increased) by the heat treatment in some cases. For the heat treatment, the conditions for the above heat treatment that can be used after the formation of the insulating films 110a_fand 110b_f can be used.

Note that the heat treatment is not necessarily performed. The heat treatment is not necessarily performed in this step, and heat treatment performed in a later step may also serve as the heat treatment in this step. In some cases, treatment at a high temperature (e.g., film formation step) or the like in a later step can serve as the heat treatment in this step.

Next, the metal oxide film 108f is processed into an island shape to include a region overlapping with the opening 141 in a plan view, whereby the semiconductor layer 108 is formed.

For the formation of the semiconductor layer 108, either one or both of a wet etching method and a dry etching method can be used. For example, a wet etching method can be suitably used to form the semiconductor layer 108.

Next, the insulating layer 106 is formed to cover the semiconductor layer 108 and the top surface of the conductive layer 112b (FIG. 13B). The insulating layer 106 can be formed with the above-described material by a PECVD method, for example.

When an oxide semiconductor is used for the semiconductor layer 108, an insulating material in which oxygen is contained and hydrogen is reduced is preferably used for the insulating layer 106. Thus, the semiconductor layer 108 including a region in contact with the insulating layer 106 is less likely to have n-type conductivity. In addition, oxygen can be supplied from the insulating layer 106 to the semiconductor layer 108 efficiently, and accordingly, oxygen vacancies (V_{O}) in the semiconductor layer 108 can be reduced. The semiconductor layer 108 functions as the semiconductor layer where the channel of the transistor 100 is formed later. Thus, the insulating layer 106 using the material described above allows the transistor 100 to have favorable electrical characteristics and high reliability.

When the temperature at the time of forming the insulating layer 106 functioning as the gate insulating layer of the transistor 100 is increased, defects in the insulating layer 106 can be reduced. However, the high temperature at the time of forming the insulating layer 106 sometimes allows release of oxygen from the semiconductor layer 108, which increases the amount of oxygen vacancies (V_{O}) and V_{O}H generated by hydrogen entry into oxygen vacancies in the semiconductor layer 108. The substrate temperature at the time of forming the insulating layer 106 is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, the transistor 100 can have favorable electrical characteristics and high reliability.

Before the formation of the insulating layer 106, a surface of the semiconductor layer 108 may be subjected to plasma treatment. By the plasma treatment, impurities such as water adsorbed on the surface of the semiconductor layer 108 can be reduced. Accordingly, impurities at the interface between the semiconductor layer 108 and the insulating layer 106 can be reduced, enabling the transistor 100 to have high reliability. Performing the plasma treatment in this manner is particularly favorable in the case where the surface of the semiconductor layer 108 is exposed to the air after the formation of the semiconductor layer 108 and before the formation of the insulating layer 106. The plasma treatment can be performed in an atmosphere of oxygen, ozone, nitrogen, dinitrogen monoxide, argon, or the like. The plasma treatment and the formation of the insulating layer 106 are preferably performed successively without exposure to the air.

Next, an insulating film 195f to be the insulating layer 195 is formed over the insulating layer 106 to fill the opening 141 (FIG. 13C). The insulating film 195f is provided so that the level of the top surface of the insulating film 195f is higher than the level of the top surface of the insulating layer 106 outside the opening 141. The insulating film 195f can be formed by a PECVD method using any of the above-described materials that can be used for the insulating layer 195, for example.

Next, the insulating film 195f is processed to form the insulating layer 195 having an opening in a region overlapping with the opening 141 (not illustrated). For the processing of the insulating film 195f, either one or both of a wet etching method and a dry etching method can be used. By this processing, the insulating layer 106 is exposed in the region overlapping with the opening 141.

Next, a conductive film to be the conductive layer 104 later is formed over the insulating layer 106 (not illustrated). The conductive film is provided in contact with at least the side surface and the top surface of the insulating layer 106 inside the opening 141. The conductive film is provided so that the level of the top surface of the conductive film is higher than the level of the top surface of the insulating layer 195 outside the opening 141. The conductive film can be formed by a sputtering method using any of the above-described materials that can be used for the conductive layer 104, for example.

Next, planarization treatment is performed on the conductive film by a CMP method until the top surface of the insulating layer 195 is exposed, whereby the conductive layer 104 including a region filling the opening 141 is formed (FIG. 1). By that treatment, the top surface of the conductive layer 104 and the top surface of the insulating layer 195 become level with each other.

Through the above process, the transistor 100 illustrated in FIG. 1B can be manufactured.

### Manufacturing Method Example 2

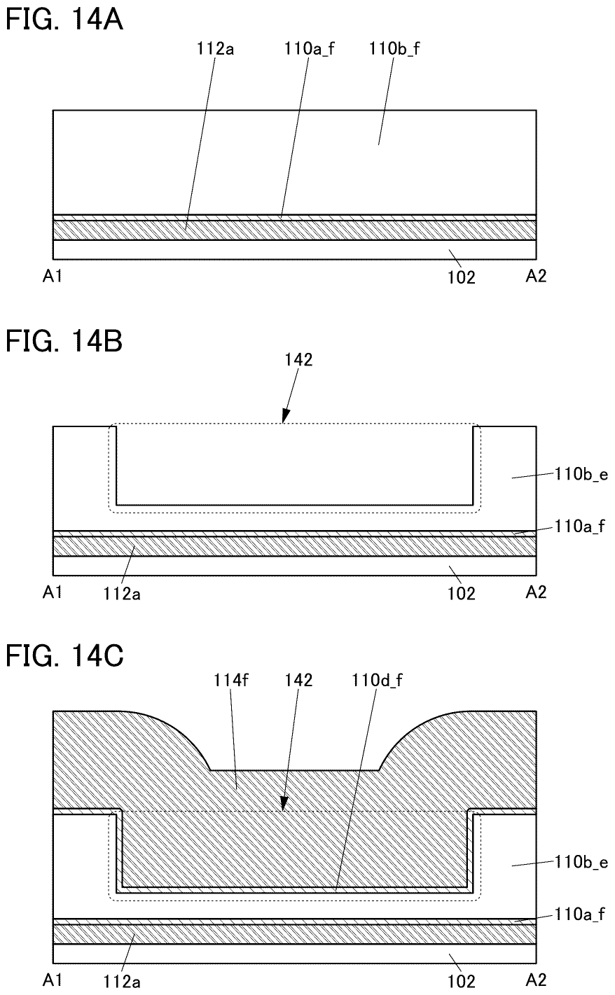

An example of manufacturing the transistor 100A illustrated in FIG. 3B is described below with reference to drawings (FIGS. 14A to 14C, FIGS. 15A to 15C, FIGS. 16A to 16C, and FIGS. 17A and 17B). Note that portions similar to those described above are not described in some cases.

First, the conductive layer 112a is formed over the substrate 102, and the insulating film 110a_f and the insulating film 110b_f are formed in this order over the conductive layer 112a (FIG. 14A).

For details of the formation, the description of FIG. 11A in <Manufacturing method example 1> can be referred to.

Next, a resist mask is formed over the insulating film 110b_f by a photolithography process (not illustrated), and then the insulating film 110b_f is processed, whereby the insulating layer 110b_e including the depressed portion 142 is formed (FIG. 14B). The insulating film 110b_f can be suitably processed by a dry etching method, for example. After the formation of the insulating layer 110b_e, the resist mask is removed.

Next, the insulating film 110d_f is formed over the insulating layer 110b_e so as to cover the depressed portion 142. The insulating film 110d_f is provided in contact with the top surface of the insulating layer 110b_e inside the depressed portion 142, the side surface of the insulating layer 110b_e inside the depressed portion 142, and the top surface of the insulating layer 110b_e outside the depressed portion 142.

Next, the conductive film 114f to be the conductive layer 114 later is formed over the insulating film 110d_f (FIG. 14C). The conductive film 114f is provided in contact with the top surface of the insulating film 110d_f inside the depressed portion 142, the side surface of the insulating film 110d_f inside the depressed portion 142, and the top surface of the insulating film 110d_f outside the depressed portion 142. The conductive film 114f is provided so that the level of the top surface of the conductive film 114f is higher than the level of the top surface of the insulating film 110d_f outside the depressed portion 142.

Note that the description of FIG. 11C in <Manufacturing Method Example 1> can be referred to for details of materials, formation methods, and the like that can be used for the insulating film 110d_f and the conductive film 114f.

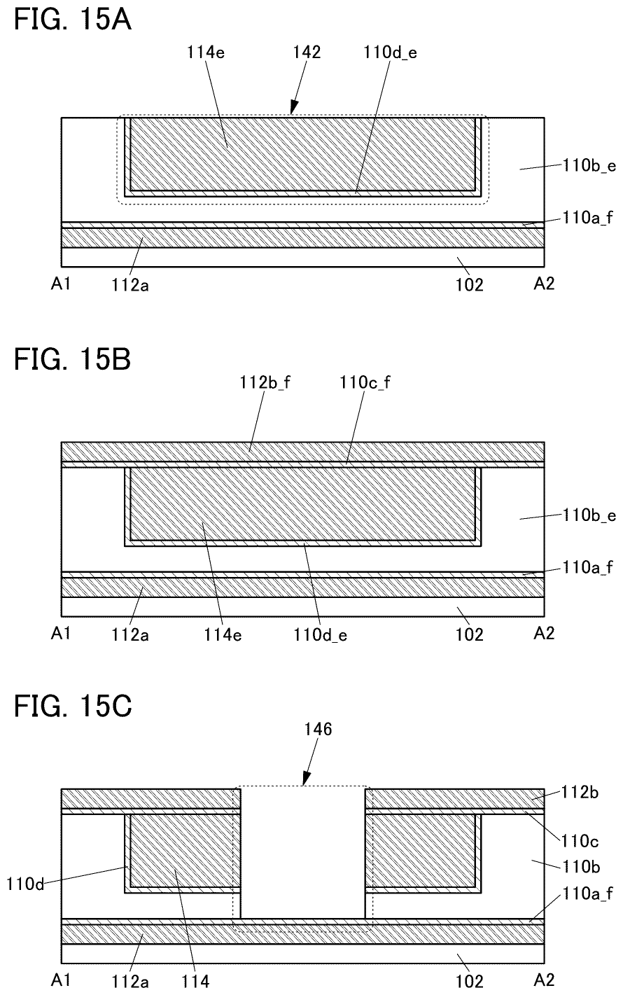

Next, planarization treatment is performed on the conductive film 114f and the insulating film 110d_f by a CMP method until the top surface of the insulating layer 110b_e is exposed, thereby forming an insulating layer 110d_e in contact with the top surface and the side surface of the insulating layer 110b_e inside the depressed portion 142 and a conductive layer 114e provided over the insulating layer 110d_e to fill the depressed portion 142 (FIG. 15A). By that treatment, the top surface of the conductive layer 114e, the upper end portion of the insulating layer 110d_e in a region not overlapping with the conductive layer 114e, and the top surface of the insulating layer 110b_e in a region not overlapping with the conductive layer 114e become level with each other.

Next, the insulating film 110c_f is formed in contact with the top surface of the conductive layer 114e and the top surface of the insulating layer 110b_e.

Next, the conductive film 112b_f to be the conductive layer 112b later is formed over the insulating film 110c_f (FIG. 15B).

Note that the description of FIG. 12B in <Manufacturing Method Example 1> can be referred to for details of materials, formation methods, and the like that can be used for the insulating film 110c_f and the conductive film 112b_f.

Next, a resist mask is formed over the conductive film 112b_f by a photolithography process (not illustrated). The resist mask is formed to include a region overlapping with at least the end portion of the depressed portion 142 in a plan view. Then, the conductive film 112b_f, the insulating film 110c_f, the conductive layer 114e, the insulating layer 110d_e, and the insulating layer 110b_e are processed to form the conductive layer 112b, the insulating layer 110c, the conductive layer 114, the insulating layer 110d, and the insulating layer 110b including the opening 146 in a region overlapping with the depressed portion 142 (FIG. 15C). By this processing, the conductive layer 110a_f is exposed in a region overlapping with the opening 146. After the processing, the resist mask is removed.

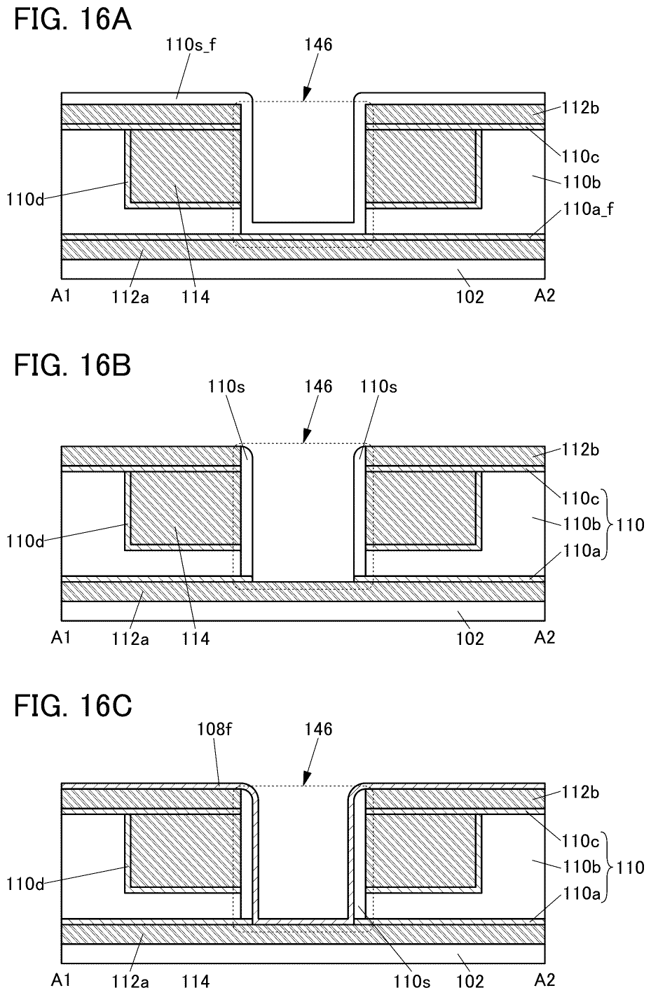

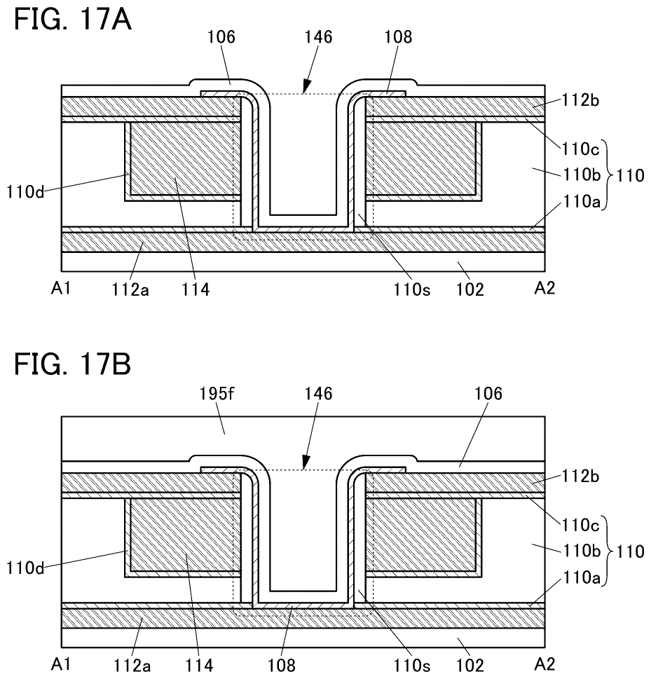

Although FIG. 15C illustrates an example in which the insulating film 110a_f is exposed inside the opening 146, the conductive layer 112a may be exposed inside the opening 146 by further successively forming an opening in the insulating film 110a_f. When the steps illustrated in FIGS. 16A to 16C and FIGS. 17A and 17B are then performed, the transistor 100J illustrated in FIG. 10B can be manufactured.

Next, an insulating film 110s_f to be the insulating layer 110s later is formed in contact with the top surface of the insulating film 110a_f inside the opening 146, the side surface of the insulating layer 110b inside the opening 146, the side surface of the insulating layer 110d inside the opening 146, the side surface of the conductive layer 114 inside the opening 146, the side surface of the insulating layer 110c inside the opening 146, the side surface of the conductive layer 112b inside the opening 146, and the top surface of the conductive layer 112b (FIG. 16A). For the insulating film 110s_f, any of the above-described materials that can be used for the insulating layer 110s can be used.

For example, the insulating film 110s_f is preferably formed by a CVD method, an ALD method, or the like, in which case the insulating film 110s_f can favorably cover the side surface of the insulating layer 110b inside the opening 146, the side surface of the insulating layer 110d inside the opening 146, the side surface of the conductive layer 114 inside the opening 146, the side surface of the insulating layer 110c inside the opening 146, and the side surface of the conductive layer 112b inside the opening 146.

Next, part of the insulating film 110s_f is removed to form the insulating layer 110s (FIG. 16B). Specifically, part of a region of the insulating film 110s_f that is in contact with the top surface of the insulating film 110a_f inside the opening 146 and a region of the insulating film 110s_f that is in contact with the top surface of the conductive layer 112b are removed. At least a region of the insulating film 110s_f that is in contact with the side surface of the insulating layer 110b inside the opening 146, the side surface of the insulating layer 110d inside the opening 146, the side surface of the conductive layer 114 inside the opening 146, the side surface of the insulating layer 110c inside the opening 146, and the side surface of the conductive layer 112b inside the opening 146 is left, whereby the insulating layer 110s can be formed. The upper end portion of the insulating layer 110s has a curved shape in some cases.

Note that when the insulating layer 110s is formed, part of a region of the insulating film 110a_f overlapping with the opening 146 is removed, whereby the insulating layer 110a including an opening is formed. Inside the opening, the conductive layer 112a is exposed.

The insulating layer 110s can be formed by anisotropic etching, for example. Specifically, the insulating layer 110s can be formed by performing highly anisotropic etching treatment using a dry etching method, for example.

Next, the metal oxide film 108f to be the semiconductor layer 108 later is formed in contact with the top surface of the conductive layer 112a in the region overlapping with the opening 146, the side surface of the insulating layer 110a in the region overlapping with the opening 146, the side surface of the insulating layer 110s inside the opening 146, the curved portion of the insulating layer 110s, and the top surface of the conductive layer 112b (FIG. 16C). The description of FIG. 13A in <Manufacturing method example 1> can be referred to for details of materials, formation methods, and the like that can be used for the metal oxide film 108f.

Next, the metal oxide film 108f is processed into an island shape to include a region overlapping with the opening 146 in a plan view, whereby the semiconductor layer 108 is formed. The description of FIG. 13B in <Manufacturing Method Example 1> can be referred to for methods that can be used for the semiconductor layer 108.

Next, the insulating layer 106 is formed to cover the semiconductor layer 108 and the top surface of the conductive layer 112b (FIG. 17A). The description of FIG. 13B in <Manufacturing Method Example 1> can be referred to for details of materials, formation methods, and the like that can be used for the insulating layer 106.

Next, the insulating film 195f to be the insulating layer 195 is formed over the insulating layer 106 to fill the opening 146 (FIG. 17B). The insulating film 195f is provided so that the level of the top surface of the insulating film 195f is higher than the level of the top surface of the insulating layer 106 outside the opening 146. The description of FIG. 13C in <Manufacturing Method Example 1> can be referred to for details of materials, formation methods, and the like that can be used for the insulating film 195f.

Next, the steps after the above step in the description of FIG. 13C in <Manufacturing Method Example 1> are performed to form the conductive layer 104 including a region filling the opening 146 and the insulating layer 195 provided so that the conductive layer 104 is embedded in the insulating layer 195 (FIG. 3B).

Through the above process, the transistor 100A illustrated in FIG. 3B can be fabricated.

This embodiment can be combined with any of the other embodiments as appropriate. In this specification, in the case where a plurality of structure examples are given in one embodiment, the structure examples can be combined as appropriate.

### Embodiment 2

In this embodiment, a semiconductor device 900 of one embodiment of the present invention is described. The semiconductor device 900 can function as a memory device.

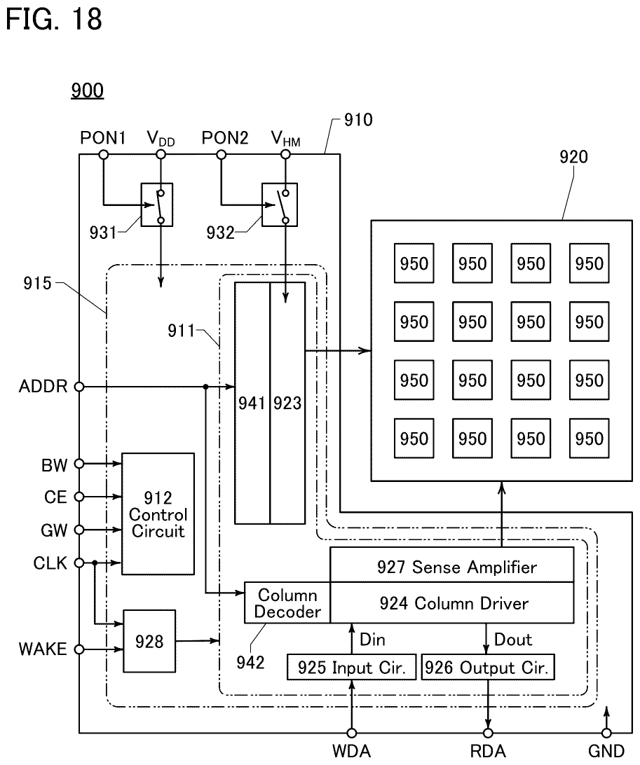

FIG. 18 is a block diagram illustrating a structure example of the semiconductor device 900. The semiconductor device 900 illustrated in FIG. 18 includes a driver circuit 910 and a memory array 920. The memory array 920 includes at least one memory cell 950. FIG. 18 illustrates an example in which the memory array 920 includes a plurality of memory cells 950 arranged in a matrix.

The transistor exemplified in the above embodiment can be used for the memory cell 950. With the use of the above transistor, a memory device can be miniaturized and highly integrated. In addition, the memory device can have a large capacity per area. In addition, the memory device can achieve high-speed data writing. In addition, the memory device can achieve high-speed data reading. In addition, the memory device can retain data for a long time. In addition, the memory device can achieve low power consumption.

The driver circuit 910 includes a power switch (PSW) 931, a PSW 932, and a peripheral circuit 915. The peripheral circuit 915 includes a peripheral circuit 911, a control circuit 912, and a voltage generation circuit 928.

In the semiconductor device 900, the circuits, signals, and voltages can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal. The signal GW is a global write enable signal. The signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the entire operation of the semiconductor device 900. For example, the control circuit 912 performs logical operation on the signal CE, the signal GW, and the signal BW to determine the operating mode (e.g., write operation or read operation) of the semiconductor device 900. Alternatively, the control circuit 912 generates a control signal for the peripheral circuit 911 so that the operating mode is executed.

The voltage generation circuit 928 has a function of generating a negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925 (Input Cir.), an output circuit 926 (Output Cir.), and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained by the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of V_{DD} to the peripheral circuit 915. The PSW 932 has a function of controlling the supply of V_{H}M to the row driver 923. Here, in the semiconductor device 900, a high power supply voltage is V_{DD} and a low power supply voltage is GND (ground potential). In addition, V_{H}M is a high power supply voltage used for setting a word line to a high level and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 18 but can be more than one. In that case, a power switch is provided for each power domain.

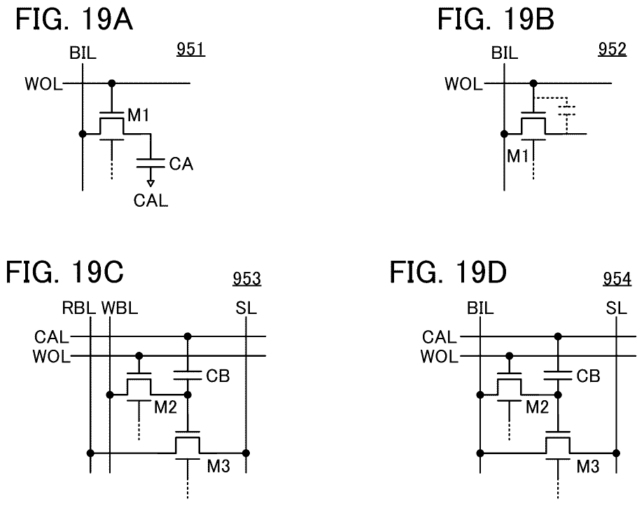

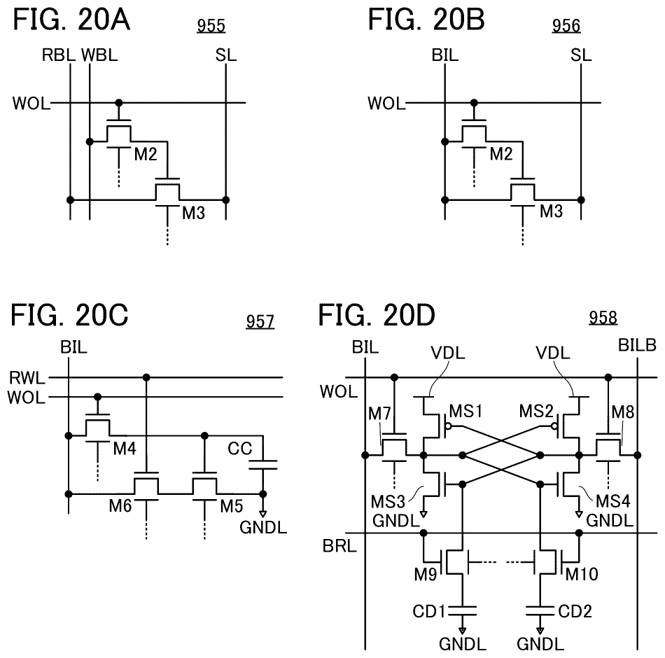

Structure examples of other memory cells each of which can be used as the memory cell 950 are described with reference to FIGS. 19A to 19D and FIGS. 20A to 20D.

### [DOSRAM]

FIG. 19A illustrates a circuit structure example of a memory cell for a DRAM. In this specification and the like, a DRAM using an OS transistor is referred to as a dynamic oxide semiconductor random access memory (DOSRAM). A memory cell 951 includes a transistor M1 and a capacitor CA.

As the transistor M1, the transistor of one embodiment of the present invention can be used. The transistor M1 includes a first gate (also referred to as simply a gate or a front gate in some cases) and a second gate (also referred to as a back gate in some cases). In FIG. 19A, the connection destination of the second gate of the transistor M1 is not specified. As described in Embodiment 1, the second gate of the transistor of one embodiment of the present invention may be connected to a wiring supplied with a constant potential or a signal or may be connected to the first gate. The connection destinations of second gates are not specified also in transistors included in memory cells illustrated in FIGS. 19B to 19D and FIGS. 20A to 20D; however, the same applies to these transistors as to the transistor M1.

A first terminal of the transistor M1 is connected to a first terminal of the capacitor CA. A second terminal of the transistor M1 is connected to a wiring BIL. The first gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and data reading, a low-level potential (referred to as a reference potential in some cases) is preferably applied to the wiring CAL.

Data writing and data reading are performed by applying a high-level potential to the wiring WOL to turn on the transistor M1, thereby connecting the wiring BIL to the first terminal of the capacitor CA.

The memory cell that can be used as the memory cell 950 is not limited to the memory cell 951, and the circuit structure can be changed. For example, the structure of a memory cell 952 illustrated in FIG. 19B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the first gate, which is shown by a dashed line. With such a structure, the structure of the memory cell can be greatly simplified.

Note that the transistor M1 is preferably the OS transistor described in the above embodiment. The use of the OS transistor described in the above embodiment enables a reduction in the area occupied by the memory cell. In addition, the OS transistor has a characteristic of an extremely low off-state current. The use of the OS transistor as the transistor M1 enables an extremely low leakage current of the transistor M1. That is, the transistor M1 enables written data to be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 19C illustrates a circuit structure example of a gain memory cell including two transistors and one capacitor. A memory cell 953 includes a transistor M2, a transistor M3, and a capacitor CB. In this specification and the like, a memory device including a gain memory cell using an OS transistor as the transistor M2 is referred to as a nonvolatile oxide semiconductor RAM (NOSRAM).

Although FIG. 19C illustrates an example in which both the transistor M2 and the transistor M3 in the memory cell 953 include a second gate, at least one of the transistors includes the second gate. The transistor of one embodiment of the present invention can be used as the transistor including the second gate. The same applies to the transistors M2 and the transistors M3 included in a memory cell 954 illustrated in FIG. 19D, a memory cell 955 illustrated in FIG. 20A, and a memory cell 956 illustrated in FIG. 20B.

A first terminal of the transistor M2 is connected to a first terminal of the capacitor CB. A second terminal of the transistor M2 is connected to a wiring WBL. The first gate of the transistor M2 is connected to the wiring WOL. A second terminal of the capacitor CB is connected to the wiring CAL. A first terminal of the transistor M3 is connected to a wiring RBL. A second terminal of the transistor M3 is connected to a wiring SL. A first gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (referred to as a reference potential in some cases) is preferably applied to the wiring CAL.

Data writing is performed by applying a high-level potential to the wiring WOL to turn on the transistor M2, thereby connecting the wiring WBL to the first terminal of the capacitor CB. Specifically, when the transistor M2 is on, a potential corresponding to data to be stored is applied to the wiring WBL, and the potential is written to the first terminal of the capacitor CB and the first gate of the transistor M3. Then, a low-level potential is applied to the wiring WOL to turn off the transistor M2, whereby the potential of the first terminal of the capacitor CB and the potential of the first gate of the transistor M3 are retained.

Data reading is performed by applying a predetermined potential to the wiring SL. A current flowing between the source and the drain of the transistor M3 and the potential of the first terminal of the transistor M3 are determined by the potential of the first gate of the transistor M3 and the potential of the second terminal of the transistor M3. Accordingly, by reading a potential of the wiring RBL connected to the first terminal of the transistor M3, a potential retained at the first terminal of the capacitor CB (or the first gate of the transistor M3) can be read. That is, data written to the memory cell can be read on the basis of the potential retained at the first terminal of the capacitor CB (or the first gate of the transistor M3).

As another example, one wiring BIL may be provided instead of the wiring WBL and the wiring RBL. A circuit structure example of the memory cell is illustrated in FIG. 19D. In the memory cell 954, one wiring BIL is provided instead of the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

The memory cell 955 illustrated in FIG. 20A is an example in which the capacitor CB and the wiring CAL in the memory cell 953 are omitted. The memory cell 956 illustrated in FIG. 20B is an example in which the capacitor CB and the wiring CAL in the memory cell 954 are omitted. Such structures enable high integration of memory cells.

Note that at least the transistor M2 is preferably the OS transistor described in the above embodiment. It is particularly preferable that the transistor M2 and the transistor M3 each be the OS transistor described in the above embodiment. The use of the OS transistor described in the above embodiment enables a reduction in the area occupied by the memory cell.

Since the OS transistor has a characteristic of an extremely low off-state current, the transistor M2 enables written data to be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of NOSRAMs.

Note that the transistor M3 may be a Si transistor. The Si transistor can have a higher field-effect mobility than the OS transistor and can be formed as a p-channel transistor, so that circuit design flexibility can be increased.

When the OS transistor is used as the transistor M3, the memory cell can be configured with the transistors having the same conductivity type.

FIG. 20C illustrates an example of a gain memory cell 957 including three transistors and one capacitor. The memory cell 957 includes transistors M4 to M6 and a capacitor CC.

Although FIG. 20C illustrates an example in which all the transistors M4 to M6 in the memory cell 957 include a second gate, at least one of the transistors includes the second gate. The transistor of one embodiment of the present invention can be used as the transistor including the second gate.

A first terminal of the transistor M4 is connected to a first terminal of the capacitor CC. A second terminal of the transistor M4 is connected to the wiring BIL. A first gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A first gate of the transistor M5 is connected to the first terminal of the capacitor CC. A second terminal of the transistor M6 is connected to the wiring BIL. A first gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed by applying a high-level potential to the wiring WOL to turn on the transistor M4, thereby connecting the wiring BIL to the first terminal of the capacitor CC. Specifically, when the transistor M4 is on, a potential corresponding to data to be stored is applied to the wiring BIL, and the potential is written to the first terminal of the capacitor CC and the first gate of the transistor M5. Then, a low-level potential is applied to the wiring WOL to turn off the transistor M4, whereby the potential of the first terminal of the capacitor CC and the potential of the first gate of the transistor M5 are retained.

Data reading is performed by precharging the wiring BIL to a predetermined potential, and then making the wiring BIL in an electrically floating state and applying a high-level potential to the wiring RWL. Since the wiring RWL has the high-level potential, the transistor M6 is turned on, so that the wiring BIL is connected to the second terminal of the transistor M5. At this time, the potential of the wiring BIL is applied to the second terminal of the transistor M5; the potential of the second terminal of the transistor M5 and the potential of the wiring BIL change depending on the potential retained at the first terminal of the capacitor CC (or the first gate of the transistor M5). Here, the potential retained at the first terminal of the capacitor CC (or the first gate of the transistor M5) can be read by reading the potential of the wiring BIL. That is, data written to the memory cell can be read on the basis of the potential retained at the first terminal of the capacitor CC (or the first gate of the transistor M5).

Note that at least the transistor M4 is preferably the OS transistor described in the above embodiment. The use of the OS transistor described in the above embodiment enables a reduction in the area occupied by the memory cell.

Note that the transistor M5 and the transistor M6 may be Si transistors. As described above, a Si transistor may have a higher field-effect mobility than the OS transistor depending on the crystal state of silicon used in a semiconductor layer, for example.

When OS transistors are used as the transistors M5 and M6, the memory cell can be configured with the transistors having the same conductivity type.

### [OS-SRAM]

FIG. 20D illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 20D is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

Although FIG. 20D illustrates an example in which all the transistors M7 to M10 in the memory cell 958 include a second gate, at least one of the transistors includes the second gate. Although FIG. 20D illustrates an example in which none of the transistors MS1 to MS4 include a second gate, each of the transistors may include the second gate. The transistor of one embodiment of the present invention can be used as the transistor including the second gate.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A first gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A first gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. A first gate of the transistor M9 is connected to a wiring BRL. A second terminal of the transistor M10 is connected to a first terminal of the capacitor CD2. A first gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential applied to the wiring BIL (i.e., the signal input to the wiring BIL) is output to the wiring BILB. Since the transistor M9 and the transistor M10 are on, the potential of the second terminal of the transistor M7 is retained at the first terminal of the capacitor CD2, and the potential of the second terminal of the transistor M8 is retained at the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed by precharging the wiring BIL and the wiring BILB with a predetermined potential, and then applying a high-level potential to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, the transistors M7 to M10 enable written data to be retained for a long time, and thus the frequency of refresh operation for the memory cell can be decreased. Alternatively, refresh operation for the memory cell can be omitted. The use of the OS transistors described in the above embodiment as the transistors M7 to M10 enables a reduction in the area occupied by the memory cell.

Note that the transistors MS1 to MS4 may be Si transistors.

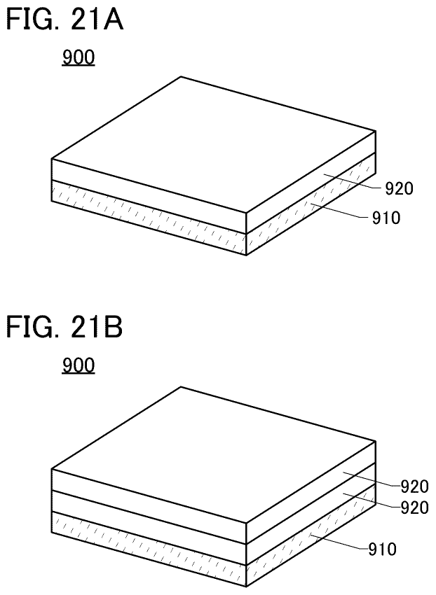

The driver circuit 910 and the memory array 920 included in the semiconductor device 900 may be provided on the same plane. Alternatively, as illustrated in FIG. 21A, the driver circuit 910 and the memory array 920 may be provided to overlap with each other. Overlapping the driver circuit 910 and the memory array 920 can shorten a signal propagation distance. As illustrated in FIG. 21B, a plurality of memory arrays 920 may be stacked over the driver circuit 910.

Next, description is made on an example of an arithmetic processing device that can include the semiconductor device, such as the memory device described above.

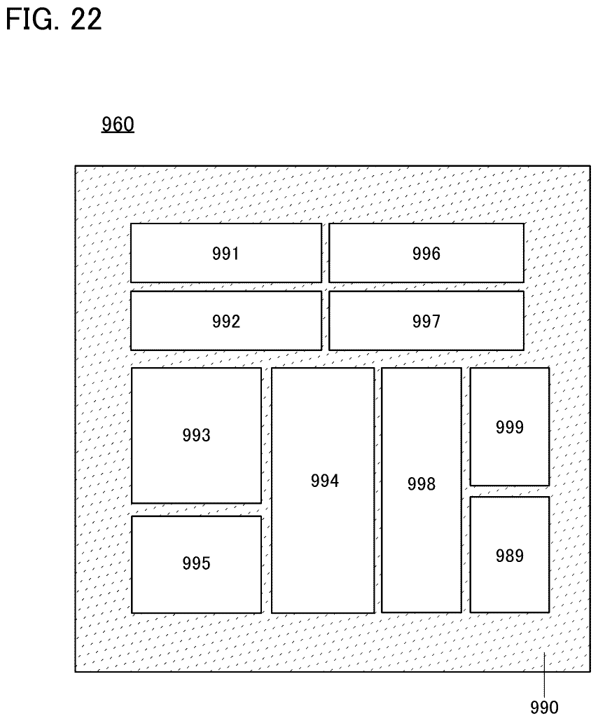

FIG. 22 is a block diagram of an arithmetic device 960. The arithmetic device 960 illustrated in FIG. 22 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 22 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 22 is only an example with a simplified configuration, and the actual arithmetic device 960 has a variety of configurations depending on the application. For example, what is called a multicore configuration is preferably employed in which a plurality of cores each including the arithmetic device 960 in FIG. 22 operate in parallel. A larger number of cores can further enhance the arithmetic performance. The number of cores is preferably larger; for example, the number is preferably 2, further preferably 4, further preferably 8, further preferably 12, further preferably 16 or larger. For application requiring extremely high arithmetic performance, e.g., a server, it is preferable to employ the multicore configuration including 16 or more, preferably 32 or more, further preferably 64 or more cores. The number of bits that the arithmetic device 960 can handle with an internal arithmetic circuit or a data bus can be 8, 16, 32, or 64, for example.

An instruction input to the arithmetic device 960 through the bus interface 998 is input to the instruction decoder 993 and decoded, which is then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 processes an interrupt request from an external input/output device, a peripheral circuit, or the like after making a determination based on its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 22, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, power supply voltage is supplied to the memory cell in the register 996. When data retention by the capacitor is selected, the data is rewritten into the capacitor, and supply of power supply voltage to the memory cell in the register 996 can be stopped.

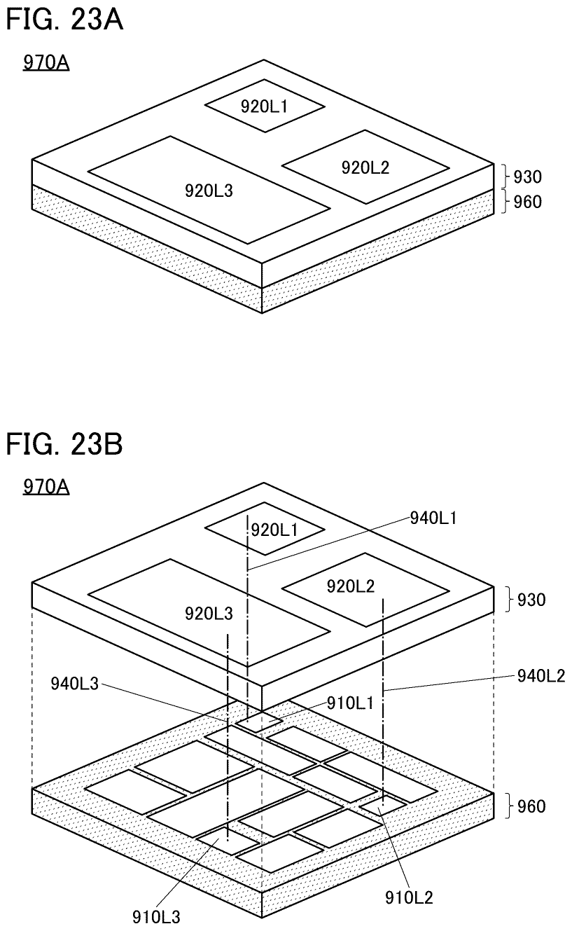

The memory array 920 and the arithmetic device 960 can be provided to overlap with each other. FIGS. 23A and 23B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 23B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 23B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

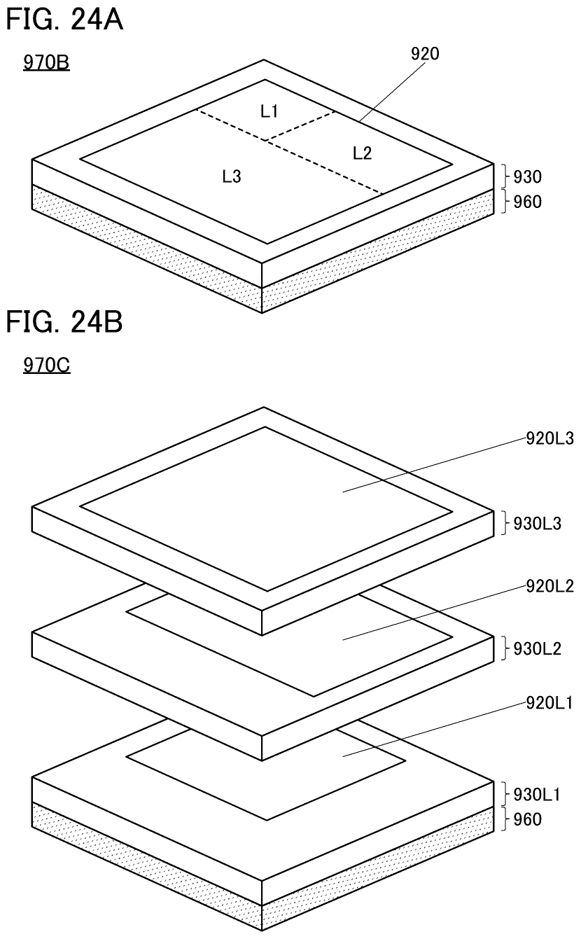

The layer 930 including one memory array 920 may be provided to overlap with the arithmetic device 960. FIG. 24A is a perspective view of a semiconductor device 970B.

In the semiconductor device 970B, one memory array 920 can be divided into a plurality of areas having different functions. FIG. 24A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 24B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined with any of the other embodiments in this specification as appropriate.

### Embodiment 3

In this embodiment, application examples of the memory device of one embodiment of the present invention are described.

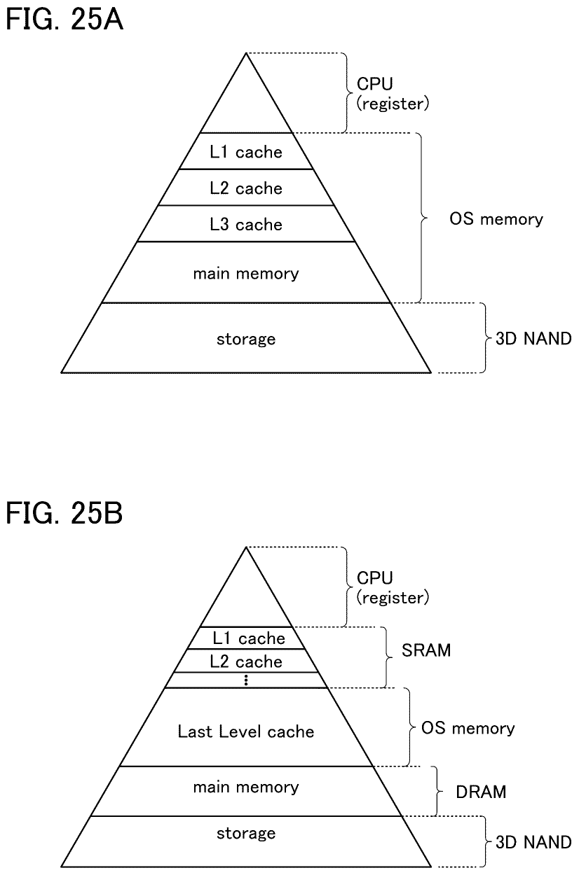

In general, a variety of memory devices are used in semiconductor devices such as computers in accordance with the intended use. FIG. 25A illustrates the hierarchy of various memory devices used in a semiconductor device. The memory devices at the upper levels require a higher operating speed, whereas the memory devices at the lower levels require a larger memory capacity and a higher memory density. FIG. 25A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

The memory included as the register in the arithmetic processing device such as a CPU is used for temporary storage of arithmetic operation results, for example, and thus is very frequently accessed by the arithmetic processing device. Accordingly, rapid operation is more important than the memory capacity of the memory. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program and data that are read from the storage, for example.

The storage has a function of retaining data that needs to be stored for a long time and programs used in the arithmetic processing device, for example. Therefore, the storage needs to have a large memory capacity and a high memory density rather than operating speed. For example, a high-capacity nonvolatile memory device such as a 3D NAND memory device can be used.

The memory device including an oxide semiconductor (the OS memory) of one embodiment of the present invention operates at high speed and can retain data for a long time. Thus, as illustrated in FIG. 25A, the memory device of one embodiment of the present invention can be suitably used at both the level including the cache and the level including the main memory. The memory device of one embodiment of the present invention can also be used at the level including the storage.

FIG. 25B illustrates an example in which an SRAM is used as at least one of the caches and the OS memory of one embodiment of the present invention is used as the other cache.

The lowest-level cache can be referred to as a last level cache (LLC). The LLC does not require a higher operation speed than a higher-level cache, but desirably has large storage capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 25B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 25B.

Note that this embodiment can be combined with any of the other embodiments in this specification as appropriate.

### Embodiment 4

An electronic device, a large computer, a device for space, and a data center (also referred to as DC) for which the semiconductor device described in the above embodiments are described in this embodiment. An electronic device, a large computer, a device for space, and a data center each employing the semiconductor device of one embodiment of the present invention are effective in improving performance, for example, reducing power consumption.

### [Electronic Device]

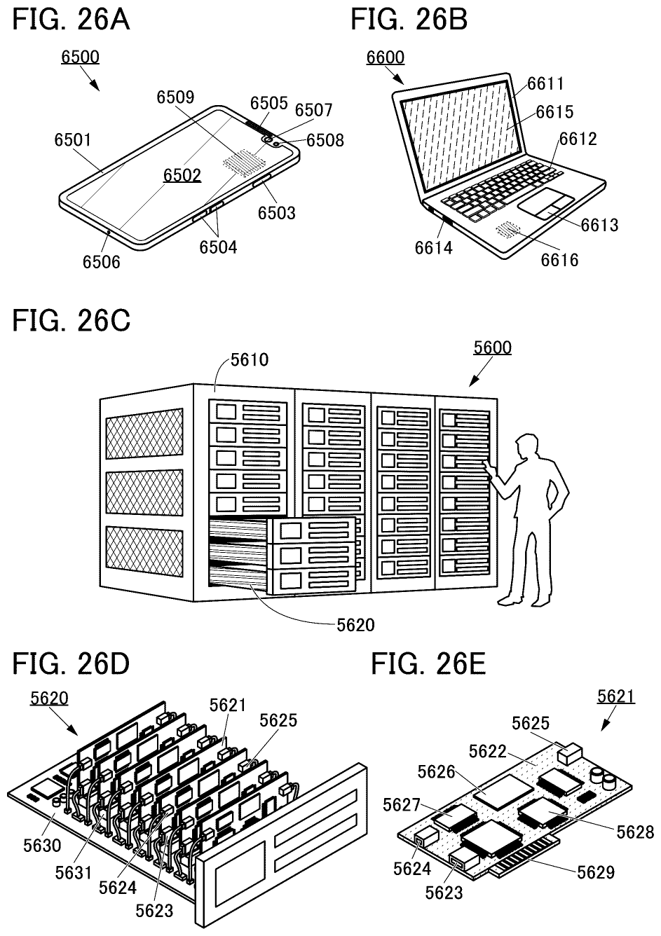

FIG. 26A is a perspective view of an electronic device 6500. The electronic device 6500 in FIG. 26A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic device 6600 illustrated in FIG. 26B is an information terminal that can be used as a laptop personal computer. The electronic device 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

Next, FIG. 26C is a perspective view of a large computer 5600. In the large computer 5600 illustrated in FIG. 26C, a plurality of rack mount computers 5620 are stored in a rack 5610. Note that the large computer 5600 may be referred to as a supercomputer.

The computer 5620 can have a structure in a perspective view illustrated in FIG. 26D, for example. In FIG. 26D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26E is an example of a processing board provided with a CPU, a GPU, a storage device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 26E also illustrates semiconductor devices other than the semiconductor device 5626, the semiconductor device 5627, and the semiconductor device 5628, the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device or the like.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used for a device for space, such as devices processing and storing information.

The semiconductor device of one embodiment of the present invention can include an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space.

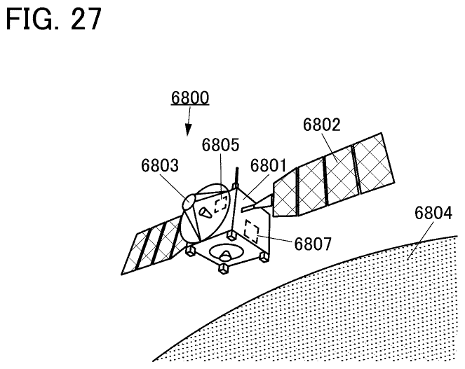

FIG. 27 illustrates an artificial satellite 6800 as an example of a device for space. The artificial satellite 6800 includes a body 6801, a solar panel 6802, an antenna 6803, a secondary battery 6805, and a control device 6807. In FIG. 27, a planet 6804 in outer space is illustrated. Note that outer space refers to, for example, space at an altitude greater than or equal to 100 km, and outer space in this specification may also include thermosphere, mesosphere, and stratosphere.

Although not illustrated in FIG. 27, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics of the OS transistor due to exposure to radiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

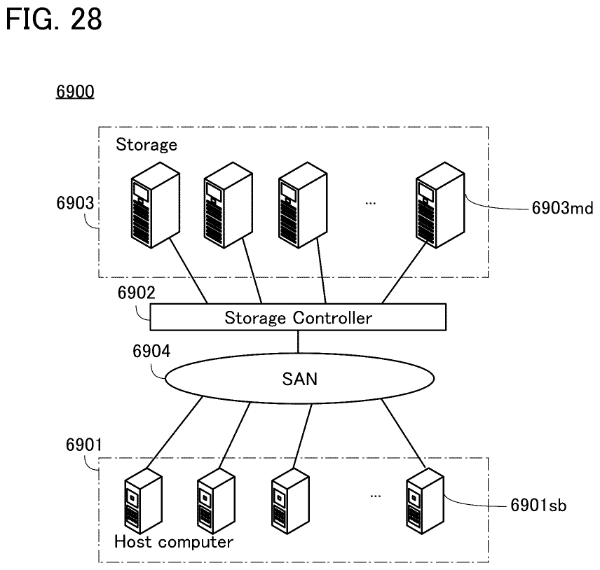

FIG. 28 illustrates a storage system that can be used in a data center. A storage system 6900 illustrated in FIG. 28 includes a plurality of servers 6901sb as a host 6901 (indicated as “Host computer” in the diagram). The storage system 6900 includes a plurality of memory devices 6903md as a storage 6903 (indicated as “Storage” in the diagram). In the illustrated example, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer which accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in the storage 6903.

In the storage system, in order to solve the problem of low access speed of the storage 6903, a cache memory is normally provided in the storage to shorten the time taken for data storage and output.

The above-described cache memory is used in the storage control circuit 6902 and the storage 6903. The data transmitted between the host 6901 and the storage 6903 is stored in the cache memories in the storage control circuit 6902 and the storage 6903 and then output to the host 6901 or the storage 6903.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic device, a large computer, a device for space, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The configurations, structures, methods, and the like described in this embodiment can be used in an appropriate combination with any of the configurations, structures, methods, and the like described in the other embodiments and the like.

This application is based on Japanese Patent Application Serial No. 2023-103055 filed with Japan Patent Office on Jun. 23, 2023, the entire contents of which are hereby incorporated by reference.

What is claimed is:

1. A semiconductor device comprising:
a first conductive layer;
a second conductive layer;
a third conductive layer;
a fourth conductive layer;
a first insulating layer;
a second insulating layer; and
a semiconductor layer,
wherein the first insulating layer is provided over the first conductive layer,
wherein the second conductive layer is provided over the first insulating layer,
wherein the second conductive layer and the first insulating layer comprise an opening reaching the first conductive layer,
wherein the semiconductor layer is provided in contact with a top surface of the first conductive layer inside the opening, a side surface of the first insulating layer inside the opening, a side surface of the second conductive layer inside the opening, and a top surface of the second conductive layer,
wherein the second insulating layer is provided in contact with a top surface of the semiconductor layer inside the opening, a side surface of the semiconductor layer inside the opening, and a top surface of the semiconductor layer outside the opening,
wherein the third conductive layer is provided over the second insulating layer to fill the opening,
wherein the first insulating layer comprises a depressed portion surrounding the opening in a plan view,
wherein the fourth conductive layer is provided to fill the depressed portion, and
wherein, inside the opening, one side of the semiconductor layer faces the third conductive layer with the second insulating layer therebetween, and the other side of the semiconductor layer faces the fourth conductive layer with the first insulating layer therebetween.

2. The semiconductor device according to claim 1, wherein the semiconductor layer comprises a metal oxide.

3. The semiconductor device according to claim 1,
wherein the first insulating layer comprises a third insulating layer and a fourth insulating layer over the third insulating layer,
wherein a fifth insulating layer is provided in contact with a top surface of the fourth insulating layer and a top surface of the fourth conductive layer,
wherein the third insulating layer and the fifth insulating layer comprise one or a plurality of silicon nitride, silicon nitride oxide, hafnium oxide, and aluminum oxide, and
wherein the fourth insulating layer comprises one or a plurality of silicon oxide and silicon oxynitride.

4. A semiconductor device comprising:
a first conductive layer;
a second conductive layer;
a third conductive layer;
a fourth conductive layer;
a first insulating layer;
a second insulating layer;
a third insulating layer; and
a semiconductor layer,
wherein the first insulating layer is provided over the first conductive layer,
wherein the second conductive layer is provided over the first insulating layer,
wherein the first insulating layer comprises a depressed portion,
wherein the third conductive layer is provided to fill the depressed portion,
wherein the second conductive layer, the third conductive layer, and the first insulating layer comprise an opening reaching the first conductive layer in a region overlapping with the depressed portion,
wherein the second insulating layer is provided in contact with a side surface of the first insulating layer inside the opening, a side surface of the third conductive layer inside the opening, and a side surface of the second conductive layer inside the opening,
wherein the semiconductor layer is provided in contact with a top surface of the first conductive layer inside the opening, a side surface of the second insulating layer inside the opening, and a top surface of the second conductive layer,
wherein the third insulating layer is provided in contact with a top surface of the semiconductor layer inside the opening, a side surface of the semiconductor layer inside the opening, and a top surface of the semiconductor layer outside the opening,
wherein the fourth conductive layer is provided over the third insulating layer to fill the opening, and
wherein the semiconductor layer comprises a region facing the fourth conductive layer with the third insulating layer therebetween and a region facing the third conductive layer with the second insulating layer therebetween inside the opening.

5. The semiconductor device according to claim 4, wherein the semiconductor layer comprises a metal oxide.

6. The semiconductor device according to claim 4,
wherein the first insulating layer comprises a fourth insulating layer and a fifth insulating layer over the fourth insulating layer,
wherein a sixth insulating layer is provided in contact with a top surface of the fifth insulating layer and a top surface of the third conductive layer,
wherein the fourth insulating layer and the sixth insulating layer comprise one or a plurality of silicon nitride, silicon nitride oxide, hafnium oxide, and aluminum oxide, and
wherein the fifth insulating layer comprises one or a plurality of silicon oxide and silicon oxynitride.

7. The semiconductor device according to claim 4, wherein the second insulating layer comprises one or a plurality of silicon oxide and silicon oxynitride.

8. The semiconductor device according to claim 4,
wherein the second insulating layer comprises a seventh insulating layer and an eighth insulating layer,
wherein the seventh insulating layer is provided in contact with the side surface of the first insulating layer inside the opening, the side surface of the third conductive layer inside the opening, and the side surface of the second conductive layer inside the opening and comprises one or a plurality of silicon nitride, silicon nitride oxide, hafnium oxide, and aluminum oxide, and
wherein the eighth insulating layer is provided over the seventh insulating layer to face the side surface of the first insulating layer inside the opening, the side surface of the third conductive layer inside the opening, and the side surface of the second conductive layer inside the opening with the seventh insulating layer therebetween and comprises one or a plurality of silicon oxide and silicon oxynitride.

9. A method for manufacturing a semiconductor device, comprising the steps of:
forming a first conductive layer and a first insulating film over the first conductive layer;
processing the first insulating film to form a first insulating layer comprising a depressed portion;
forming a first conductive film over the first insulating layer;
planarizing the first conductive film until a top surface of the first insulating layer is exposed to form a second conductive layer filling the depressed portion;
forming a second insulating film over the second conductive layer and the first insulating layer and a second conductive film over the second insulating film;
processing the second conductive film, the second insulating film, and the first insulating layer to form a third conductive layer, a second insulating layer, and a third insulating layer comprising an opening reaching the first conductive layer in a region surrounded by the depressed portion in a plan view;
forming a metal oxide film in contact with a top surface of the first conductive layer inside the opening, a side surface of the third insulating layer inside the opening, a side surface of the second insulating layer inside the opening, a side surface of the third conductive layer inside the opening, and a top surface of the third conductive layer; and
processing the metal oxide film to form a semiconductor layer comprising a region overlapping with the opening in a plan view.

10. A method for manufacturing a semiconductor device, comprising the steps of:
forming a first conductive layer, a first insulating film over the first conductive layer, and a second insulating film over the first insulating film;
processing the second insulating film to form a first insulating layer comprising a depressed portion;
forming a first conductive film over the first insulating layer;
planarizing the first conductive film until a top surface of the first insulating layer is exposed to form a second conductive layer filling the depressed portion;
forming a third insulating film over the second conductive layer and the first insulating layer and a second conductive film over the third insulating film;
processing the second conductive film, the third insulating film, the second conductive layer, and the first insulating layer to form a third conductive layer, a second insulating layer, a fourth conductive layer, and a third insulating layer comprising an opening reaching the first insulating film in a region overlapping with the depressed portion in a plan view;
forming a fourth insulating film in contact with a top surface of the first insulating film inside the opening, a side surface of the third insulating layer inside the opening, a side surface of the fourth conductive layer inside the opening, a side surface of the second insulating layer inside the opening, a side surface of the third conductive layer inside the opening, and a top surface of the third conductive layer;
removing a region of the fourth insulating film in contact with the top surface of the third conductive layer, part of a region of the fourth insulating film in contact with the first insulating film, and part of a region of the first insulating film overlapping with the opening to form a fourth insulating layer in contact with the side surface of the third insulating layer inside the opening, the side surface of the fourth conductive layer inside the opening, the side surface of the second insulating layer inside the opening, and the side surface of the third conductive layer inside the opening and to expose the first conductive layer in a region overlapping with the opening;
forming a metal oxide film in contact with a top surface of the first conductive layer in the region overlapping with the opening, a side surface of the fourth insulating layer inside the opening, and the top surface of the third conductive layer; and
processing the metal oxide film to form a semiconductor layer comprising a region overlapping with the opening in a plan view.
